(19) United States
(12) Patent Application Publication
(10) Pub. No.: US 2025/0185455 A1
(43) Pub. Date: Jun. 5, 2025

(54) ORGANIC LIGHT-EMITTING DEVICE

(71) Applicant: CANON KABUSHIKI KAISHA, Tokyo (JP)

(72) Inventors: HIROKAZU MIYASHITA, Miyagi (JP); HITOSHI NAGASHIMA, Kanagawa (JP); YOSUKE NISHIDE, Kanagawa (JP); NAOKI YAMADA, Tokyo (JP)

(21) Appl. No.: 19/044,417

(22) Filed: Feb. 3, 2025

Related U.S. Application Data
(63) Continuation of application No. PCT/JP2023/026493, filed on Jul. 20, 2023.

(30) Foreign Application Priority Data
Aug. 10, 2022 (JP) 2022-128081

(51) Int. Cl. H10K 50/12; H10K 50/13; H10K 101/40

(52) U.S. Cl. CPC H10K 50/12; H10K 50/13; H10K 2101/40

(57) ABSTRACT

An organic light-emitting device having improved carrier transfer and triplet energy transfer between stacked light-emitting layers and having improved driving durability. The light-emitting layers include a first light-emitting layer and a second light-emitting layer. The first light-emitting layer contains a first organic compound, a first metal complex, and a second metal complex. The second light-emitting layer contains a second organic compound and a third metal complex and is free of the first metal complex. Relationships represented by the following formulae [a] to [c] hold:

T1D2≥T1D1 [a]

T1D3≥T1D2 [b]

$$T 1 D 2 - T 1 D 1 > T 1 D 3 - T 1 D 2 \qquad [ c ]$$

where T1D1 is the triplet energy of the first metal complex, T1D2 is the triplet energy of the second metal complex, and T1D3 is the triplet energy of the third metal complex.

### CROSS-REFERENCE TO RELATED APPLICATIONS

This application is a Continuation of International Patent Application No. PCT/JP2023/026493, filed Jul. 20, 2023, which claims the benefit of Japanese Patent Application No. 2022-128081, filed Aug. 10, 2022, both of which are hereby incorporated by reference herein in their entirety.

### TECHNICAL FIELD

The present invention relates to an organic light-emitting device and various apparatuses each including the organic light-emitting device.

### BACKGROUND ART

The organic light-emitting device (hereinafter, also referred to as an “organic electroluminescent device” or an “organic EL device”) is a device that emits light by energizing an anode, a cathode, and organic electroluminescent (EL) layers including a light-emitting layer disposed between those electrodes.

In recent years, research and development of full-color displays using organic light-emitting devices has been vigorously pursued. Organic light-emitting devices are known to be broadly classified into fluorescent devices and phosphorescent devices in accordance with the type of compound contained in light-emitting layers, and energy diagrams suitable for each are required to be designed.

In the case of producing a full-color display, there are known a method in which a light-emitting layer is separately provided for each pixel (device), and a method in which an organic light-emitting device is used in which a light-emitting layer emits white light and a color filter is provided separately for each pixel. In the case of using a white light-emitting layer, two or more light-emitting materials are known to be used in an organic light-emitting device.

Japanese Patent Laid-Open No. 2014-96557 discloses an organic light-emitting device in which a light-emitting layer composed of an exciplex host and a phosphorescent material is stacked. Japanese Patent Laid-Open No. 2013-200939 discloses an organic light-emitting device in which a light-emitting layer composed of a hole transport host and a phosphorescent material and a light-emitting layer composed of an electron transport host and a phosphorescent material are stacked. Japanese Patent Laid-Open No. 2011-171269 discloses an organic light-emitting device in which two light-emitting layers each containing a blue-phosphorescent material, a green-phosphorescent material, and a red-phosphorescent material are stacked. Japanese Patent Laid-Open No. 2010-34484 discloses an organic light-emitting device in which a light-emitting layer containing a blue-phosphorescent material and a green-phosphorescent material and a light-emitting layer containing a red-phosphorescent material are stacked.

### CITATION LIST

### Patent Literature

PTL 1 Japanese Patent Laid-Open No. 2014-96557
PTL 2 Japanese Patent Laid-Open No. 2013-200939
PTL 3 Japanese Patent Laid-Open No. 2011-171269
PTL 4 Japanese Patent Laid-Open No. 2010-34484

However, in the organic light-emitting devices described in the above patent documents, carrier transfer and triplet energy transfer between stacked light-emitting layers are difficult to occur. Thus, there is room for improvement in durability.

### SUMMARY OF INVENTION

The present invention has been made in response to the above issue and provides an organic light-emitting device having improved carrier transfer and triplet energy transfer between stacked light-emitting layers and having improved driving durability.

One disclosed aspect of the present invention is directed to providing an organic light-emitting device including a first electrode, a light-emitting layer including a first light-emitting layer and a second light-emitting layer, and a second electrode. The first light-emitting layer is in contact with the second light-emitting layer. The first light-emitting layer contains a first organic compound, a first metal complex, and a second metal complex. The second light-emitting layer contains a second organic compound and a third metal complex and is free of the first metal complex. Relationships represented by the following formulae [a] to [c] hold:

T1D2≥T1D1 [a]

T1D3≥T1D2 [b]

$$T 1 D 2 - T 1 D 1 > T 1 D 3 - T 1 D 2 \qquad [ c ]$$

where T1D1 is the triplet energy of the first metal complex, T1D2 is the triplet energy of the second metal complex, and T1D3 is the triplet energy of the third metal complex.

Further features of the present invention will become apparent from the following description of exemplary embodiments with reference to the attached drawings.

### BRIEF DESCRIPTION OF DRAWINGS

FIG. 1 is a schematic cross-sectional view of an organic light-emitting device according to an embodiment of the present invention.

FIG. 2 is an energy diagram illustrating schematic energy levels around the light-emitting layer of an organic light-emitting device according to an embodiment of the present invention.

FIG. 3 is a schematic diagram of the triplet energy levels of metal complexes contained in the light-emitting layer of an organic light-emitting device according to an embodiment of the present invention.

FIG. 4A is a schematic view of a display apparatus according to an embodiment of the present invention.

FIG. 4B is a schematic cross-sectional view of a display apparatus according to an embodiment of the present invention.

FIG. 5 is a schematic view of a display apparatus according to an embodiment of the present invention.

FIG. 6A is a schematic view of an image pickup apparatus according to an embodiment of the present invention.

FIG. 6B is a schematic view of an electronic apparatus according to an embodiment of the present invention.

FIG. 7A is a schematic view of a display apparatus according to an embodiment of the present invention.

FIG. 7B is a schematic view of a foldable display apparatus according to an embodiment of the present invention.

FIG. 8A is a schematic view of a lighting apparatus according to an embodiment of the present invention.

FIG. 8B is a schematic view of an automobile including an automotive lighting unit according to an embodiment of the present invention.

FIG. 9A is a schematic view of an example of a wearable device according to an embodiment of the present invention.

FIG. 9B is a schematic view of an example of a wearable device according to an embodiment of the present invention, the wearable device including an image pickup apparatus.

FIG. 10A is a schematic view of an example of an image-forming apparatus according to an embodiment of the present invention and an example of an exposure light source thereof.

FIG. 10B is a schematic view of an example of an image-forming apparatus according to an embodiment of the present invention and an example of an exposure light source thereof.

FIG. 10C is a schematic view of an example of an image-forming apparatus according to an embodiment of the present invention and an example of an exposure light source thereof.

### DESCRIPTION OF EMBODIMENTS

An organic light-emitting device according to an embodiment of the present invention includes a first electrode, a stacked light-emitting layer including a first light-emitting layer and a second light-emitting layer, and a second electrode. At least one of the first electrode and the second electrode is required to be a light-transmitting electrode. One of the first electrode and the second electrode may be a reflective electrode. The first light-emitting layer and the second light-emitting layer are in contact with each other. One of the first light-emitting layer and the second light-emitting layer is adjacent to an anode, and the other is adjacent to a cathode.

The first light-emitting layer contains a first organic compound, a first metal complex, and a second metal complex. The second light-emitting layer contains a second organic compound and a third metal complex and does not contain the first metal complex. That is, the first metal complex and the second metal complex are different metal complexes from each other and have different triplet energies from each other. Thus, the first light-emitting layer and the second light-emitting layer exhibit different emission colors from each other.

### Stacked Light-Emitting Layer

In an organic light-emitting device according to an embodiment of the present invention, relationships represented by the following formulae [a] to [c] hold:

T1D2≥T1D1 [a]

T1D3≥T1D2 [b]

$$T 1 D 2 - T 1 D 1 > T 1 D 3 - T 1 D 2. \qquad [ c ]$$

T1D1 is the triplet energy of the first metal complex, T1D2 is the triplet energy of the second metal complex, and T1D3 is the triplet energy of the third metal complex.

Formula [a] described above indicates that the first metal complex has a lower triplet energy than the second metal complex, and thus indicates that light emission from the first metal complex is mainly observed in the first light-emitting layer.

Formula [b] described above indicates that the triplet energy of the third metal complex contained in the second light-emitting layer is higher than or equal to that of the second metal complex contained in the first light-emitting layer. Furthermore, formula [b], in conjunction with formula [a], indicates that the third metal complex has a higher triplet energy than the first metal complex. This indicates that the second light-emitting layer is a light-emitting layer that emits light with a shorter wavelength than the wavelength of light emitted from the first light-emitting layer.

Formula [c] described above indicates that the difference in triplet energy between the third metal complex and the second metal complex is smaller than the difference in triplet energy between the first metal complex and the second metal complex. As described below, this indicates that the relationship is such that energy transfer is more likely to occur between the third metal complex and the second metal complex than between the third metal complex and the first metal complex.

The third metal complex and the second metal complex are metal complexes having a small or no difference in triplet energy and thus have approximately the same energy gap. For this reason, the positional relationship between the energy levels of the highest occupied molecular orbital (HOMO) and the lowest unoccupied molecular orbital (LUMO) is also close. This indicates that the relationship is such that carrier transfer is more likely to occur between the third metal complex and the second metal complex than between the third metal complex and the first metal complex. Thereby, as described below, the exciton density generated in the first light-emitting layer and the second light-emitting layer can be easily adjusted between these light-emitting layers, improving driving durability.

In this specification, the triplet energy refers to the energy of the lowest excited triplet state and is expressed in units of eV. A larger value thereof indicates a higher energy. When the energy is converted to a wavelength, a higher energy indicates a shorter wavelength.

In this specification, the energy gap refers to the energy gap from the energy level of the highest occupied molecular orbital (HOMO) to the energy level of the lowest unoccupied molecular orbital (LUMO) and is also called a band gap. The energy level of the HOMO may be referred to as a “HOMO” or “HOMO level”. The energy level of the LUMO may be referred to as a “LUMO” or “LUMO level”.

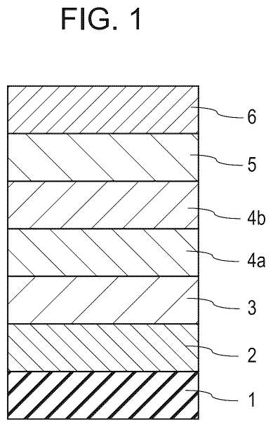

An embodiment of the present invention will be described in more detail below with reference to FIGS. 1 to 3.

FIG. 1 is a schematic cross-sectional view of an organic light-emitting device according to the present embodiment. The organic light-emitting device in FIG. 1 includes an anode 2, a hole transport layer 3, a first light-emitting layer 4a, a second light-emitting layer 4b, an electron transport layer 5, and a cathode 6 disposed in that order over an insulating layer 1.

In the present embodiment, the light-emitting layer refers to a layer that emits light among the organic compound layers provided between the electrodes. Among the compounds contained in each light-emitting layer, a compound having the largest mass ratio may be referred to as a host, and a compound mainly contributing to light emission may be referred to as a dopant or a guest. The term “host” refers to a material contained in the light-emitting layer in an amount of more than 50% by mass among materials contained in the light-emitting layer. The term “dopant” refers to a material contained in the light-emitting layer in an amount of less than 50% by mass among the materials contained in the light-emitting layer. The concentration of the dopant in the light-emitting layer is preferably 0.1% or more by mass and 40% or less by mass, more preferably 30% or less by mass, in order to inhibit concentration quenching. In the present invention, the first organic compound and the second organic compound are hosts, and the first metal complex and the third metal complex are dopants.

Among compounds contained in the light-emitting layer, the term “assist material” refers to a compound that has a lower proportion by mass than the host in the compounds constituting the light-emitting layer and that assists the light emission of the guest. The assist material is also referred to as a second host. Alternatively, when the guest is referred to as a “first compound”, the assist material can also be referred to as a “second compound”. The second metal complex according to an embodiment of the present invention is an assist material.

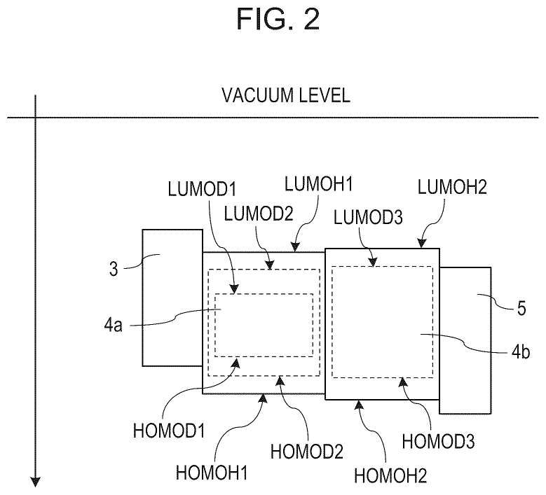

FIG. 2 is an energy diagram schematically illustrating energy levels around the light-emitting layer included in the organic light-emitting device according to an embodiment of the present invention. In the figure, HOMOD1 is the HOMO level of the first metal complex, LUMOD1 is the LUMO level of the first metal complex, HOMOD2 is the HOMO level of the second metal complex, LUMOD2 is the LUMO level of the second metal complex, HOMOD3 is the HOMO level of the third metal complex, LUMOD3 is the LUMO level of the third metal complex, HOMOH1 is the HOMO level of the first host, LUMOH1 is the LUMO level of the first host, HOMOH2 is the HOMO level of the second host, and LUMOH2 is the LUMO level of the second host.

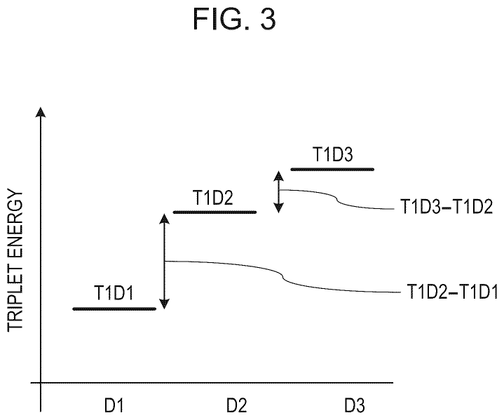

FIG. 3 is a schematic diagram illustrating the relationship among triplet energy levels of metal complexes contained in a light-emitting layer included in an organic light-emitting device according to an embodiment of the present invention. In FIG. 3, the vertical axis represents the energy level, and the upper direction of the figure represents higher energy. In the figure, D1 represents the first metal complex, D2 represents the second metal complex, and D3 represents the third metal complex. T1D1 represents the triplet energy level of the first metal complex, T1D2 represents the triplet energy level of the second metal complex, and T1D3 represents the triplet energy level of the third metal complex.

As illustrated in FIG. 3, in an embodiment of the present invention, the first metal complex and the second metal complex contained in the first light-emitting layer 4a, and the third metal complex contained in the second light-emitting layer 4b satisfy the relationships represented by the following formulae [a] to [c]:

T1D2≥T1D1 [a]

T1D3≥T1D2 [b]

$$T 1 D 2 - T 1 D 1 > T 1 D 3 - T 1 D 2. \qquad [ c ]$$

In an embodiment of the present invention, as the triplet energy of the metal complex, an actually measured value may be used, or a value obtained by molecular orbital calculation may be used. As the molecular orbital calculation method of a metal complex in this specification, the density functional theory (DFT), which is widely used at present, was used with the B3PW91 functional and LANL2DZ as the basis function. The molecular orbital calculation method was performed using Gaussian 09 (Gaussian 09, Revision D.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2013), which is widely used at present. A specific method for measuring an actual value will be described in examples below.

An organic light-emitting device according to an embodiment of the present invention has a device configuration including two or more light-emitting layers and has the following configuration.

(1) Two light-emitting layers are stacked, each of the light-emitting layers contains a metal complex that is a phosphorescent material that emits light of a different color, and one of the light-emitting layers contains a metal complex that is an assist material for triplet energy transfer.

An organic light-emitting device according to an embodiment of the present invention includes two light-emitting layers that are stacked. Each of the light-emitting layers contains a phosphorescent metal complex. Each light-emitting layer exhibits a different emission wavelength. Phosphorescence is light emission derived from triplet energy. That is, different triplet energies are generated in different light-emitting layers, and there is a magnitude relationship. This results in energy transfer from a light-emitting layer having a higher triplet energy to a light-emitting layer having a lower triplet energy.

The inventors have found that the device durability can be improved by quickly transferring excess triplet energy generated in a light-emitting layer having a higher triplet energy to an adjacent light-emitting layer having a lower triplet energy. More specifically, a metal complex having a triplet energy that is an intermediate level between the triplet energy levels of the metal complexes contained in the respective light-emitting layers is contained in the light-emitting layer to which the energy is transferred. With this structure, it is possible to promote energy transfer from a high-energy light-emitting layer to an adjacent low-energy light-emitting layer. In other words, an assist material for triplet energy transfer is contained.

Typically, phosphorescent devices are prone to triplet-triplet annihilation (TTA) due to the long emission lifetime of phosphorescent materials. TTA is caused by collisions of excess triplet excitons that do not transfer to the light emission process. A high-order excited state generated by TTA has high energy and may cause material degradation, resulting in the deterioration of the device durability.

The high energy produced by TTA is proportional to the triplet energy of the light-emitting layer. For this reason, in a light-emitting layer having a higher triplet energy, TTA that generates a high-order excited state having a higher energy occurs, leading to a higher possibility of material degradation. Thus, it is considered that material degradation can be inhibited by reducing TTA in the light-emitting layer having a higher energy and, instead, increasing TTA in the light-emitting layer having a lower energy.

In the present invention, the relationships represented by formulae [a] and [b] hold. That is, in order to facilitate energy transfer from the second light-emitting layer containing the third metal complex having a higher triplet energy to the first light-emitting layer containing the first metal complex having a lower triplet energy, of two adjacent light-emitting layers, the first light-emitting layer contains the second metal complex having an intermediate energy level to promote triplet energy transfer. This can reduce TTA that may occur in the second light-emitting layer containing the third metal complex having a higher triplet energy, thereby inhibiting material deterioration. As a result, an organic light-emitting device having excellent durability can be obtained.

(2) The triplet energy of the assist material that promotes energy transfer has a value closer to the triplet energy of the light-emitting material that is the source of the energy transfer than to the triplet energy of the light-emitting material that is the destination of the energy transfer.

As described above, according to an embodiment of the present invention, the organic light-emitting device having the stacked light-emitting layer that can have improved driving durability by promoting triplet energy transfer with the assist material.

Typically, energy transfer of triplet excitons is believed to occur via Dexter energy transfer. As described in the following formula [A], the rate constant of Dexter energy transfer is proportional to the overlap between the emission spectrum of the source of the energy transfer (donor) and the absorption spectrum of the destination of the energy transfer (acceptor). It is also exponentially inversely proportional to the intermolecular distance between the donor and the acceptor.

$${k}_{DEXT} = ( \frac{2 π}{h} ) {K}^{2} exp ( - \frac{2 R}{L} ) \int {f}_{D} ( γ ) {ε}_{A} ( γ ) d γ \qquad [ A ]$$

h: Planck's constant
K²: Dipole orientation factor
R: Intermolecular distance between donor and acceptor
L: effective molecular radius
F_{D}(λ): Normalized emission spectrum of donor
ε_{A}(λ): Normalized absorption spectrum of acceptor

The inventors have found that when the relationship represented by formula [c] described above holds, Dexter energy transfer between the first light-emitting layer and the second light-emitting layer can be promoted. That is, in the configuration of the stacked light-emitting layer according to an embodiment of the present invention, the triplet energy of the second metal complex, which is an assist material that promotes energy transfer, has a value closer to the value of the triplet energy of the third metal complex, which is the source of energy transfer, than to the value of the triplet energy of the first metal complex, which is the destination of energy transfer, thereby promoting energy transfer.

In an embodiment of the present invention, the second metal complex serving as the assist material is contained in the first light-emitting layer. The third metal complex, which is the source of energy transfer, is contained in the second light-emitting layer. Thus, the opportunity for contact between the donor (third metal complex) and the acceptor (second metal complex) is limited to the interface between the first light-emitting layer and the second light-emitting layer.

From formula [A] described above, in Dexter energy transfer, a shorter intermolecular distance between the donor (third metal complex) and the acceptor (second metal complex) results in easier energy transfer. Therefore, a short distance between the donor (third metal complex) and the acceptor (second metal complex) is preferred. The inventors have found that a reduction in the difference in triplet energy between the donor (third metal complex) and the acceptor (second metal complex) increases compatibility and shortens the intermolecular distance.

The reason for this is presumably that the molecular structures have similar characteristics because they are metal complexes and that the dipole moments are easily aligned because the metal complexes have similar energies, thus allowing the molecules to approach each other more easily.

For example, when the second light-emitting layer is stacked after the formation of the first light-emitting layer containing the acceptor (second metal complex), the donor (third metal complex) tends to gather around the acceptor (second metal complex), which is a molecule having a similar energy level, because it is energetically more stable. As a result, the intermolecular distance between the donor (third metal complex) and the acceptor (second metal complex) is shortened. Since the difference in triplet energy between the donor (third metal complex) and the acceptor (second metal complex) is small, the overlap between the emission spectrum (phosphorescence) of the donor and the absorption spectrum of the acceptor is sufficiently large.

As described above, when the relationship represented by formula [c] holds, the intermolecular distance between the donor (third metal complex) and the acceptor (second metal complex) is shortened, and the overlap between the emission spectrum of the donor and the absorption spectrum of the acceptor is sufficiently large, thereby promoting Dexter energy transfer.

After the energy is transferred from the third metal complex to the second metal complex, the energy is transferred from the second metal complex to the first metal complex in the first light-emitting layer, and then the light-emitting process of the first metal complex is started. In this manner, the stacked light-emitting layer, which undergoes the continuous triplet energy transfer process, should reduce the accumulation itself of excess triplet excitons that are present without reaching the luminescence process. In other words, triplet excitons diffuse easily in the stacked light-emitting layer. That is, TTA itself, in which excess triplet excitons collide with each other, can be reduced, and the organic light-emitting device can have improved durability characteristics, which is also a feature according to an embodiment of the present invention.

In addition to the above-mentioned features (1) and (2), the organic light-emitting device according to an embodiment of the present invention preferably has the following configurations.

(3) The concentration of the second metal complex is higher than the concentration of the third metal complex.

(4) The concentration of the second metal complex is higher than the concentration of the first metal complex.

(5) The second metal complex and the third metal complex have at least one identical ligand.

(6) The second metal complex and the third metal complex have a HOMO level difference of 0.2 eV or less and a LUMO level difference of 0.2 eV or less.

(7) The first metal complex is a red-phosphorescent material, and the third metal complex is a green-phosphorescent material.

(8) The second light-emitting layer contains the second organic compound (assist material) that is not a metal complex.

(9) The first electrode is the anode, the second electrode is the cathode, the first light-emitting layer is adjacent to the anode, and the second light-emitting layer is adjacent to the cathode.

(10) The concentration of the third metal complex is higher than the concentration of the first metal complex.

(11) The second metal complex and the third metal complex are the same compound.

(12) The first organic compound (host in the first light-emitting layer) and the second organic compound (host in the second light-emitting layer) are the same compound.

These will be described below.

(3) The concentration of the second metal complex is higher than the concentration of the third metal complex.

As described above, the opportunity for contact between the third metal complex (donor) contained in the second light-emitting layer and the second metal complex (acceptor) contained in the first light-emitting layer is limited to the interface between the first light-emitting layer and the second light-emitting layer. A higher concentration of the second metal complex (acceptor) than the third metal complex (donor) can promote energy transfer between the first light-emitting layer and the second light-emitting layer. The second metal complex that has received energy then needs to transfer energy to the first metal complex. When the concentration of the third metal complex (donor) is higher, the second metal complex (acceptor) has more triplet excitons before the energy transfer to the first metal complex because the second metal complex (acceptor) receives more triplet energy from the third metal complex (donor), thus easily causing TTA. If TTA occurs in the second metal complex, energy cannot be transferred to the first metal complex, which is not preferred.

Therefore, the concentration of the second metal complex is preferably higher than the concentration of the third metal complex. Preferably, the relationship represented by the following formula [d] holds:

C1D2≥C1D3 [d]

where C1D2 is the concentration of the second metal complex in the light-emitting layer, and C1D3 is the concentration of the third metal complex in the light-emitting layer.

(4) The concentration of the second metal complex is higher than the concentration of the first metal complex.

A feature of the organic light-emitting device according to an embodiment of the present invention is that triplet energy transfer occurs continuously. Specifically, energy is transferred from the third metal complex to the second metal complex, and then from the second metal complex to the first metal complex. In this manner, the stacked light-emitting layer, which undergoes the continuous triplet energy transfer process, should reduce the accumulation itself of excess triplet excitons that are present without reaching the luminescence process.

The concentration of the second metal complex is preferably higher than the concentration of the first metal complex. When the concentration of the first metal complex is higher, the triplet energy transfer from the third metal complex is not to the second metal complex but to the first metal complex. It is thus difficult to undergo exciton diffusion through the continuous energy transfer process described above.

Therefore, the concentration of the second metal complex is preferably higher than the concentration of the first metal complex. Preferably, the relationship represented by the following formula [e] holds:

C1D2≥C1D1 [e]

where C1D1 is the concentration of the first metal complex in the light-emitting layer, and C1D2 is the concentration of the second metal complex in the light-emitting layer.

(5) The second metal complex and the third metal complex have at least one identical ligand.

As described above, the compatibility between the third metal complex (donor) contained in the second light-emitting layer and the second metal complex (acceptor) contained in the first light-emitting layer is increased, thereby promoting energy transfer between the first light-emitting layer and the second light-emitting layer.

As means for increasing the compatibility between the third metal complex (donor) and the second metal complex (acceptor), they preferably contain the same partial structure in their molecules. Specifically, at least one ligand contained in one of the metal complexes has the same structure as the other metal complex. The ligands having the same structure approach each other easily. This should reduce the intermolecular distance between the third metal complex (donor) and the second metal complex (acceptor). For example, the second metal complex and the third metal complex preferably contain the same molecular structure selected from the following molecular structures. The following examples include examples using a phenylpyridine skeleton, which is a typical skeleton of a bidentate ligand, a pyridylpyridine skeleton, a phenylpyrimidine skeleton, and a phenylpyrazine skeleton. Ligands having fused-ring structures, monodentate ligands, tridentate ligands, and tetradentate ligands can be used. In each of the following structural formulae, the two bonds between the ligand and the metal are both represented by dotted lines. One of the dotted lines is a covalent bond, and the other is a coordinate bond.

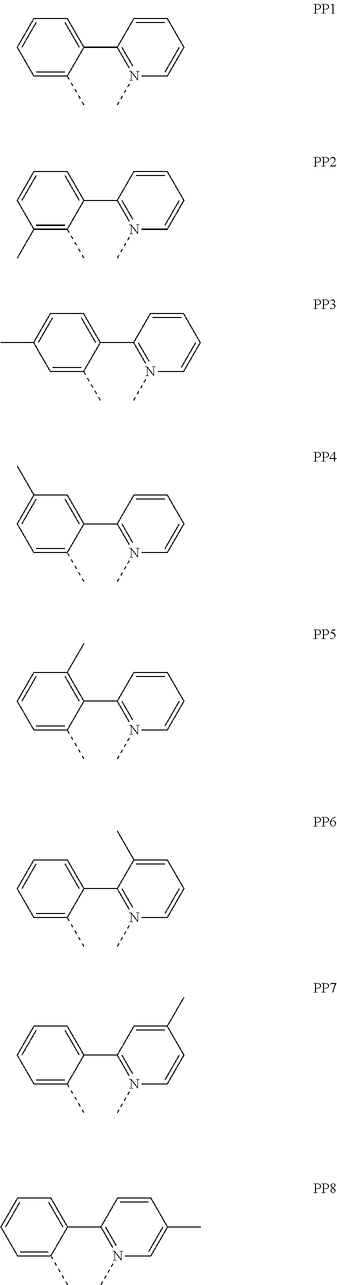

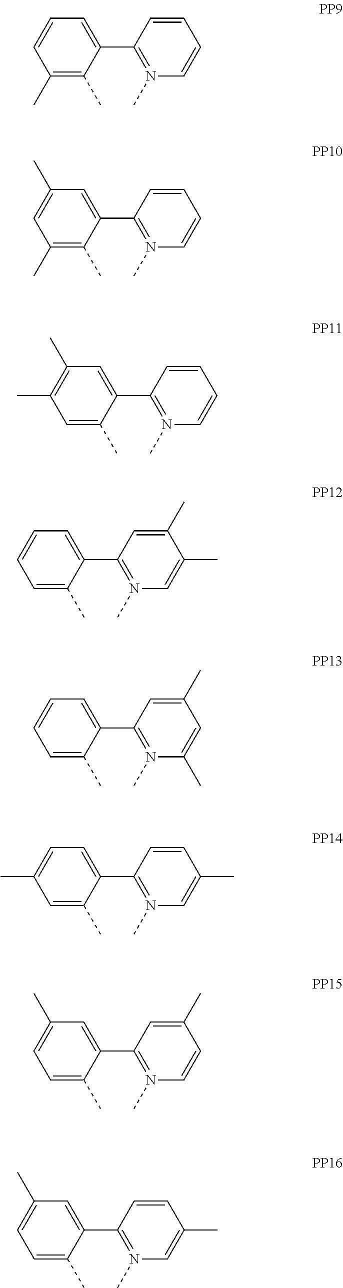

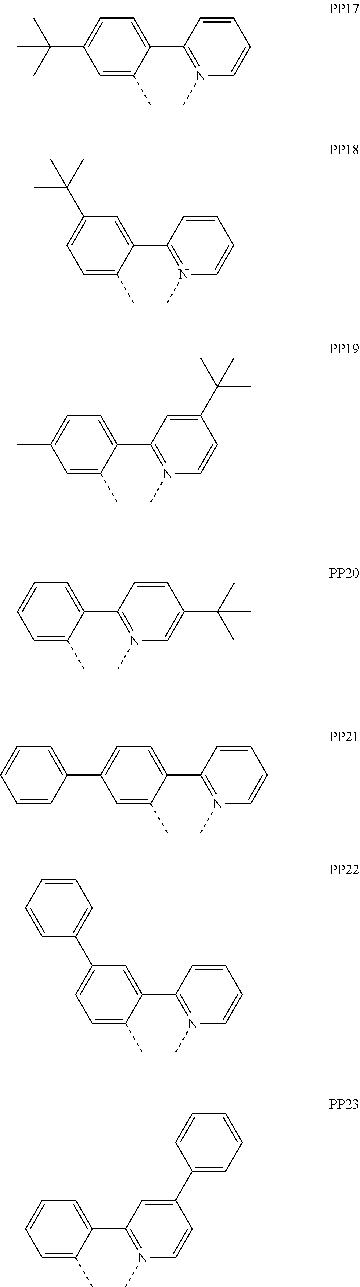

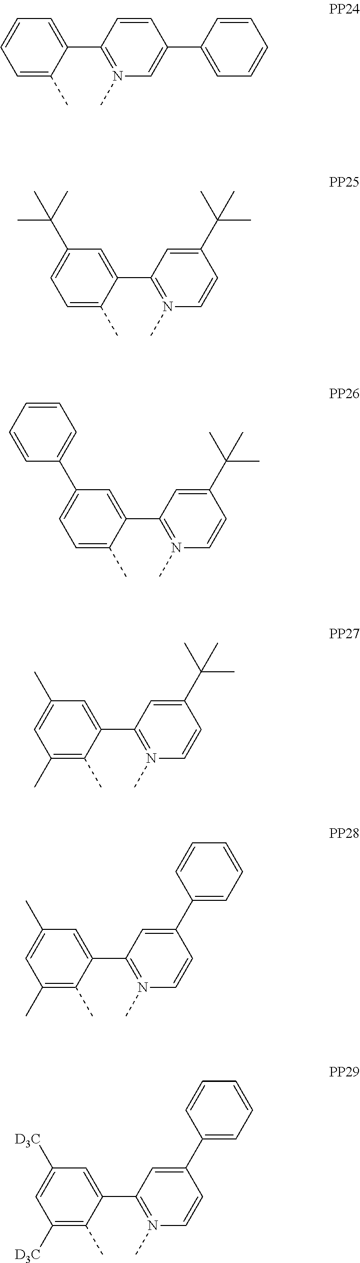

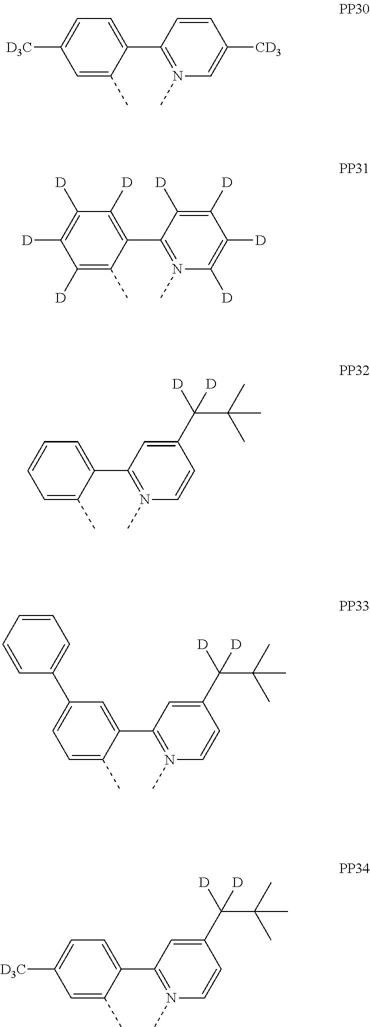

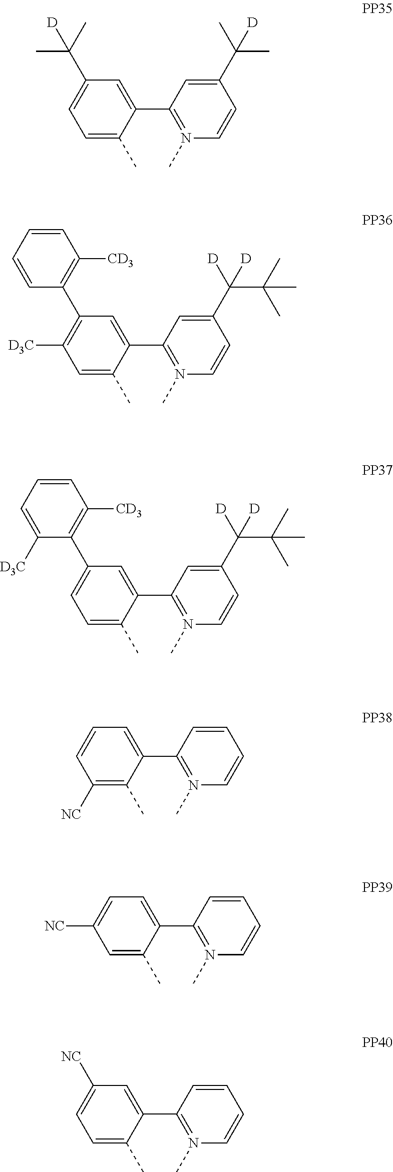

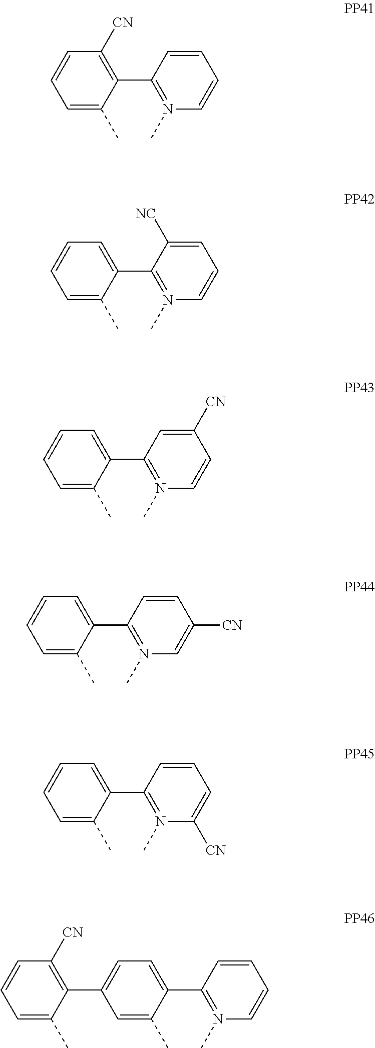

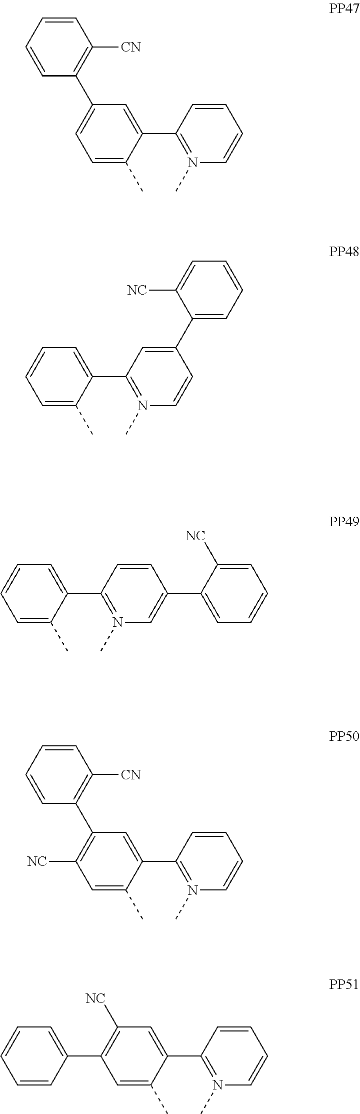

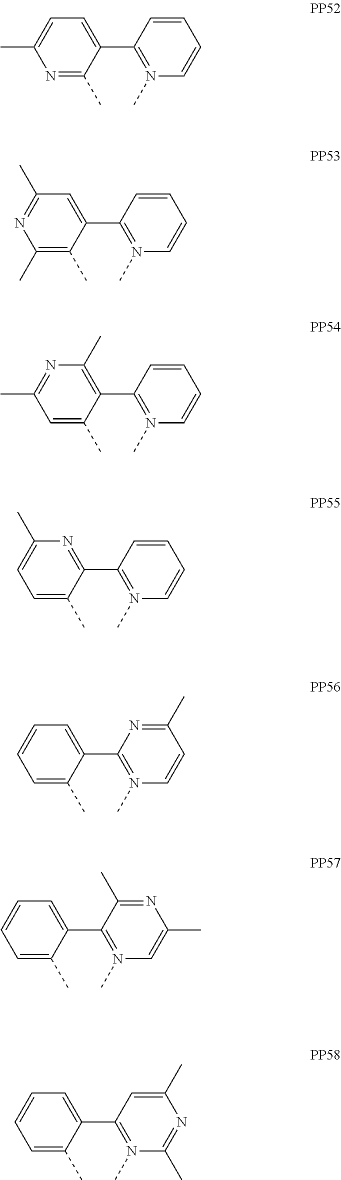

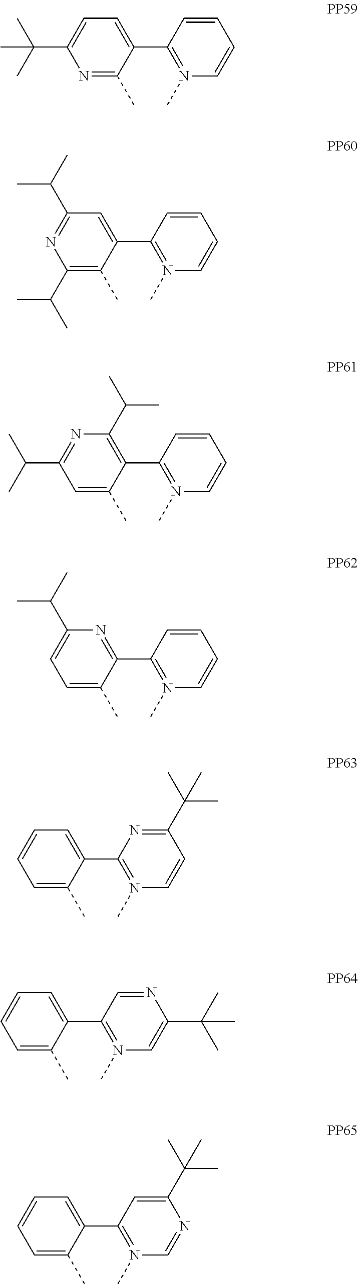

(6) The second metal complex and the third metal complex have a HOMO level difference of 0.2 eV or less and a LUMO level difference of 0.2 eV or less.

In FIG. 2, the light-emitting layer 4a contains a host (first organic compound), an assist material (second metal complex), and a dopant (first metal complex). The light-emitting layer 4b contains a host (second organic compound) and a dopant (third metal complex). Therefore, the dopant or the assist material is considered to serve as a trap level for the moving carriers (holes and electrons) in the light-emitting layer.

The second metal complex and the third metal complex preferably have a HOMO level difference of 0.2 eV or less and a LUMO level difference of 0.2 eV or less. This is because such a relationship promotes carrier transfer between the first light-emitting layer and the second light-emitting layer. That is, the second metal complex serving as the carrier trap level of the first light-emitting layer and the third metal complex serving as the carrier trap level of the second light-emitting layer have comparable HOMO levels and LUMO levels, thereby promoting carrier transfer. When there is a significant difference in the HOMO level or LUMO level between the second metal complex and the third metal complex, carriers accumulate at the interface between the first light-emitting layer and the second light-emitting layer, and the recombination zone is concentrated, which is disadvantageous to the luminous efficiency and the device durability. The promotion of carrier transfer eliminates unwanted charge accumulation and also eliminates exciton concentration. This can reduce the occurrence of TTA and improve durability characteristics.

Preferably, the relationships represented by the following formulae [f] and [g] hold:

$$\vert LUMOD 3 - LUMOD 2 \vert \leq 0.2 eV \qquad [ f ]$$

$$\vert HOMOD 3 - HOMOD 2 \vert \leq 0.2 eV \qquad [ g ]$$

where in [f] and [g], HOMOD2 is the HOMO level of the second metal complex, LUMOD2 is the LUMO level of the second metal complex, HOMOD3 is the HOMO level of the third metal complex, and LUMOD3 is the LUMO level of the third metal complex.

The relationship between formulae [f] and [g] is also advantageous in that the carrier balance between the first light-emitting layer and the second light-emitting layer can be easily adjusted.

(7) The first metal complex is a red-phosphorescent material, and the third metal complex is a green-phosphorescent material.

From the viewpoint of maximizing the luminous efficiency of each of the first light-emitting layer and the second light-emitting layer while satisfying the relationship of formulae [a] and [b], preferably, the first metal complex is a red-phosphorescent material, and the third metal complex is a green-phosphorescent material.

In the organic light-emitting device according to an embodiment of the present invention, the recombination zone is slightly biased toward the second light-emitting layer. This provides a stacked structure that allows efficient energy transfer to the first light-emitting layer and easily achieves a good balance between green light emission and red light emission.

In this specification, the blue-light-emitting material refers to a light-emitting material that exhibits an emission spectrum with a maximum peak wavelength of 430 nm to 480 nm. The green-light-emitting material refers to a light-emitting material that exhibits an emission spectrum with a maximum peak wavelength of 500 nm to 570 nm. The red-light-emitting material refers to a light-emitting material that exhibits an emission spectrum with a maximum peak wavelength of 580 nm to 680 nm. The emission spectra can be measured with the influence of other compounds and crystalline states reduced by using, for example, a dilute toluene solution.

Yellow light emission indicates that a main part of an emission spectrum is included in 565 nm to 590 nm. For example, yellow light emission can also be obtained by mixing green light emission and red light emission. Cyan light emission indicates that a main part of an emission spectrum is included in 485 nm to 500 nm. For example, cyan light emission can also be obtained by mixing blue light emission and green light emission.

(8) The second light-emitting layer contains the second organic compound (assist material) that is not a metal complex.

As described above, in the organic light-emitting device according to an embodiment of the present invention, the recombination zone is slightly biased toward the second light-emitting layer. Energy can thus be efficiently transferred to the first light-emitting layer to allow well-balanced light emission to be extracted from the light-emitting layers.

The second light-emitting layer preferably contains the second organic compound that is not a metal complex as an assist material. When the assist material in the second light-emitting layer is also a phosphorescent metal complex, due to the phenomenon described above, energy transfer between the third metal complex and the assist material in the second light-emitting layer, in other words, energy transfer in the second light-emitting layer, is promoted to inhibit energy transfer to the first light-emitting layer, which is not preferred. Preferably, the assist material in the second light-emitting layer is not a metal complex but is a material that injects hole or electron carriers into the light-emitting layer and adjusts the recombination zone slightly toward the middle of the second light-emitting layer.

Specifically, a material having any of a triarylamine skeleton, a carbazole skeleton, an azine ring, and a xanthone skeleton is preferred. These materials are preferred because they have excellent electron-donating and electron-withdrawing properties, and thus the HOMO level and the LUMO level can be easily adjusted, and the injection of carriers from the surrounding layers can be promoted.

(9) The first electrode is the anode, the second electrode is the cathode, the first light-emitting layer is adjacent to the anode, and the second light-emitting layer is adjacent to the cathode.

It is preferable that the above-mentioned condition (7) be satisfied and that, as illustrated in FIG. 2, the light-emitting layer 4a adjacent to the anode contain the host (first organic compound), the assist material (second metal complex), and the dopant (first metal complex). The light-emitting layer 4b adjacent to the cathode preferably contains the host (second organic compound) and the dopant (third metal complex). In this case, the first metal complex serving as the red-phosphorescent material traps holes, and the third metal complex serving as the green-phosphorescent material traps electrons, thus resulting in a stacked structure with the best carrier balance.

(10) The concentration of the third metal complex is higher than the concentration of the first metal complex.

In addition to the above-mentioned condition (9), the concentration of the third metal complex is preferably higher than the concentration of the first metal complex. Since the first metal complex is a red-phosphorescent material, the band gap is small; hence, the carrier trapping property is likely to be high. In this embodiment, the hole trapping property is enhanced. Thus, a high concentration of the first metal complex serving as the red-phosphorescent material is not preferred because the hole concentration in the first light-emitting layer is localized. For this reason, the carrier balance is adjusted by reducing the concentration of the first metal complex and allowing the second metal complex serving as the assist material to play the role of hole transport in the first light-emitting layer. In the second light-emitting layer, the third metal complex serves to transport electrons; thus, as described above, carriers can be smoothly transferred from and to the second metal complex. Therefore, the concentration of the third metal complex is preferably higher than the concentration of the first metal complex, and the relationship represented by the following formula [h] preferably holds:

C1D3>C1D1 [h]

where C1D1 is the concentration of the first metal complex in the light-emitting layer, and C1D3 is the concentration of the third metal complex in the light-emitting layer.

(11) The second metal complex and the third metal complex are the same compound.

As described above, in the embodiment of the present invention, carrier transfer and energy transfer between the light-emitting layers stacked are preferably good. Thus, the second metal complex and the third metal complex are preferably the same compound. In this case, carrier transfer and energy transfer between the first light-emitting layer and the second light-emitting layer can be particularly promoted.

(12) The first organic compound (host in the first light-emitting layer) and the second organic compound (host in the second light-emitting layer) are the same compound.

As described above, in the embodiment of the present invention, carrier transfer and energy transfer between the light-emitting layers stacked are preferably good. Thus, the host (first organic compound) in the first light-emitting layer and the host (second organic compound) in the second light-emitting layer are preferably the same compound. In this case, carrier transfer and energy transfer between the first light-emitting layer and the second light-emitting layer can be particularly promoted.

### First to Third Metal Complexes

The first to third metal complexes used in the organic light-emitting device according to an embodiment of the present invention will be specifically described below. The first to third metal complexes used in an embodiment of the present invention are preferably compounds represented by the following general formula [I].

Ir(L)_{q}(L′)ᵣ(L″)ₛ [I]

In general formula [1], L, L′, and L″ are different bidentate ligands from one another.

q is an integer of 1 to 3, and r and s are each an integer of 0 to 2, provided that q+r+s=3. When r is 2, a plurality of L′ may be the same or different. When s is 2, a plurality of L″ may be the same or different.

The partial structure Ir(L)_{q} is a structure represented by the following general formulae [Ir-1] to [Ir-16].

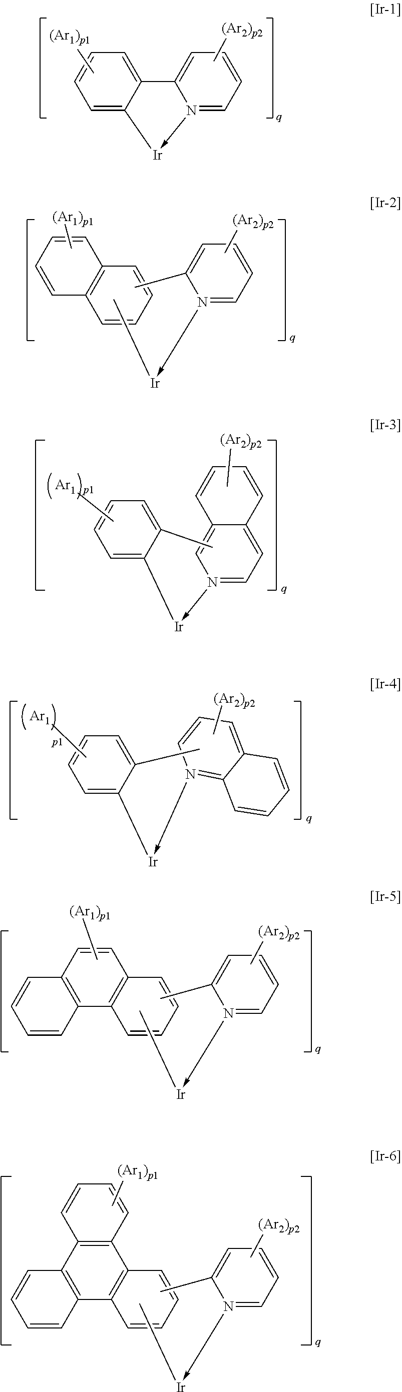

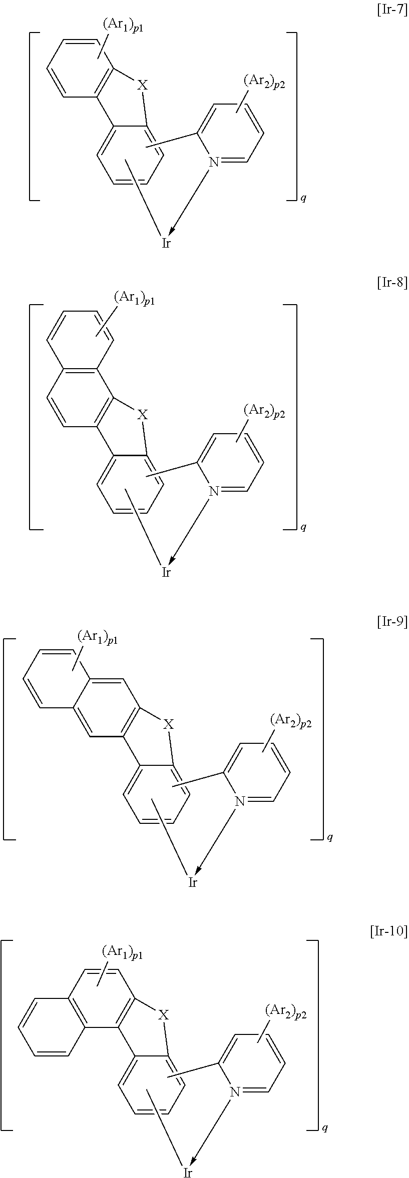

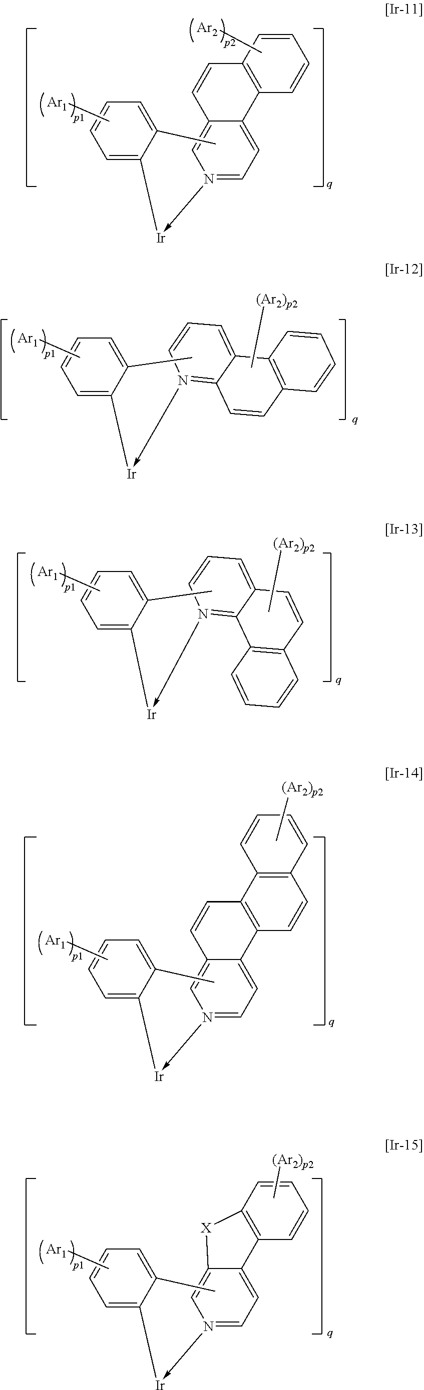

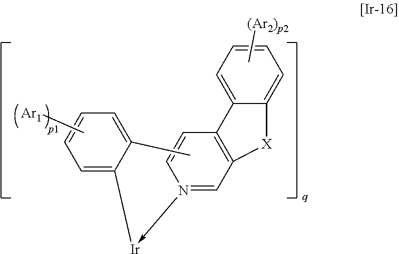

In each of general formulae [Ir-1] to [Ir-16], Ar₁ and Ar₂ are each independently a deuterium atom, a halogen atom, a substituted or unsubstituted alkyl group, a substituted or unsubstituted alkoxy group, a substituted or unsubstituted aryl group, a substituted or unsubstituted heterocyclic group, a substituted or unsubstituted silyl group, or a cyano group. Specifically, Ar₁ and Ar₂ are each preferably a deuterium atom, a fluorine atom, an alkyl group having 1 to 6 carbon atoms, an alkoxy group having 1 to 4 carbon atoms, an aryl group having 6 to 10 carbon atoms, an alkyl group-substituted silyl group, or a cyano group, more preferably a methyl group, a tert-butyl group, or a phenyl group.

p1 and p2 are each independently an integer of 0 to 4.

In general formulae [Ir-5] to [Ir-16], each X is selected from an oxygen atom, a sulfur atom, C(R₁)(R₂), or NR₃.

R₁ to R₃ are each independently selected from a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, and a cyano group. R₁ and R₂ may be taken together to form a ring. Specifically, R₁ to R₃ are each preferably an alkyl group having 1 to 3 carbon atoms or a phenyl group, more preferably a methyl group.

As mentioned above, each metal complex used in an embodiment of the present invention is a dopant or assist material. The metal complex particularly preferably has a skeleton in which carrier transfer and energy transfer occurs easily. Thus, the intermolecular distance is reduced by using a highly planar compound containing a ligand having a fused-ring structure. This is because highly planar partial structures easily approach each other. Thus, energy transfer by the Dexter mechanism occurs easily, so that the organic light-emitting device having high driving durability and highly efficient light emission characteristics can be provided. Specifically, the metal complexes represented by general formulae [Ir-5] to [Ir-16] are preferably used.

More specifically, each of the first to third metal complexes more preferably has a triphenylene skeleton, a phenanthrene skeleton, a fluorene skeleton, a benzofluorene skeleton, a dibenzofuran skeleton, a dibenzothiophene skeleton, a benzoisoquinoline skeleton, or a naphthoisoquinoline skeleton in its ligand. By using a metal complex having at least one of these skeletons in its ligand, the organic compound according to the present embodiment can provide an organic light-emitting device with improved luminous efficiency.

Specific examples of the first to third metal complexes according to the present embodiment are illustrated below. However, the present invention is not limited thereto. In each of the structural formulae below, both of the two bonds between the ligand and the iridium atom may be represented by solid lines. In such cases, one of the bonds may be a covalent bond, and the other bond may be a coordinate bond. When solid lines and dotted lines are mixed, the solid lines may represent covalent bonds, and the dotted lines may represent coordinate bonds. Among the following specific examples, JJ1 to JJ30 are specific examples of general formulae [Ir-1] to [Ir-4], and the others are specific examples of general formulae [Ir-5] to [Ir-16].

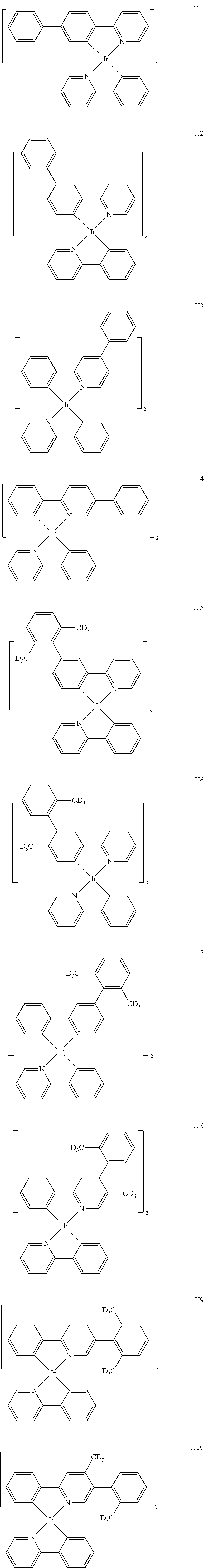

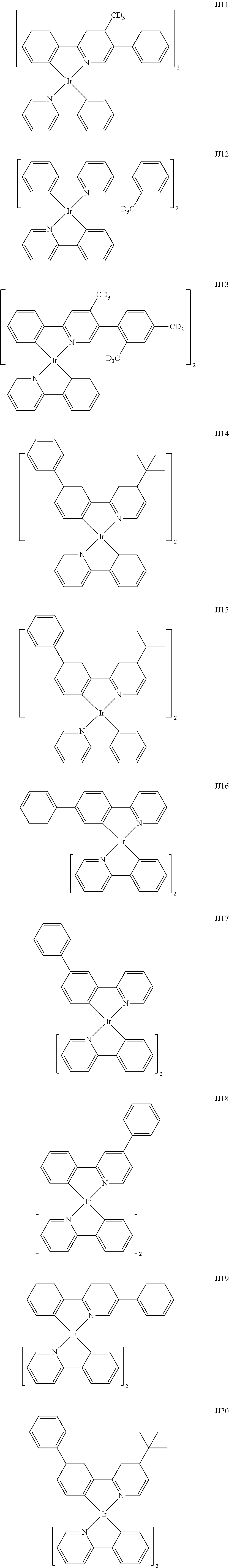

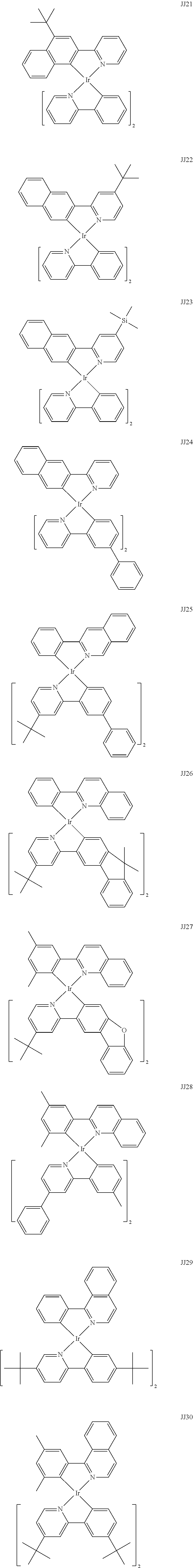

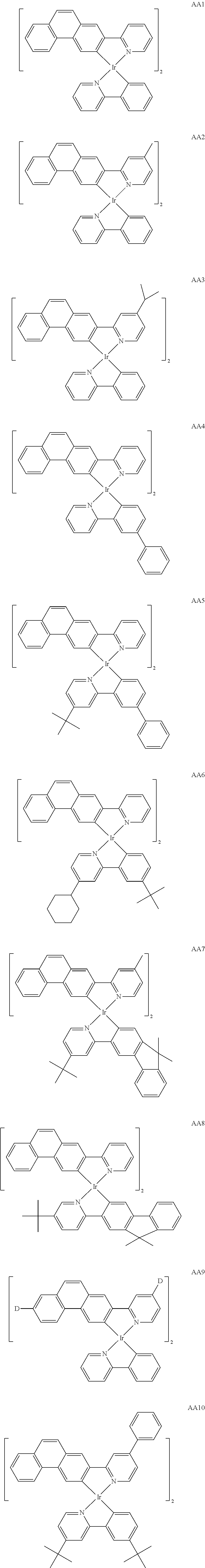

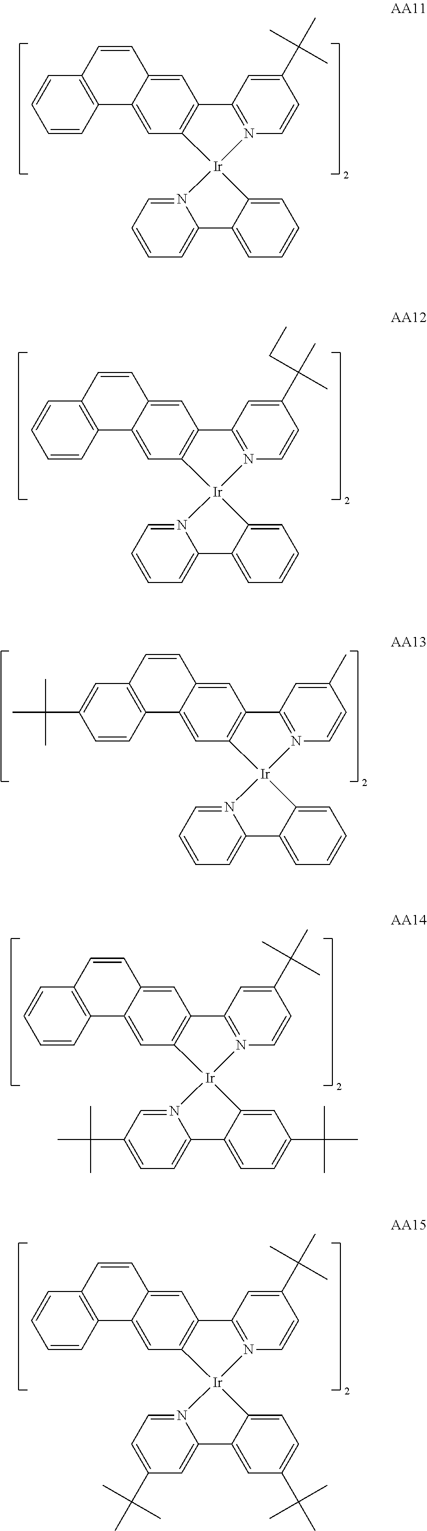

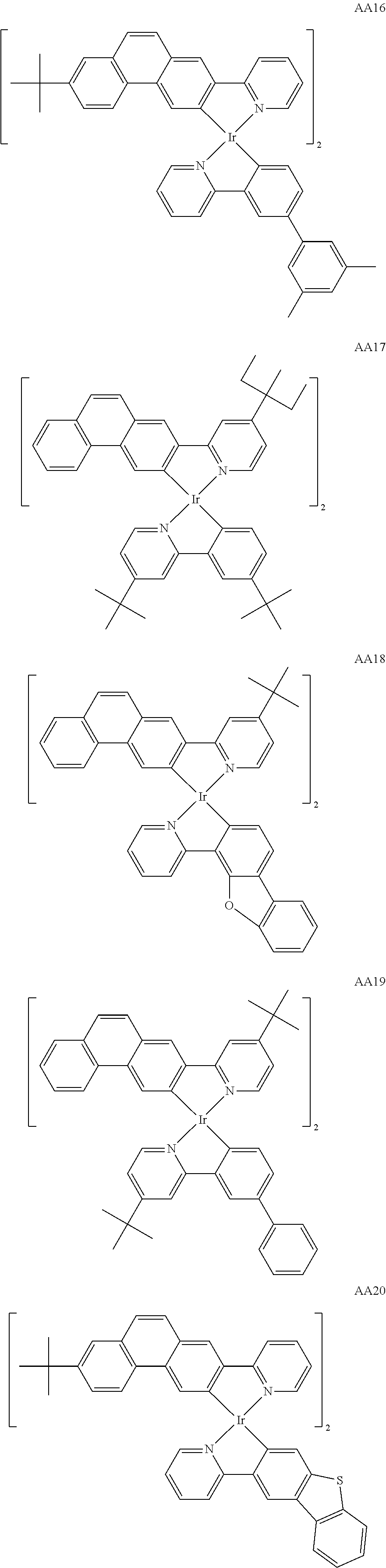

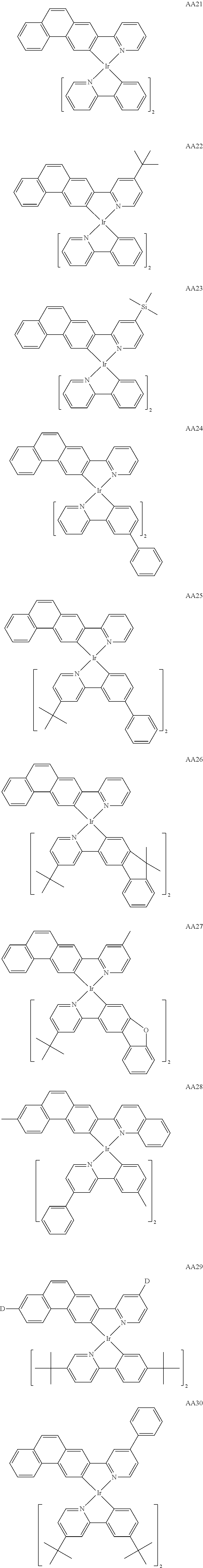

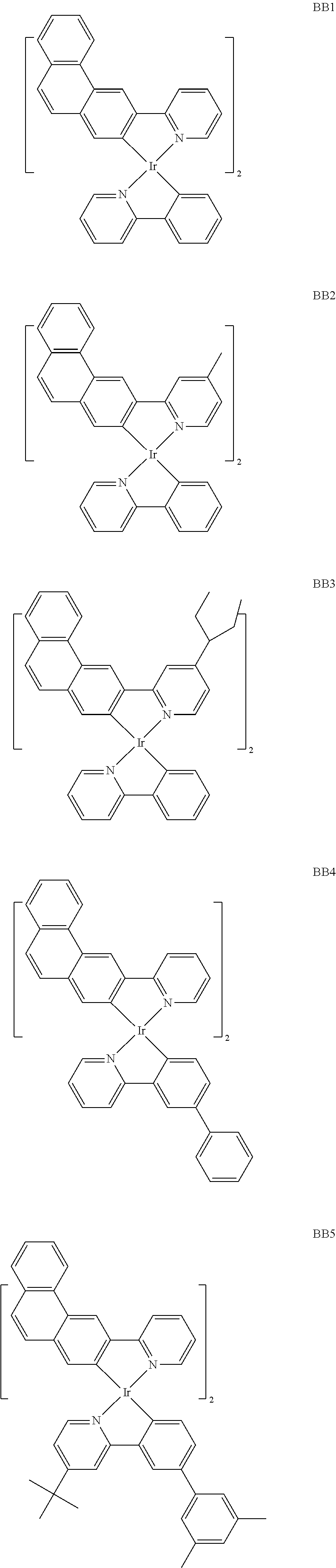

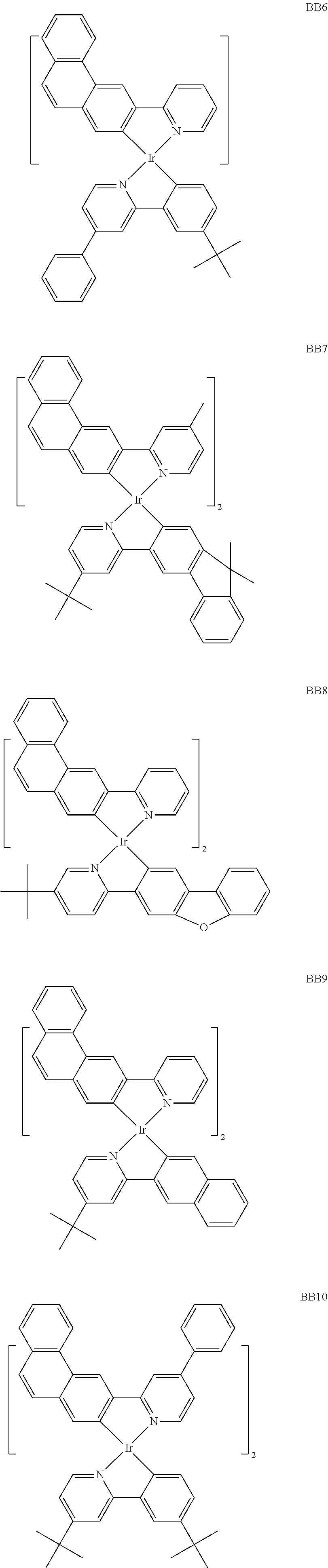

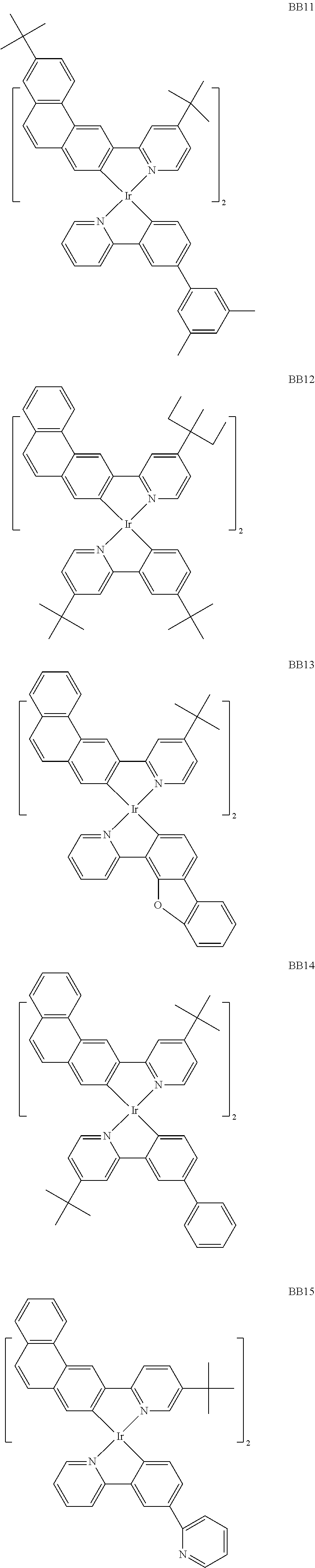

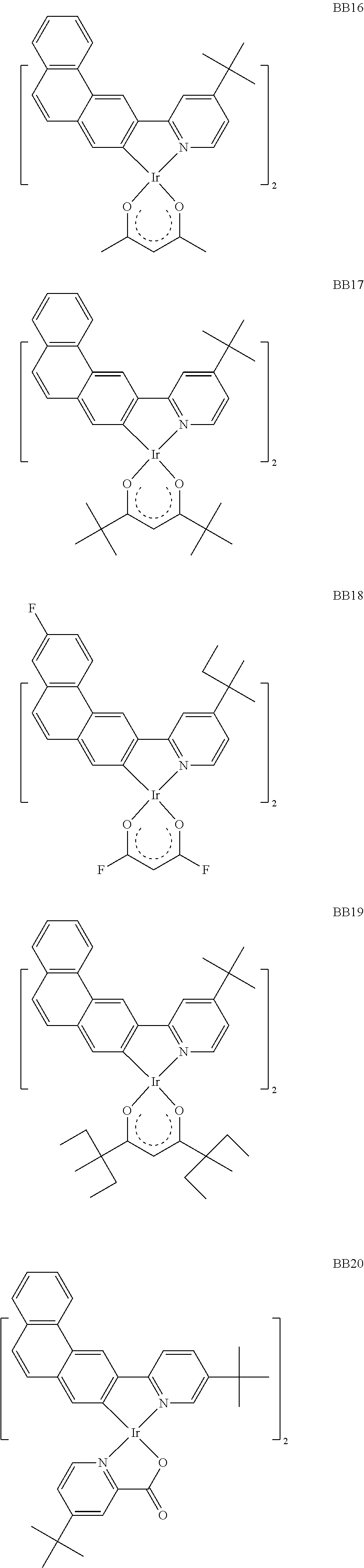

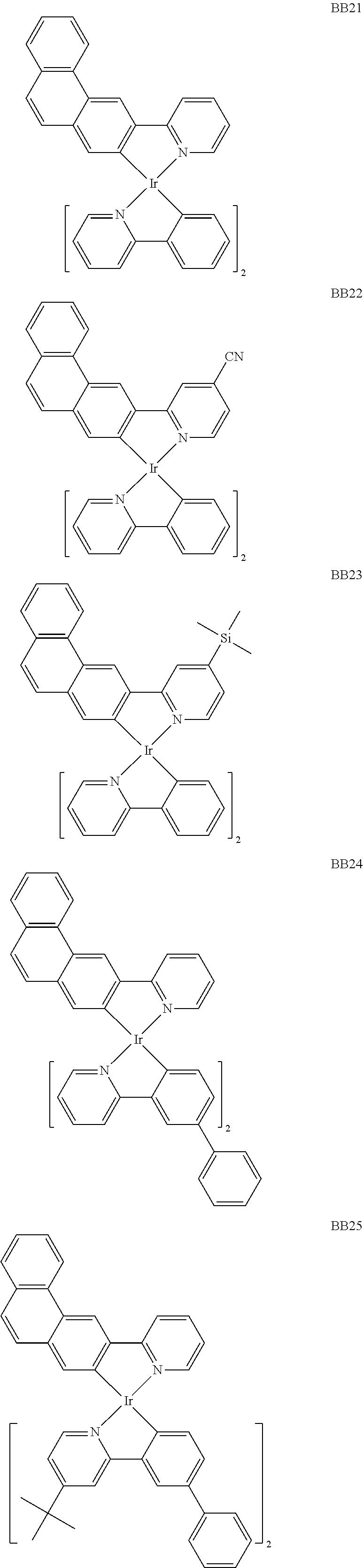

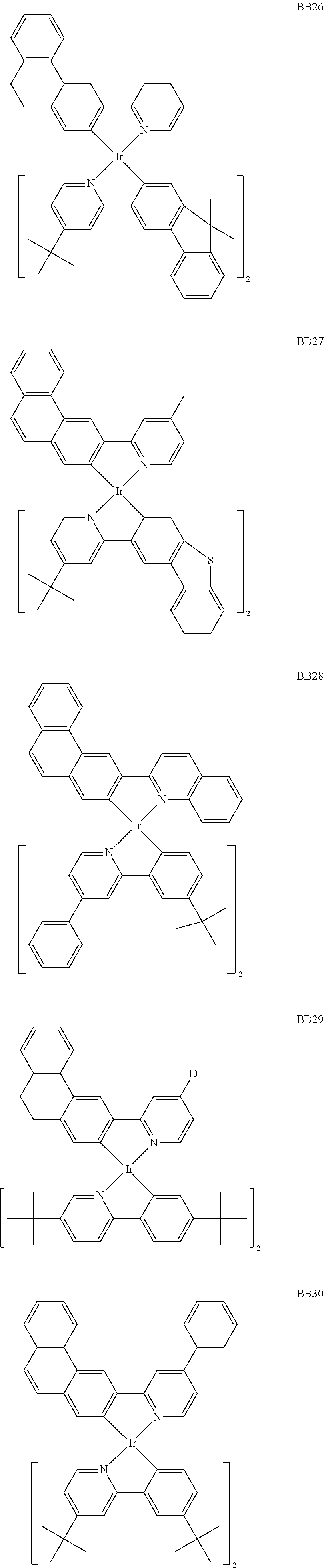

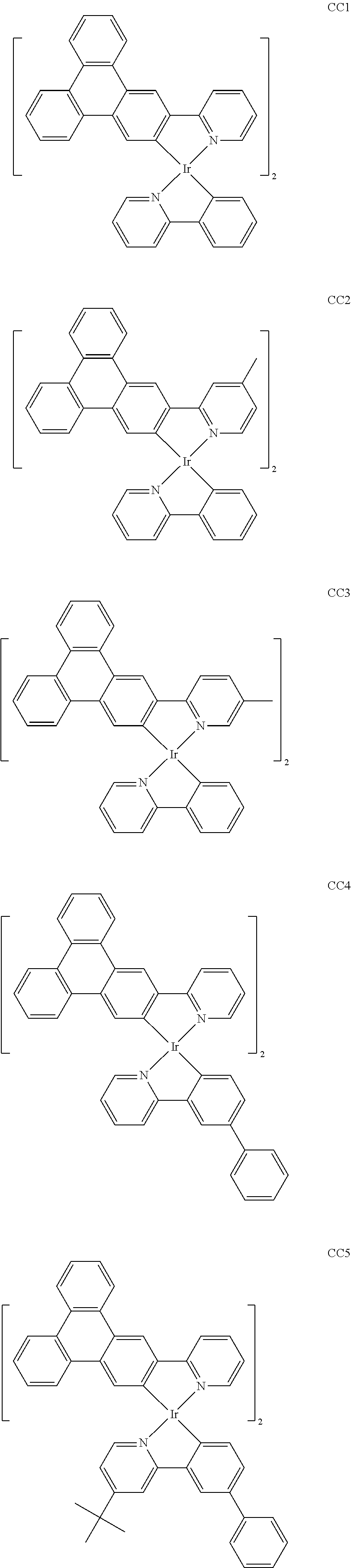

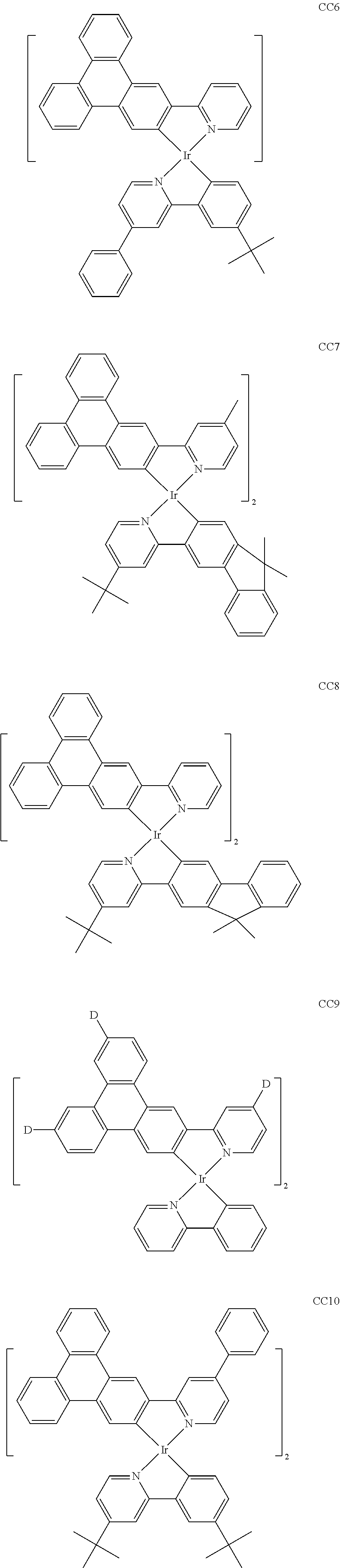

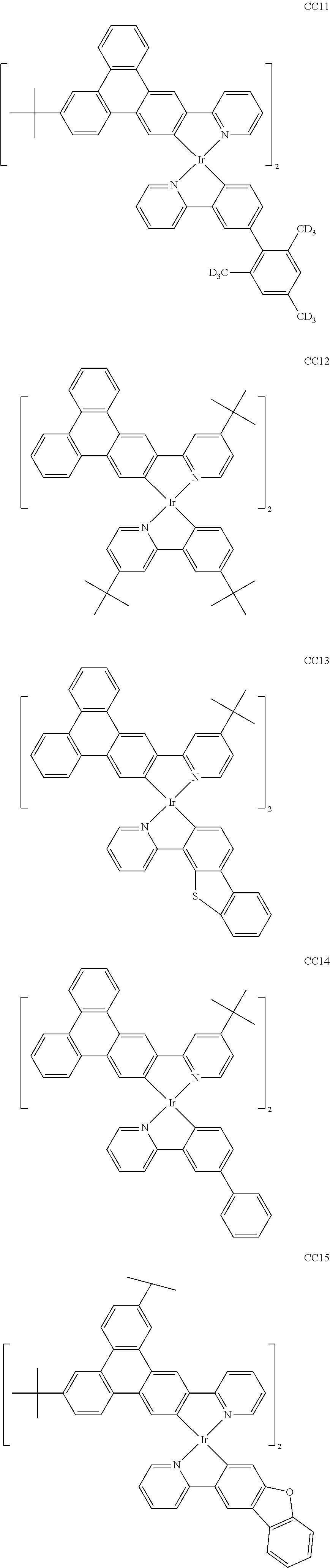

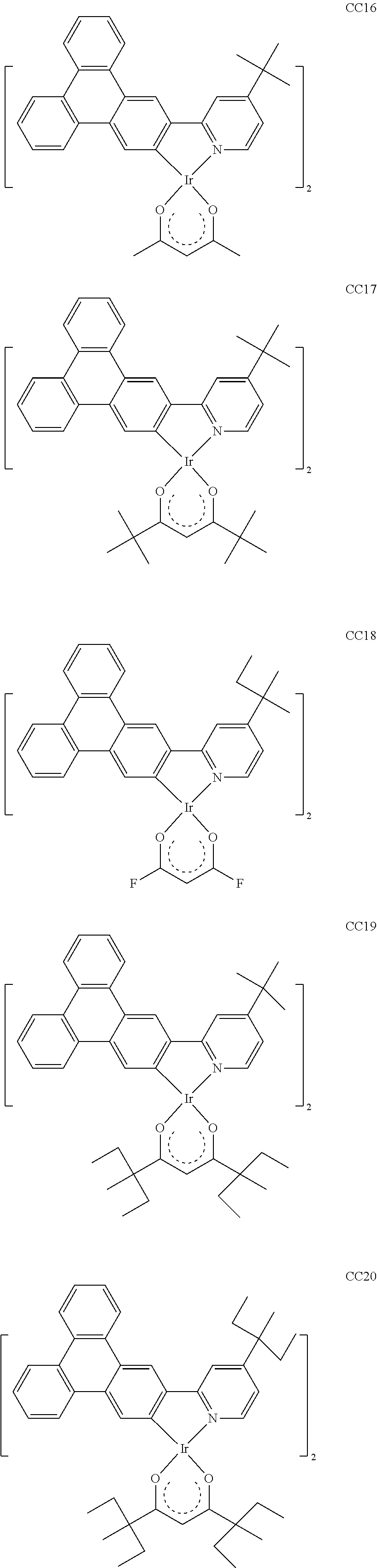

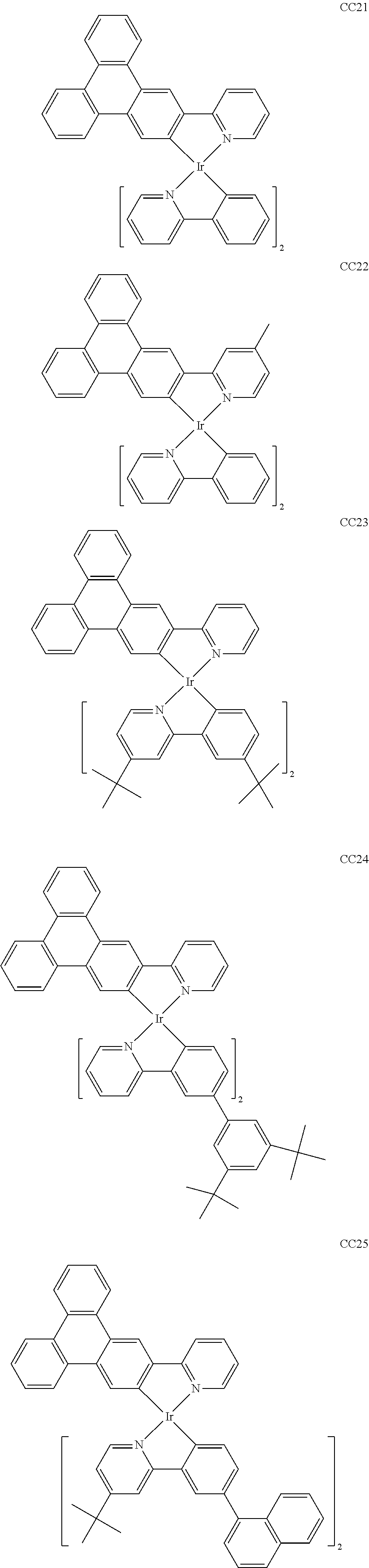

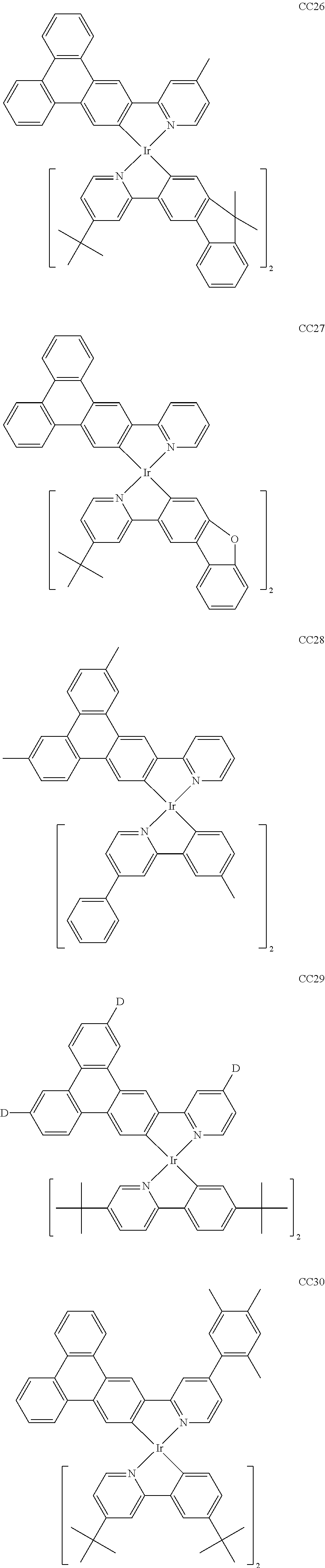

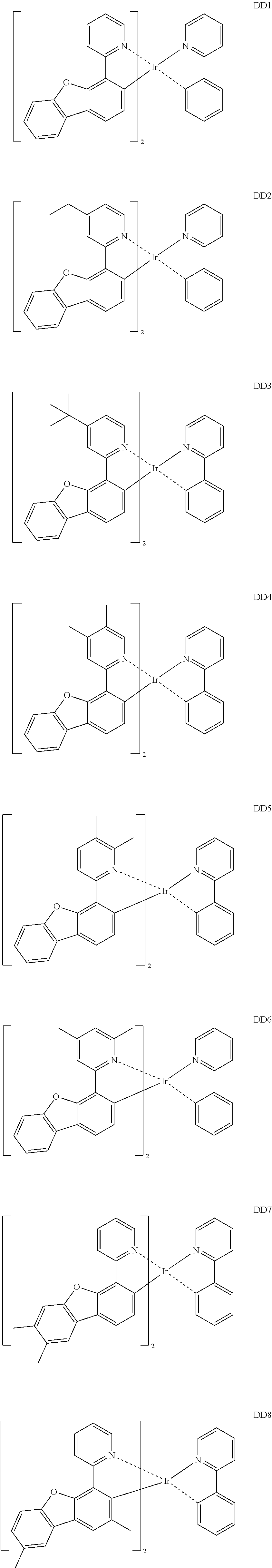

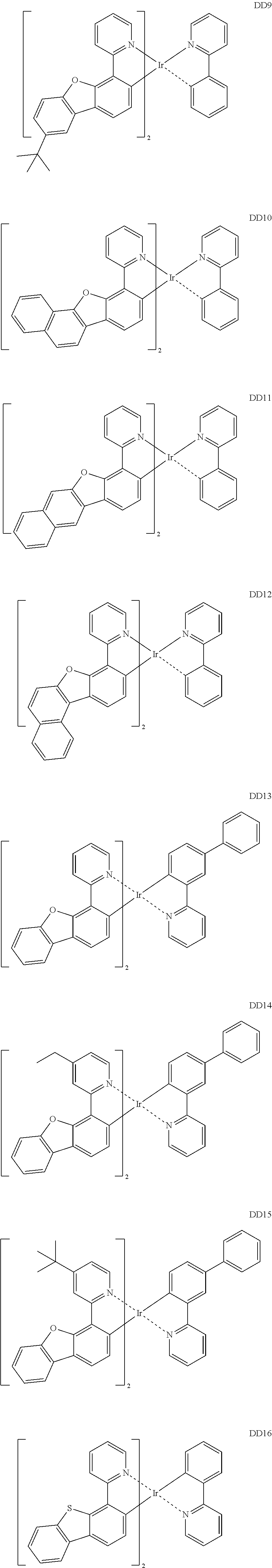

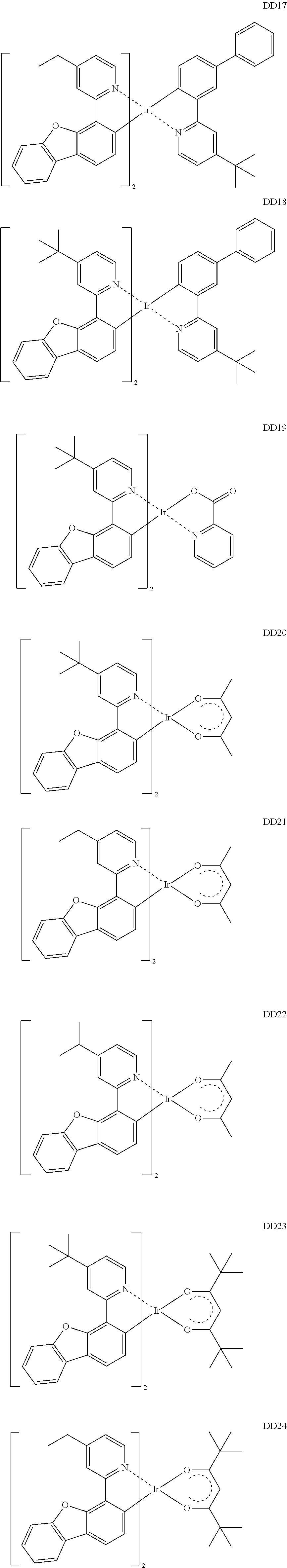

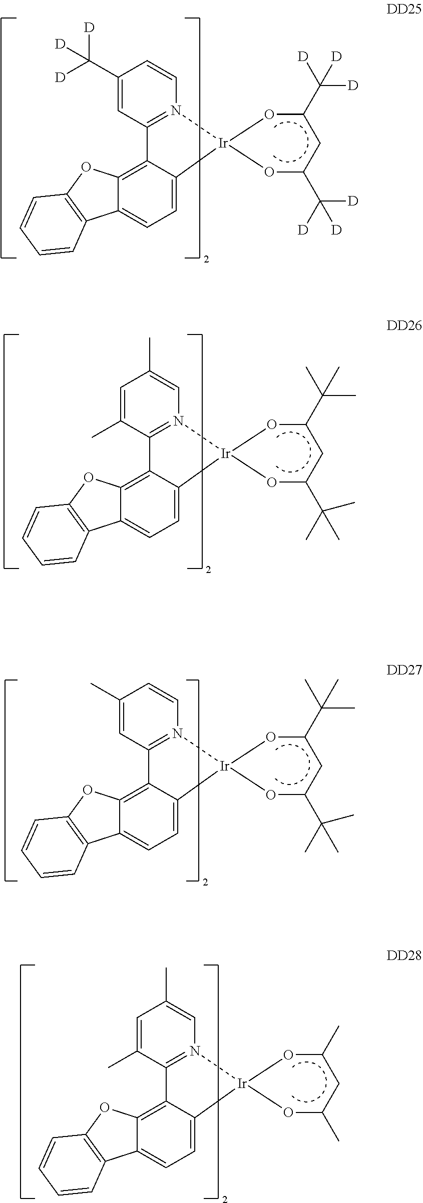

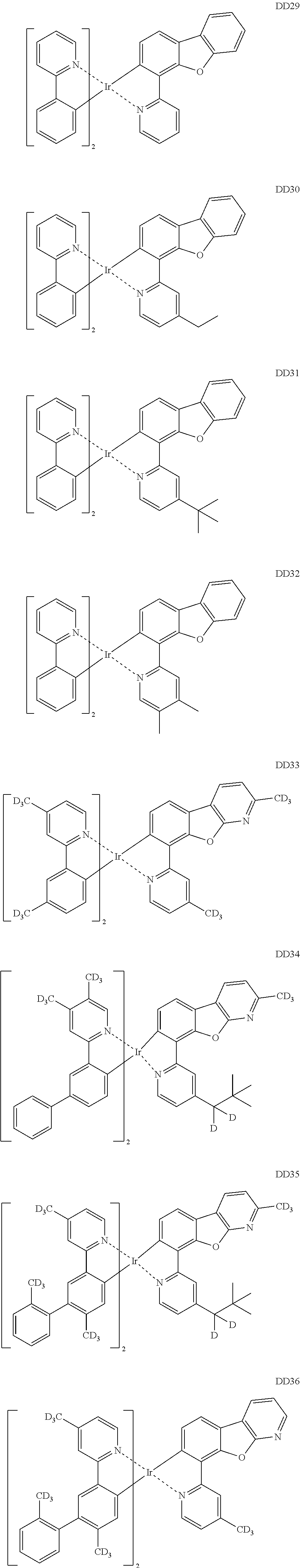

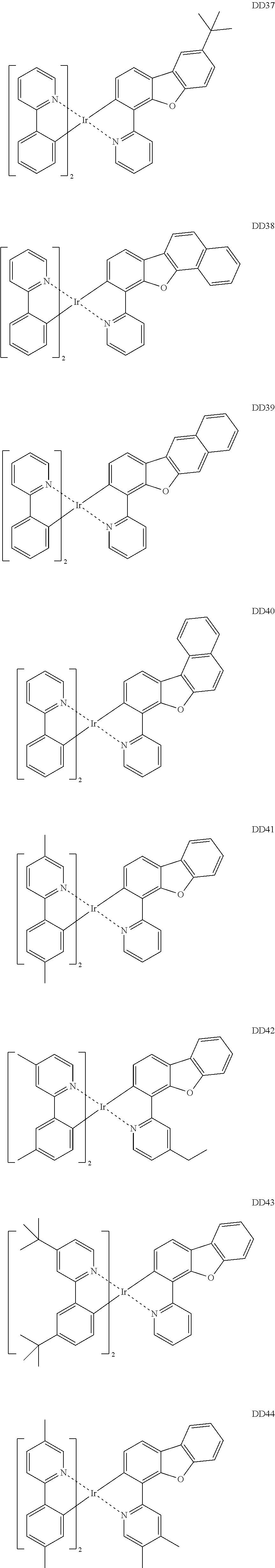

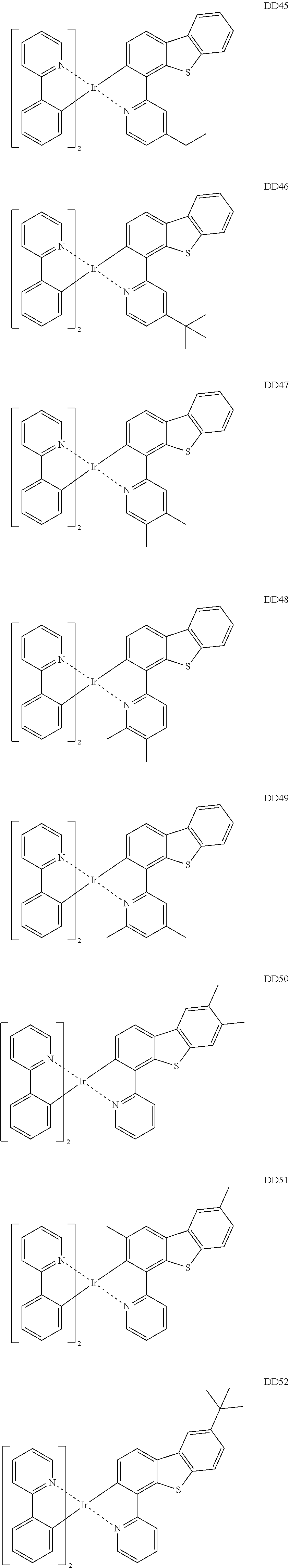

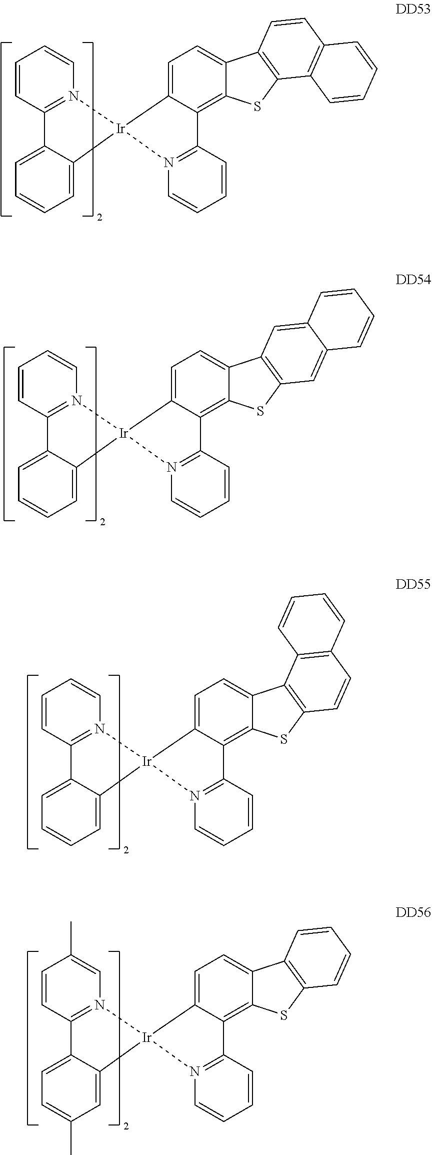

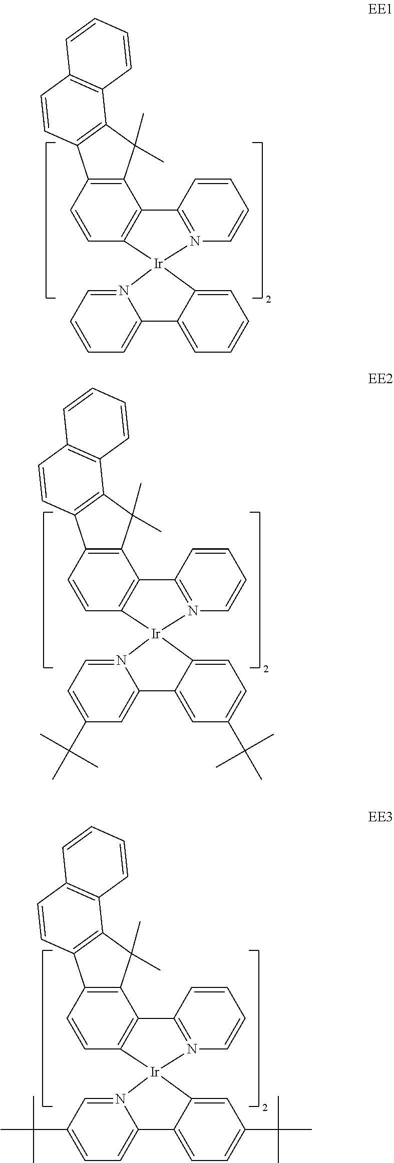

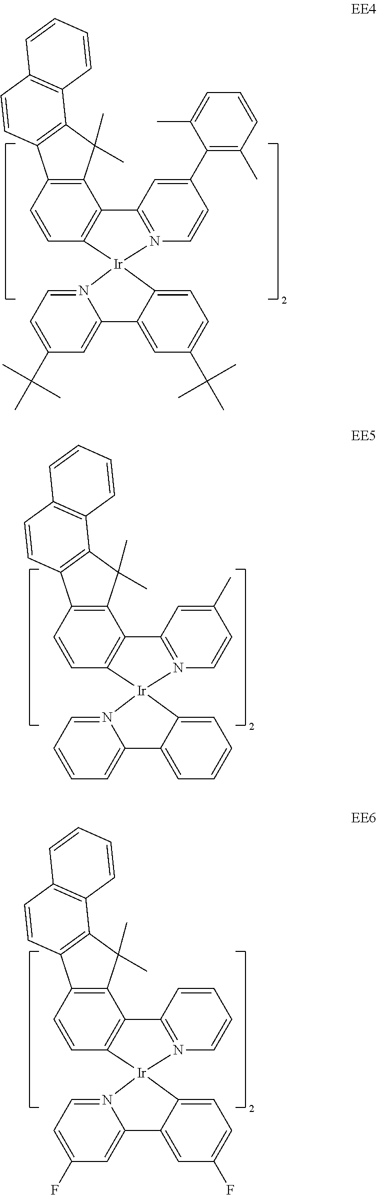

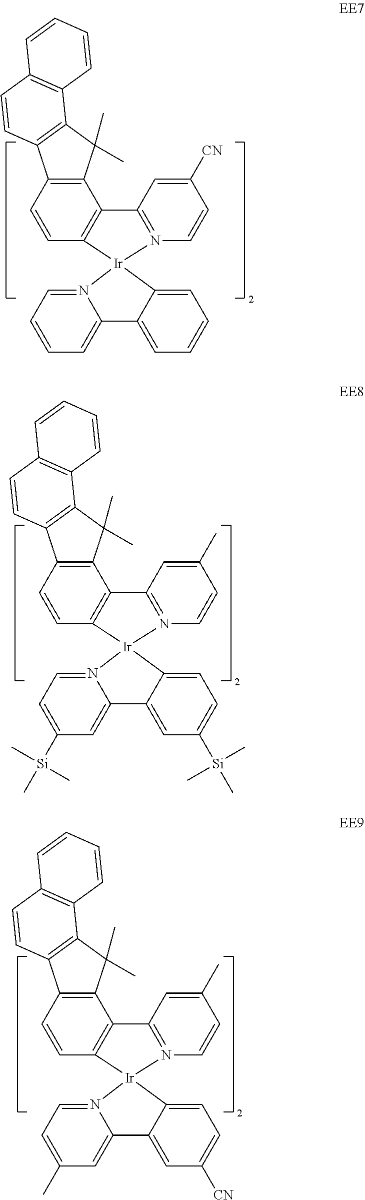

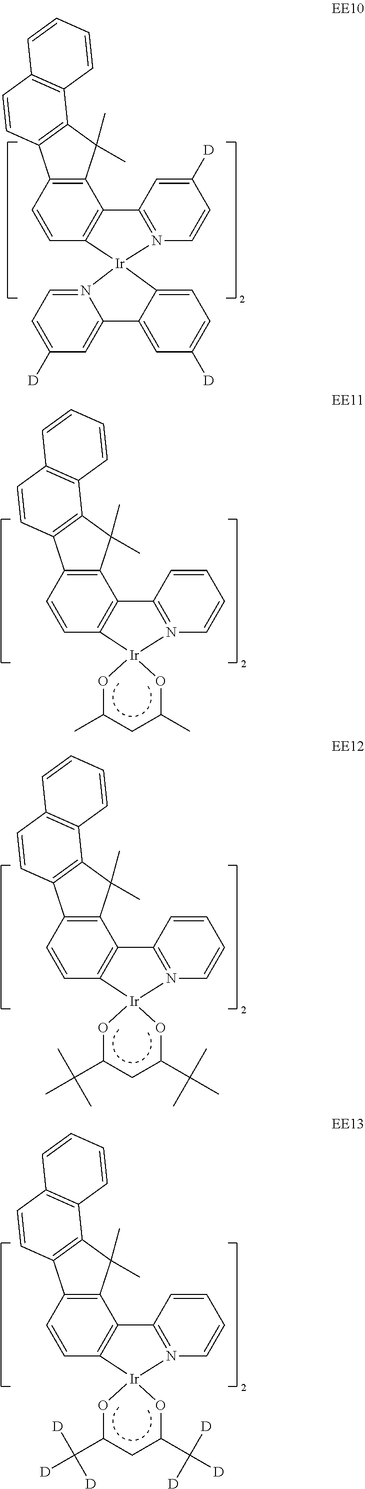

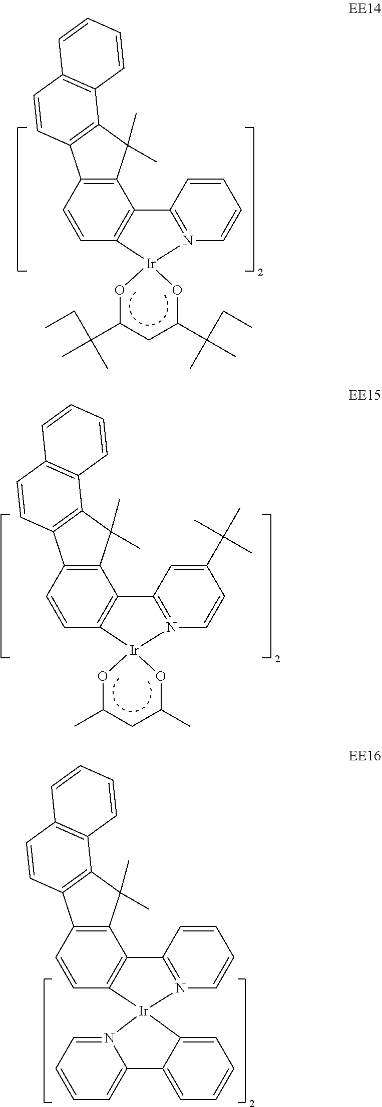

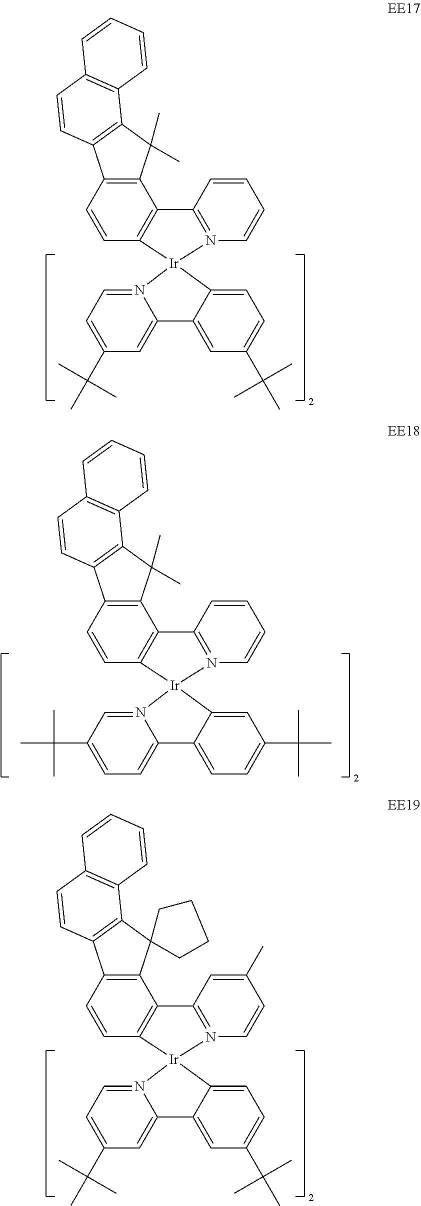

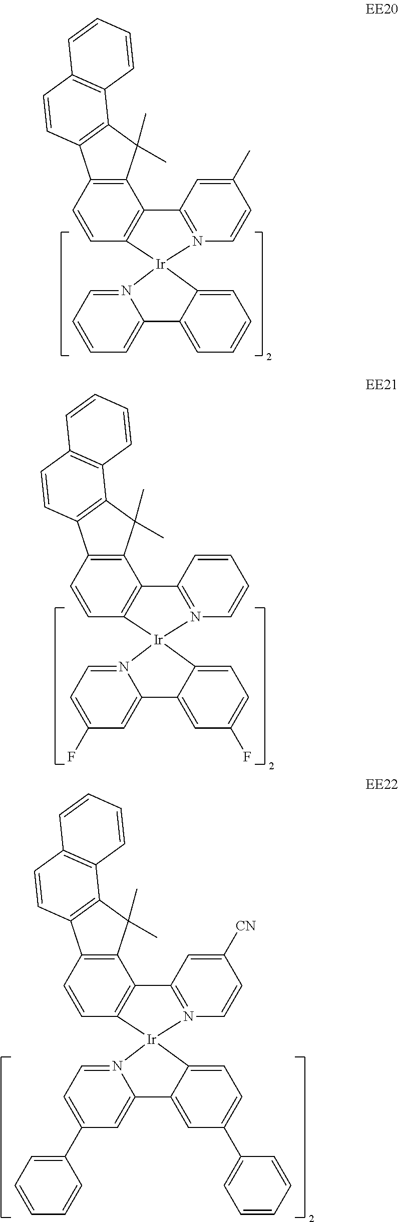

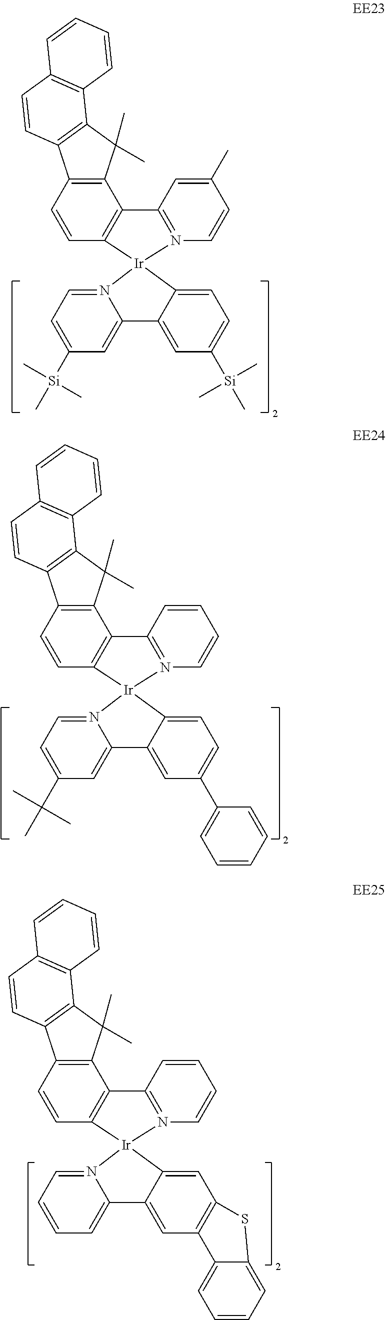

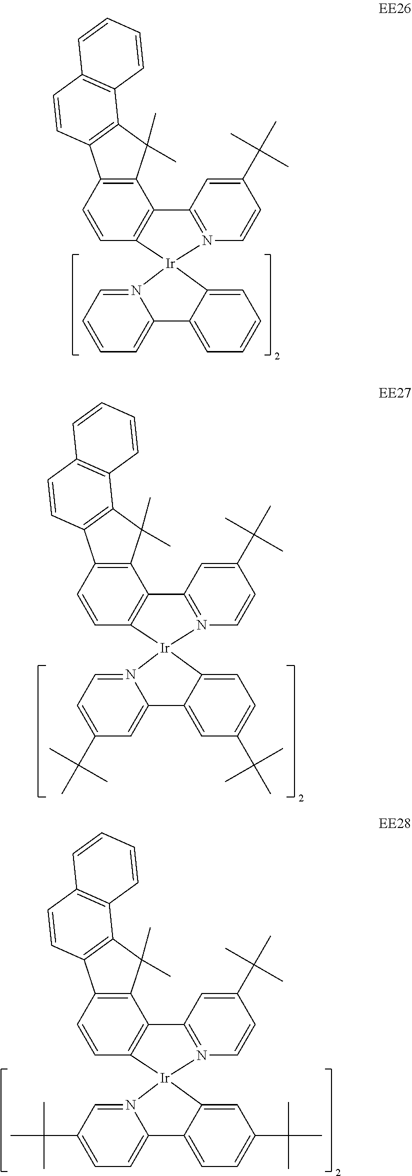

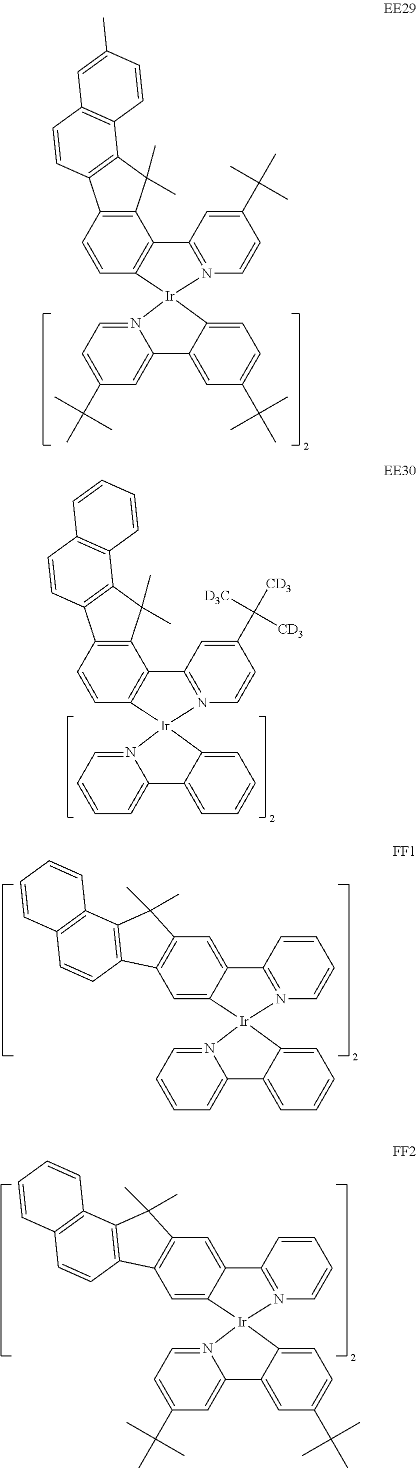

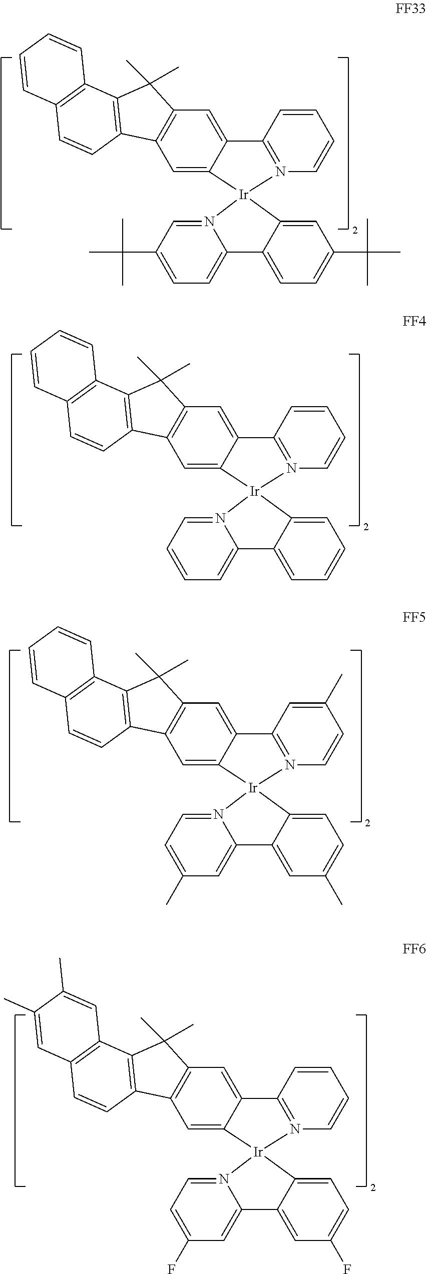

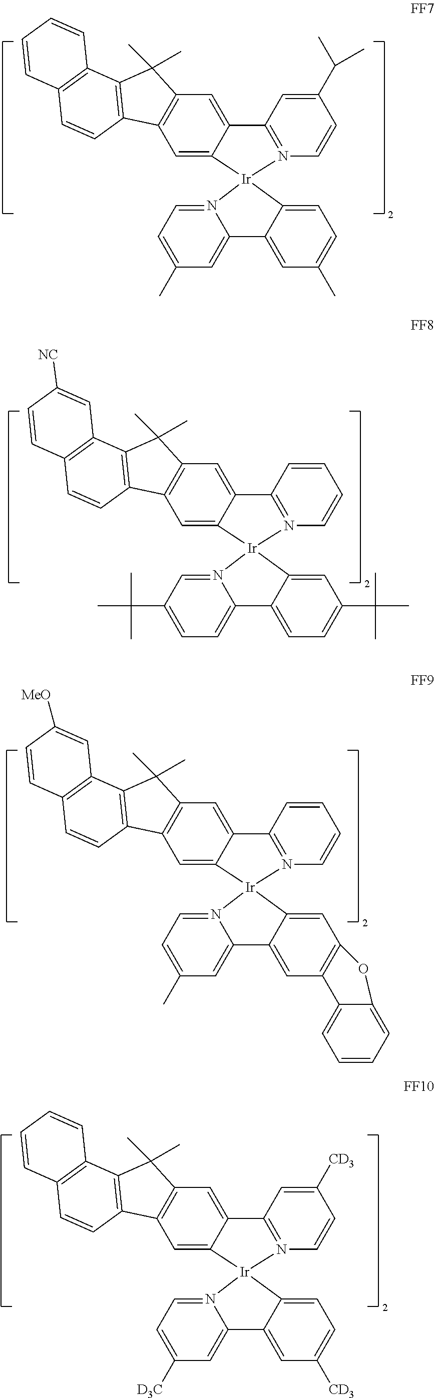

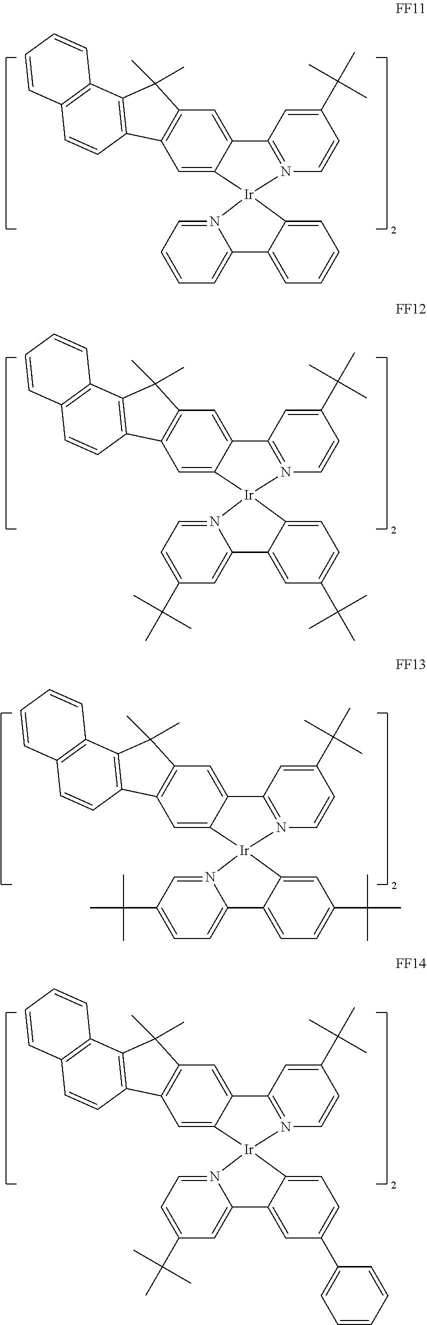

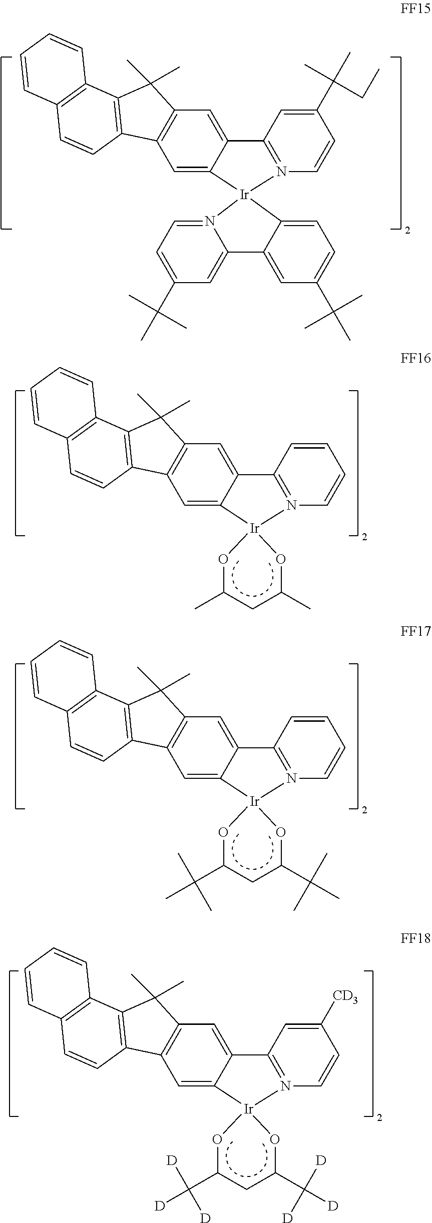

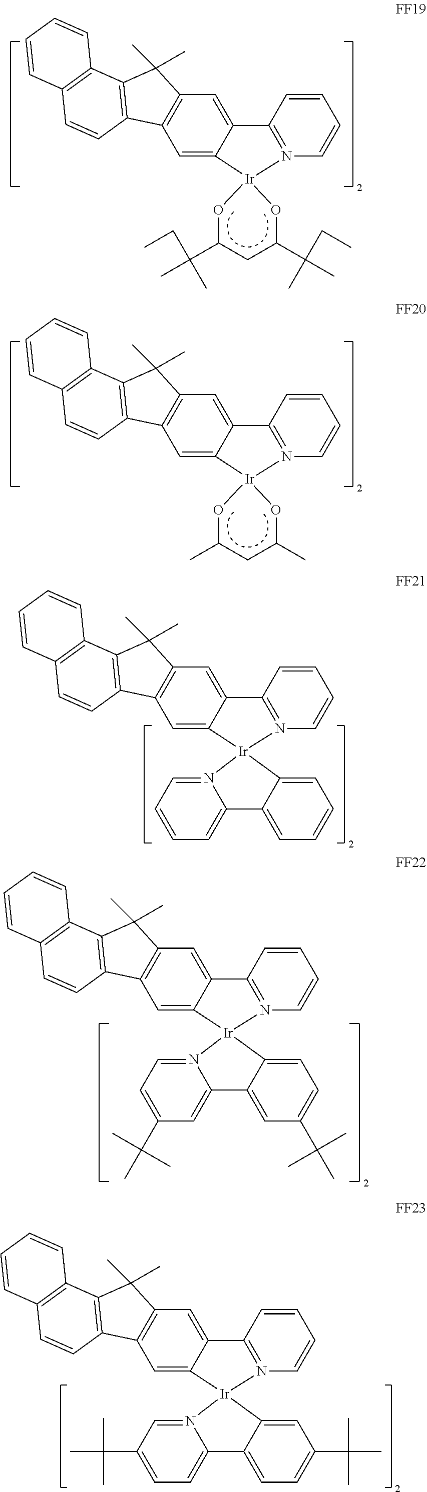

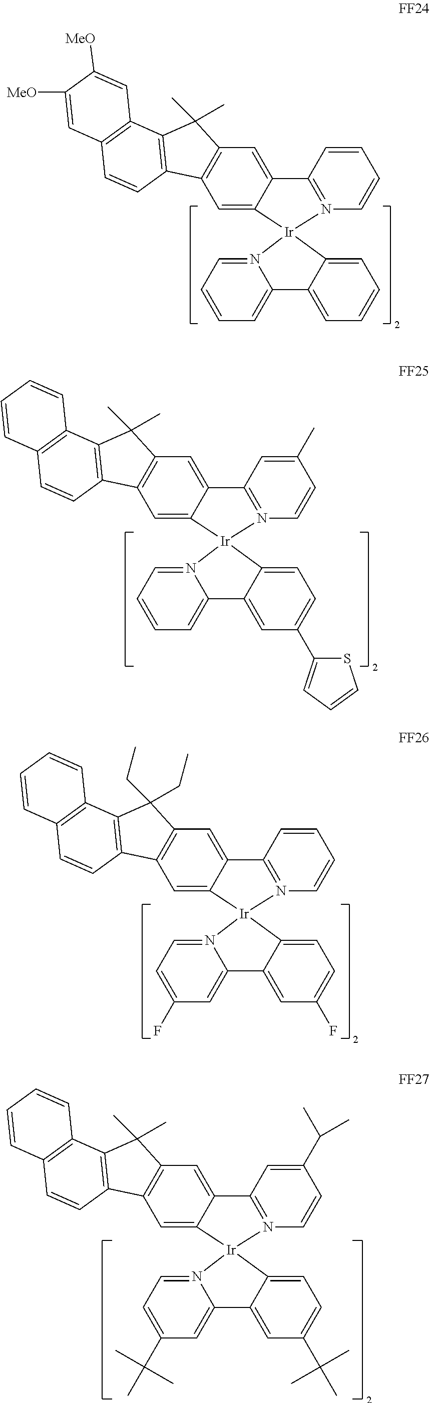

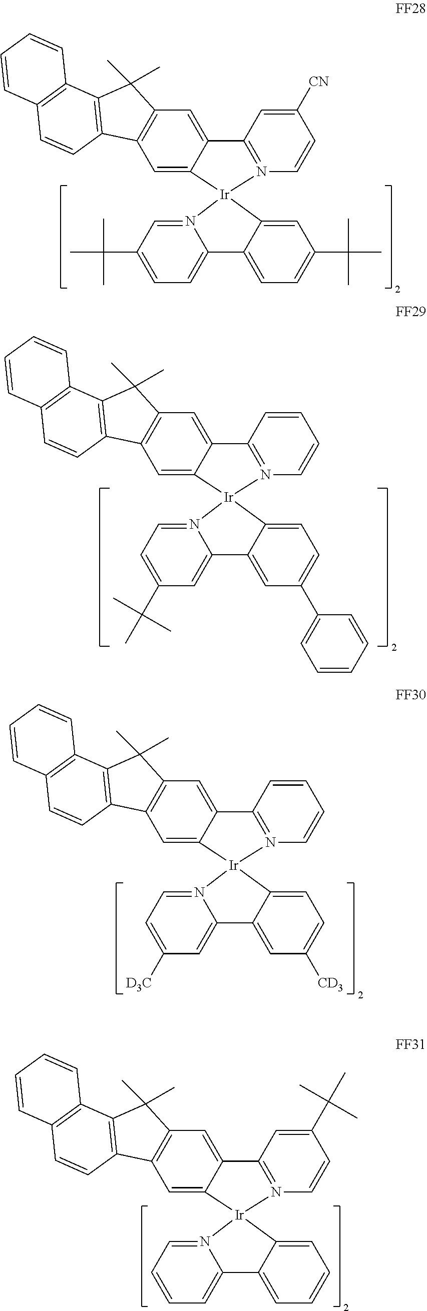

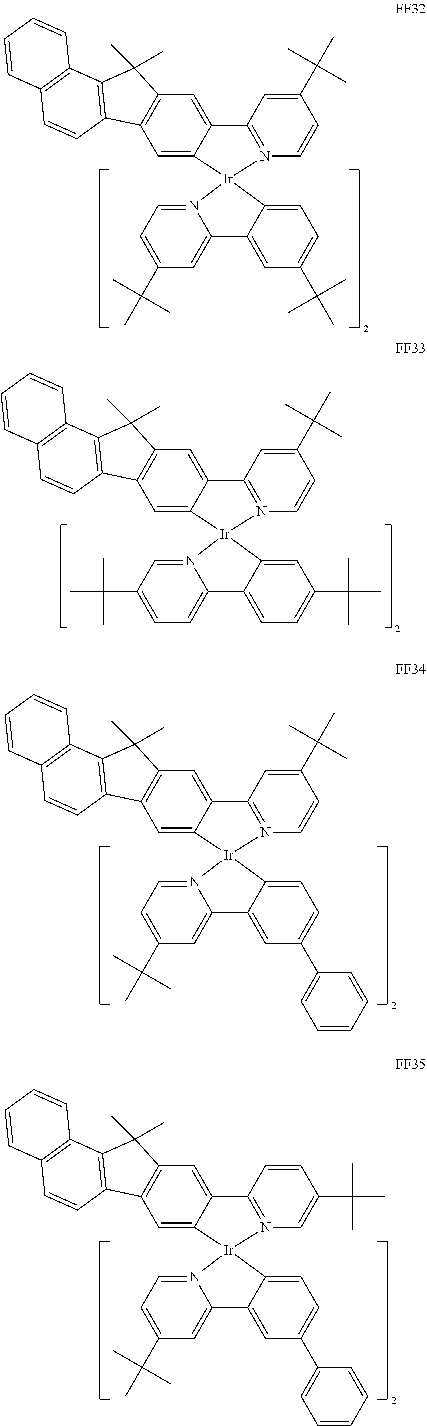

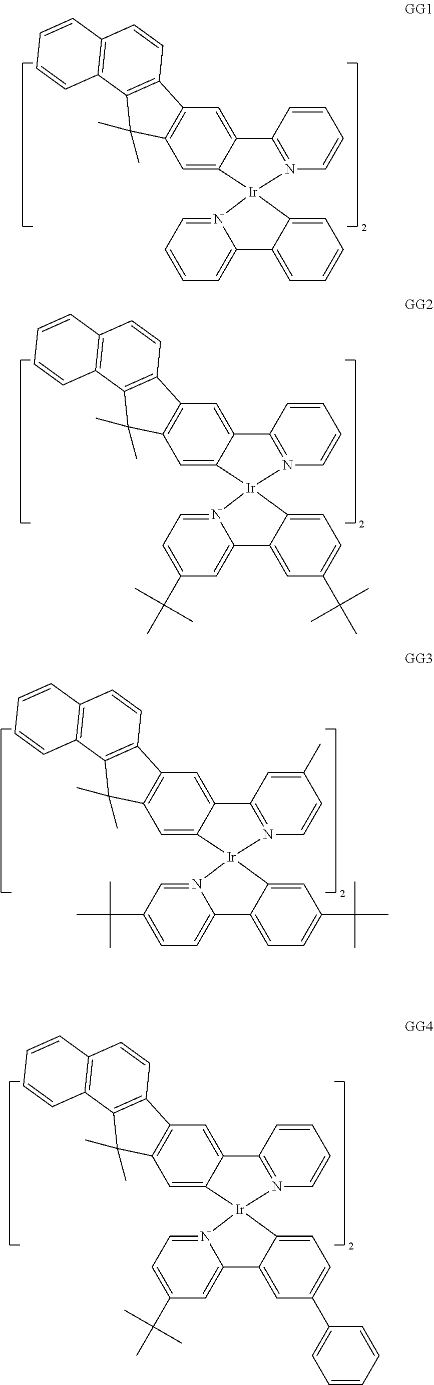

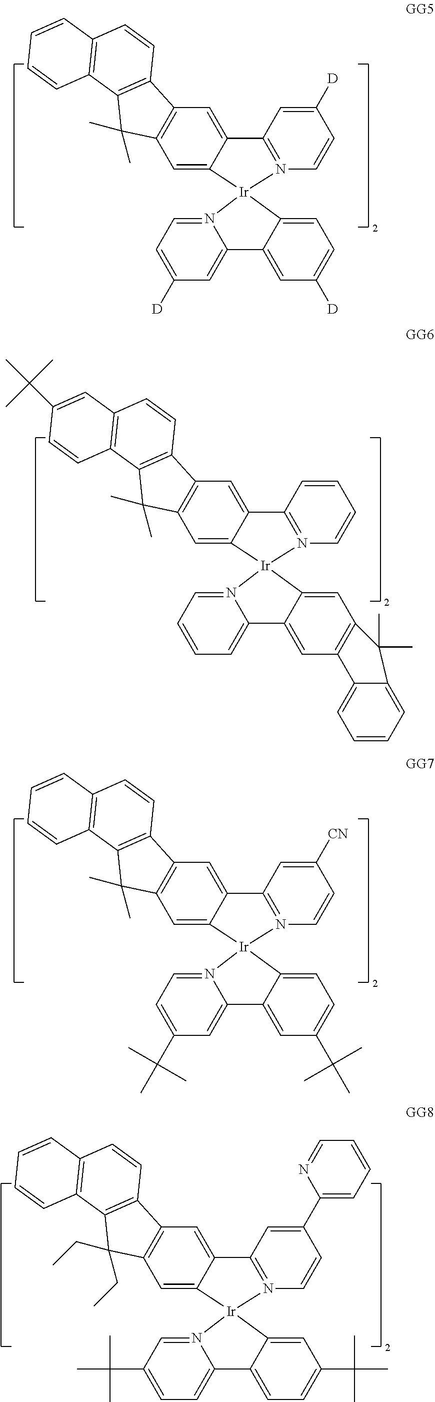

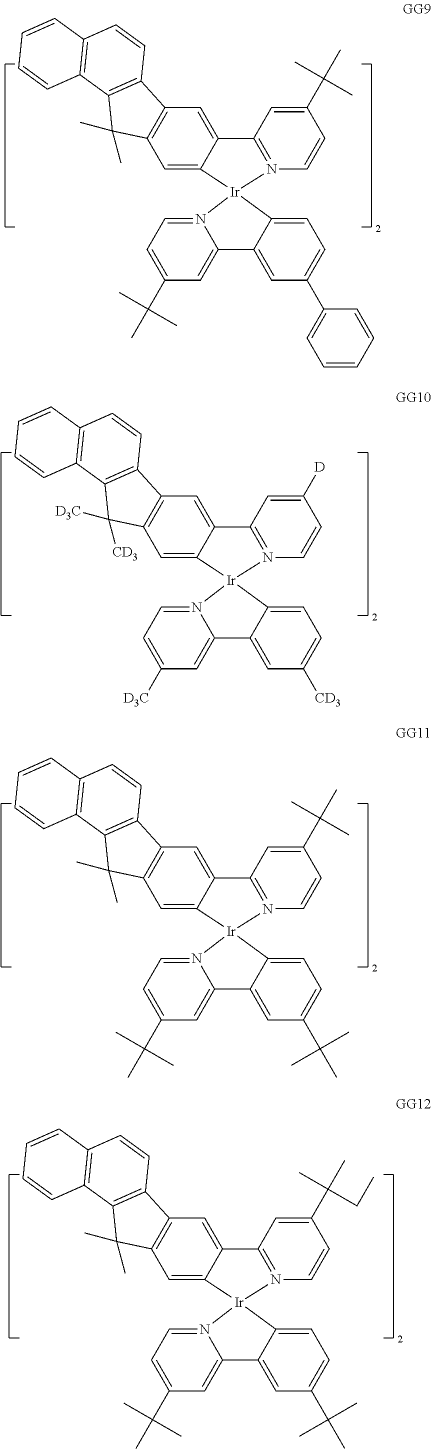

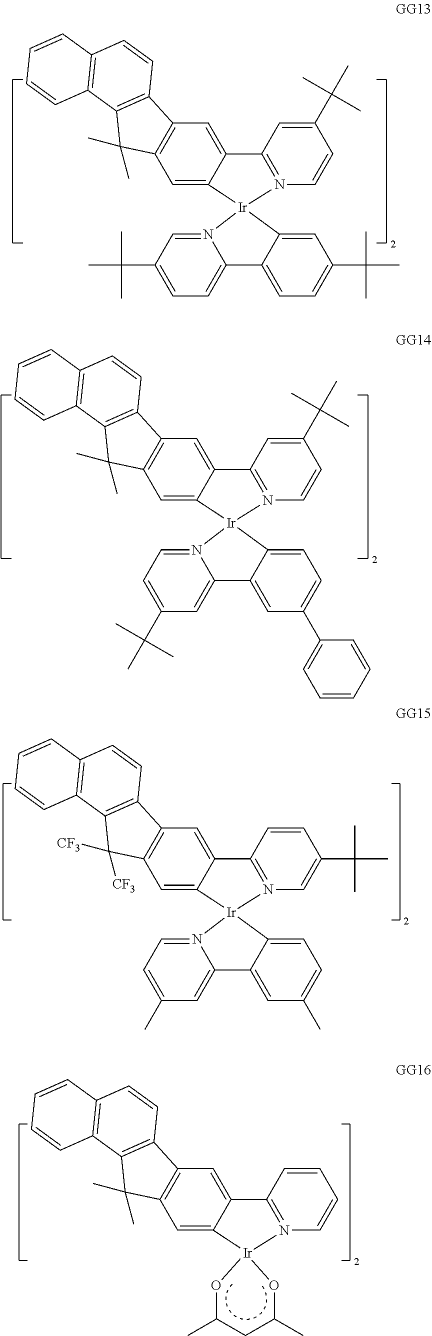

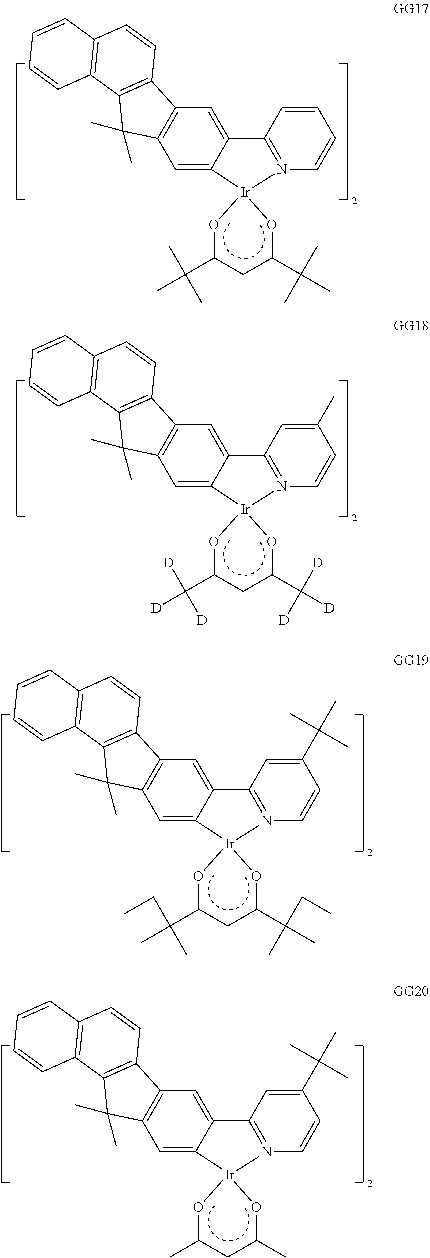

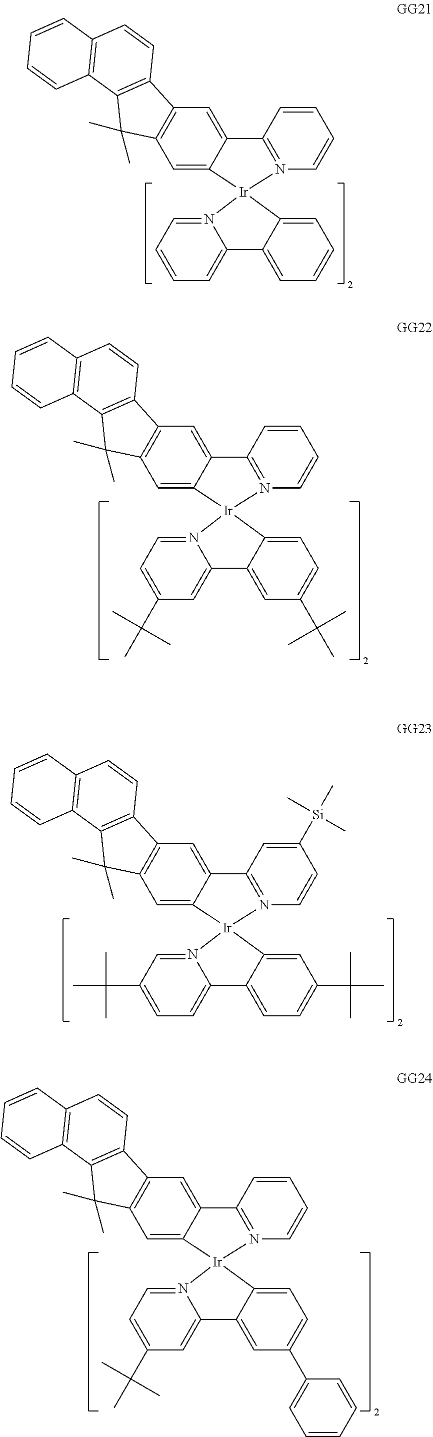

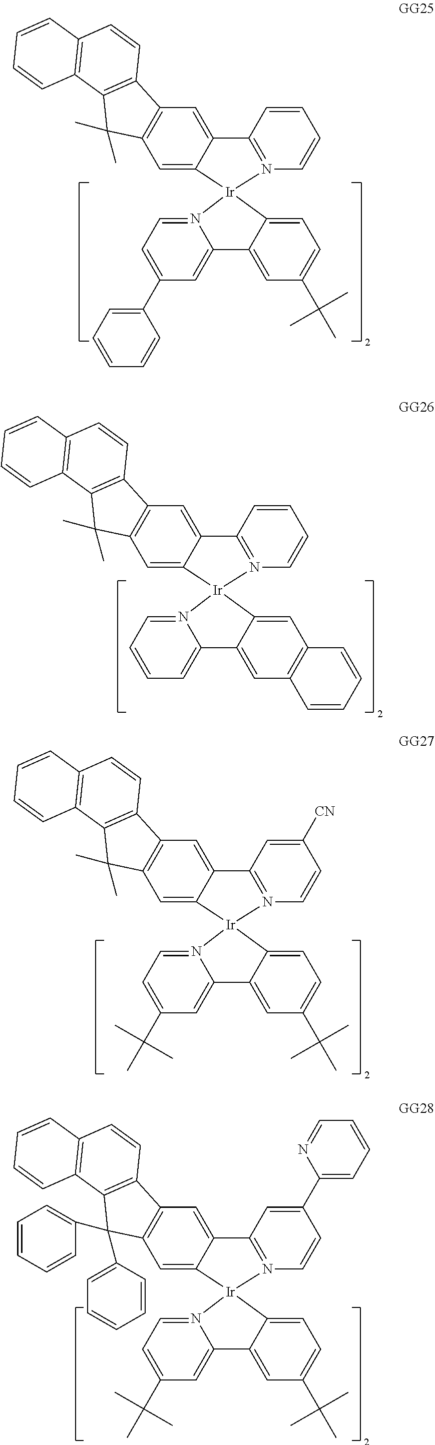

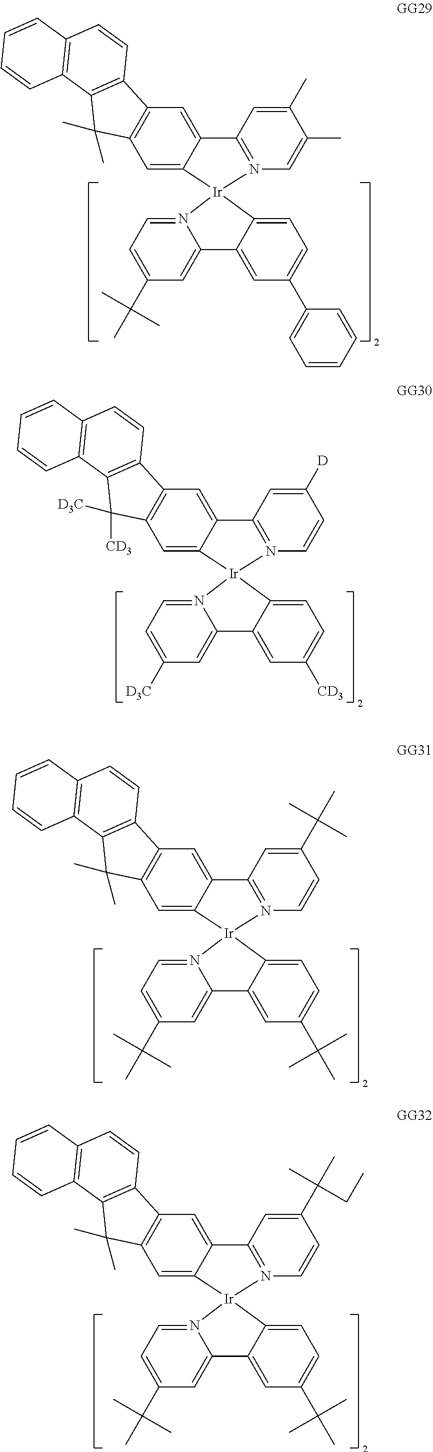

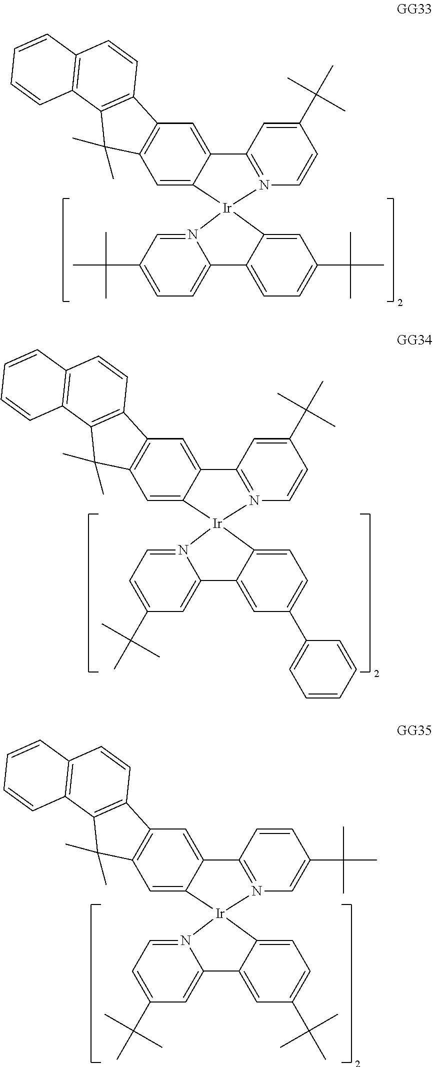

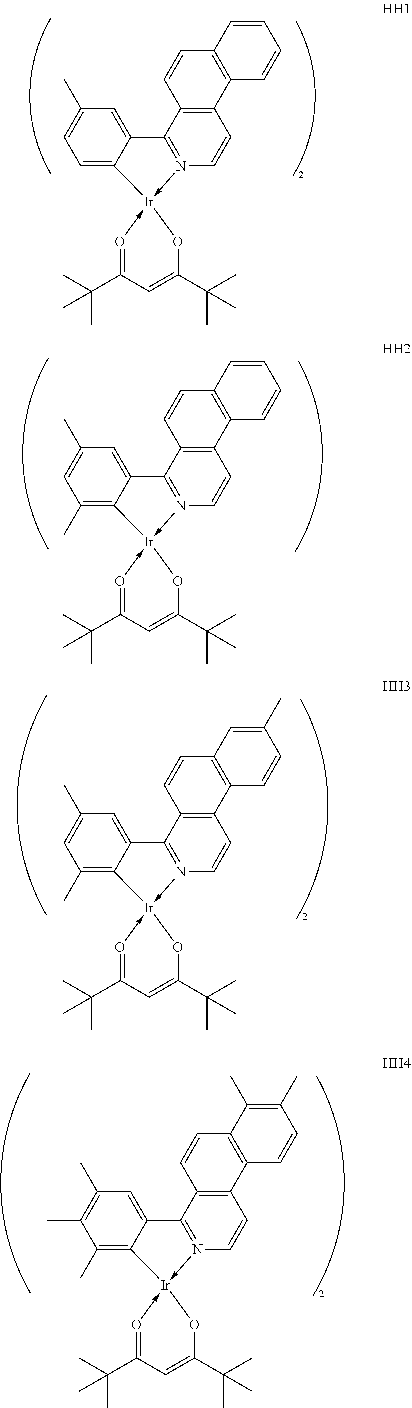

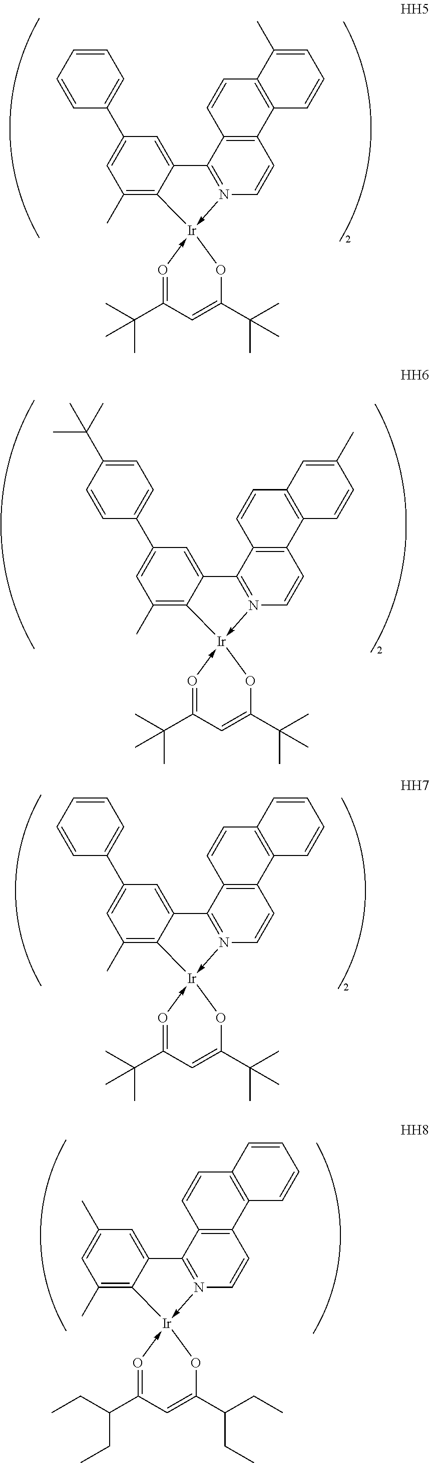

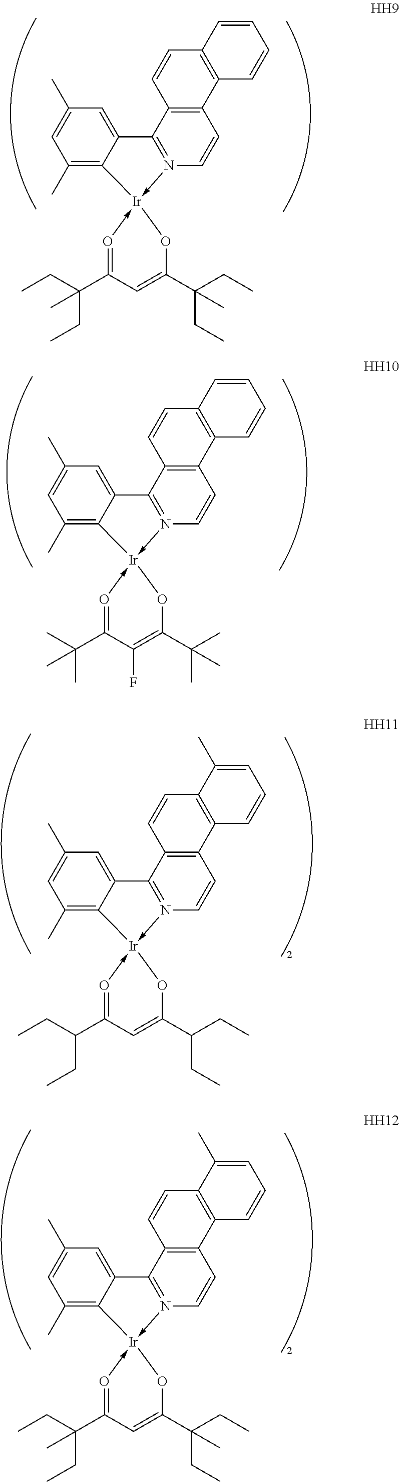

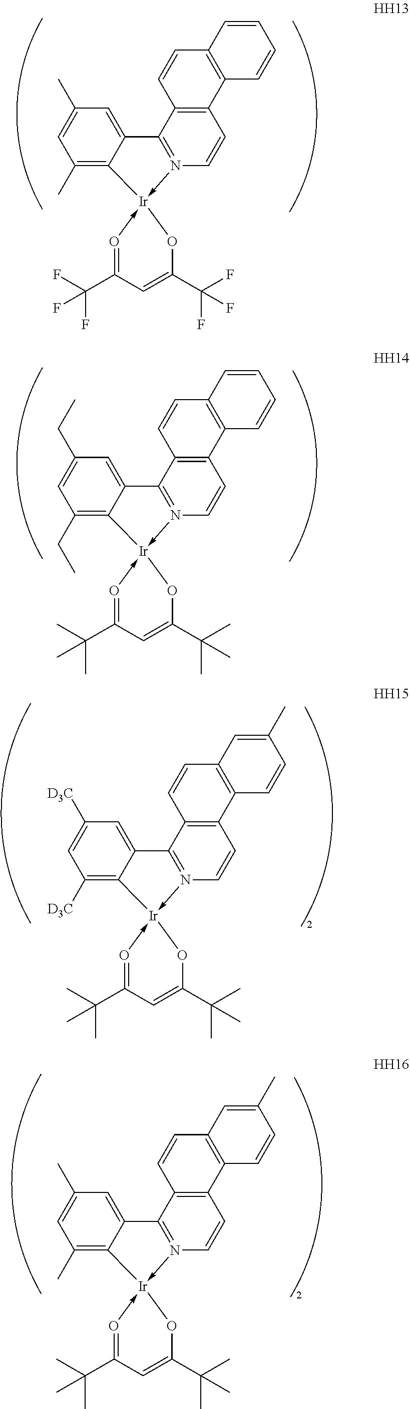

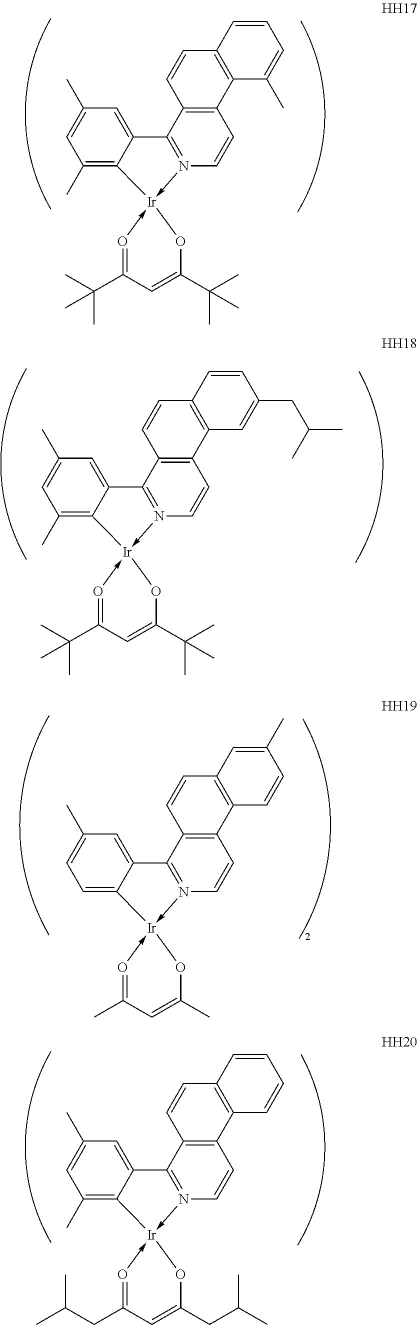

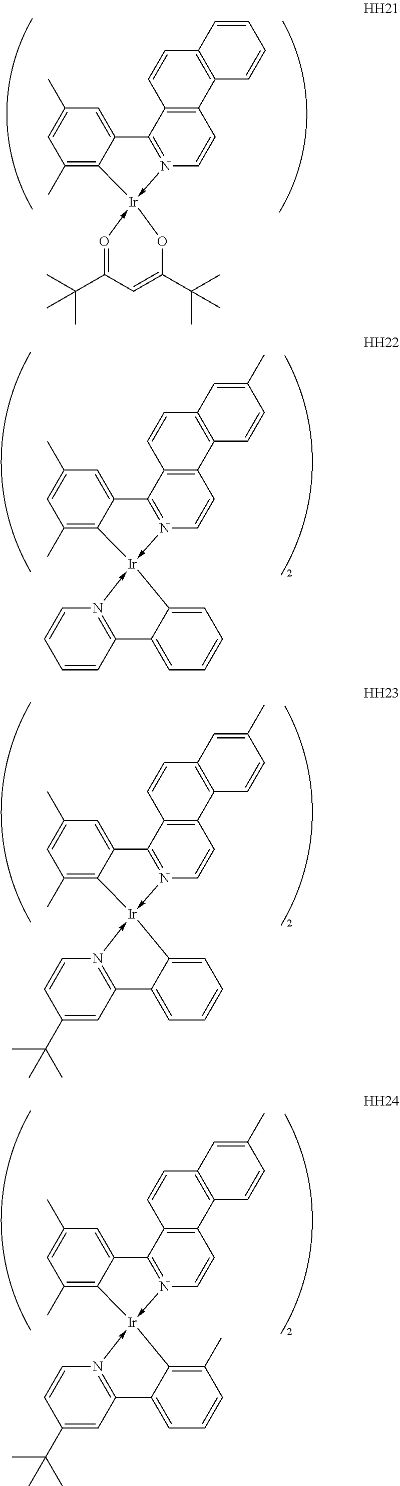

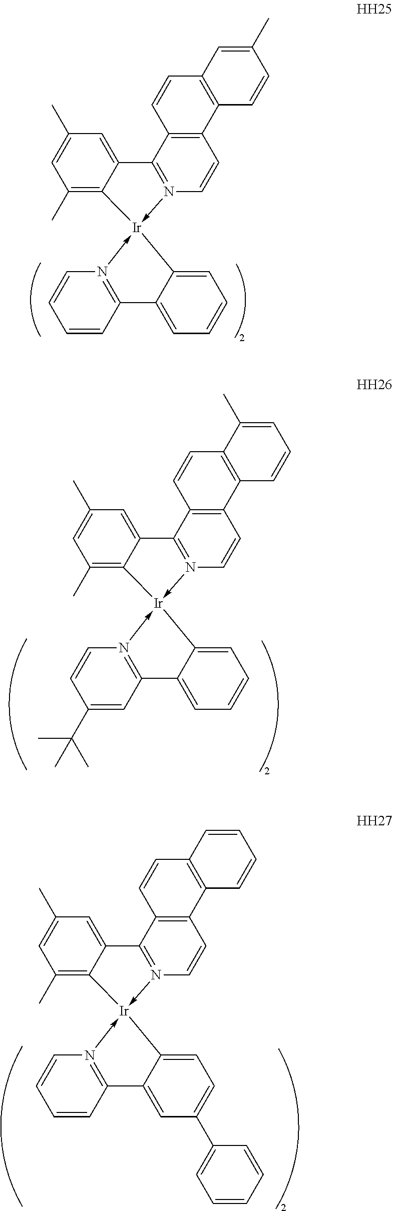

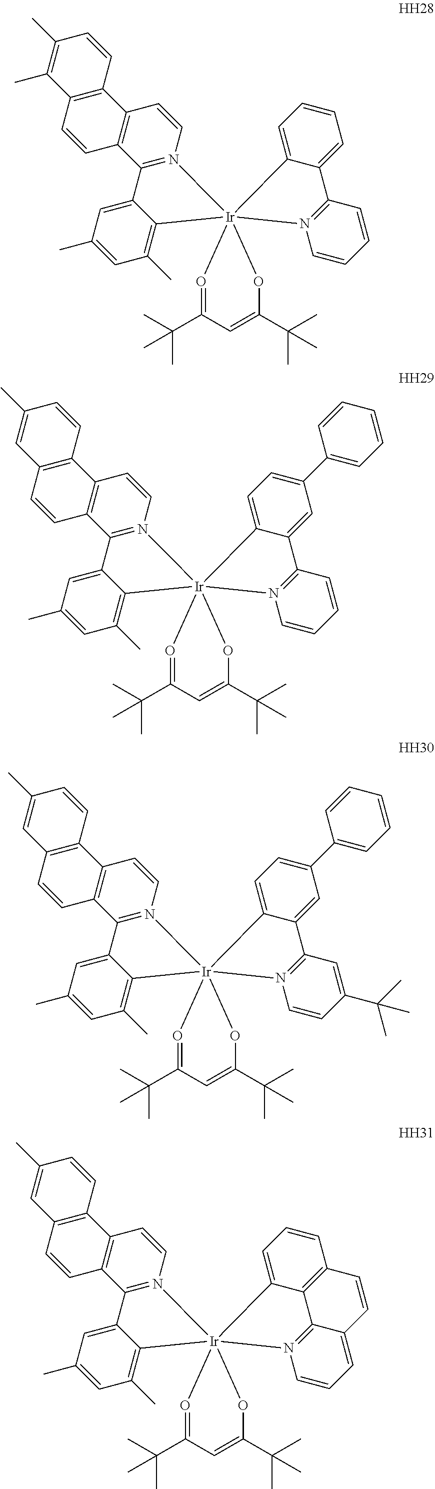

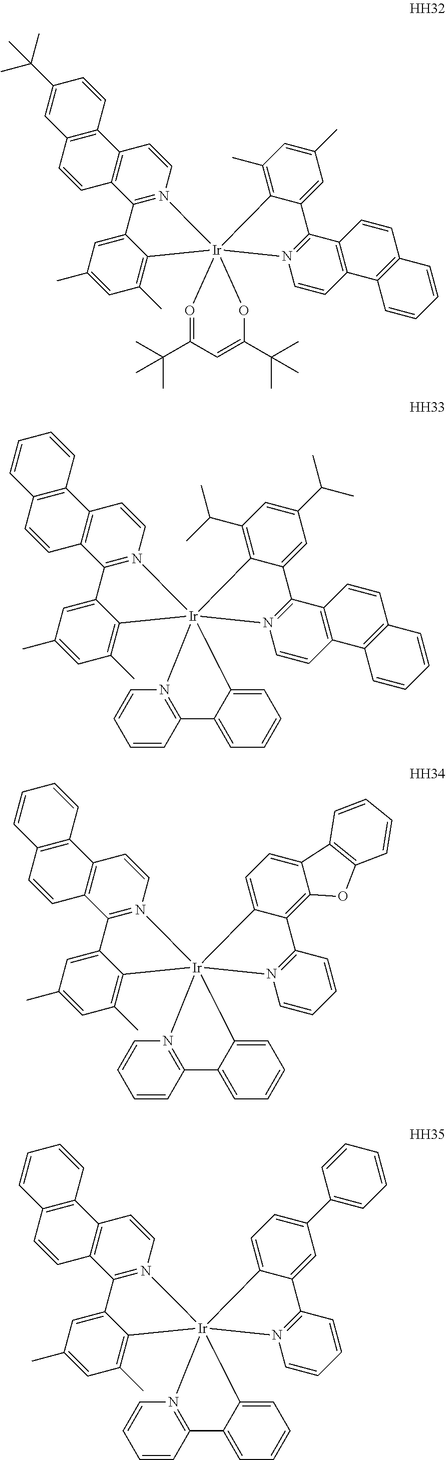

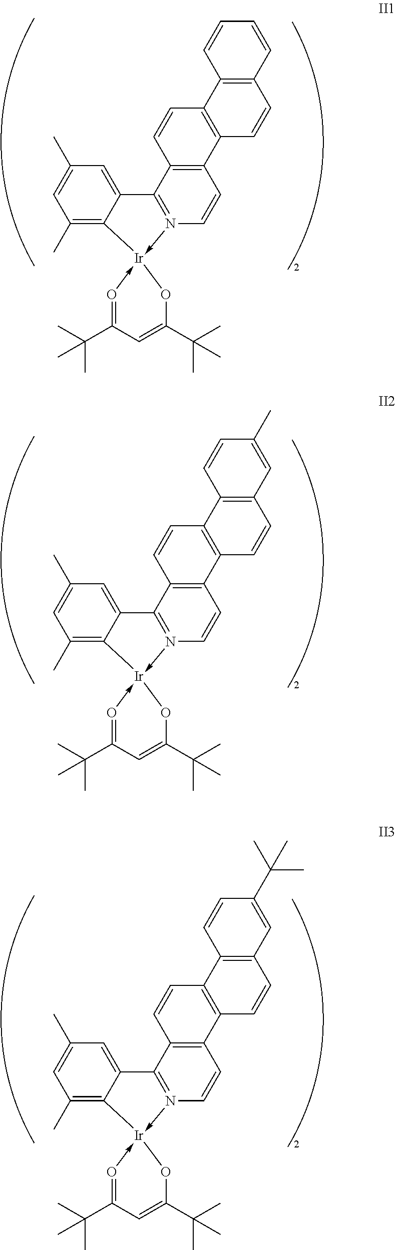

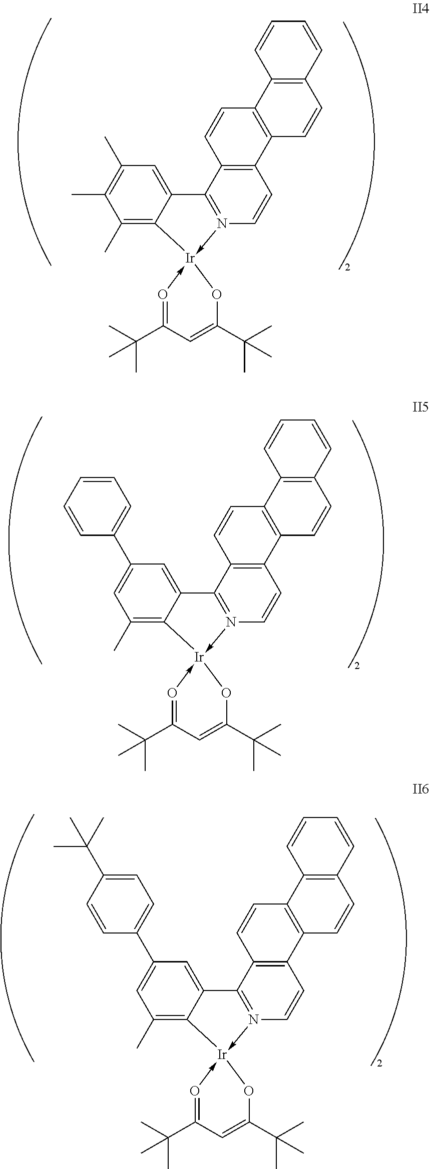

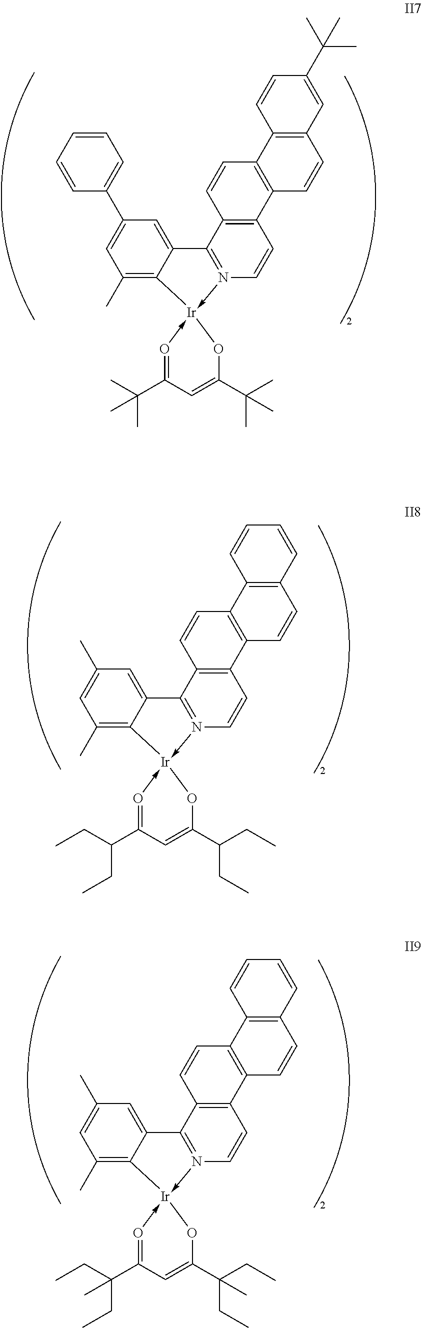

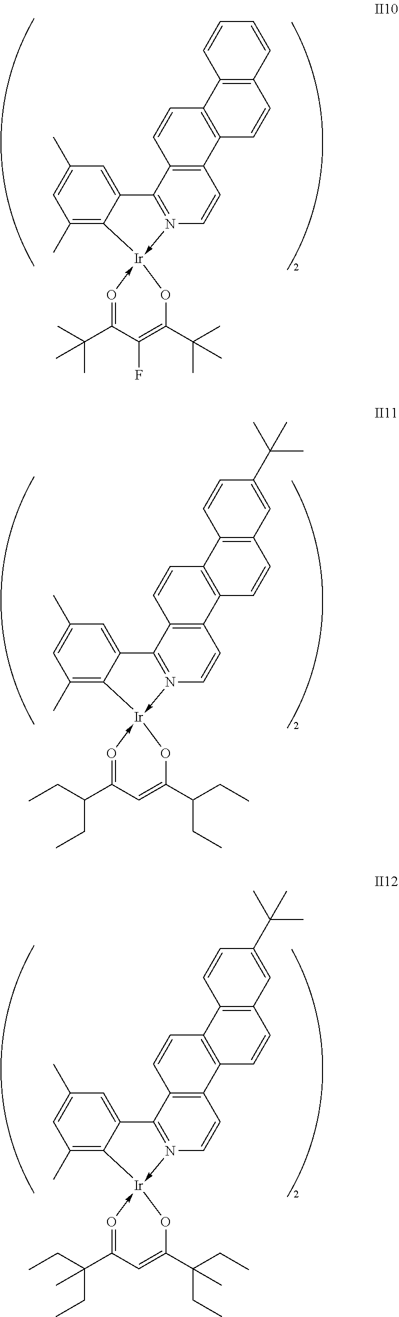

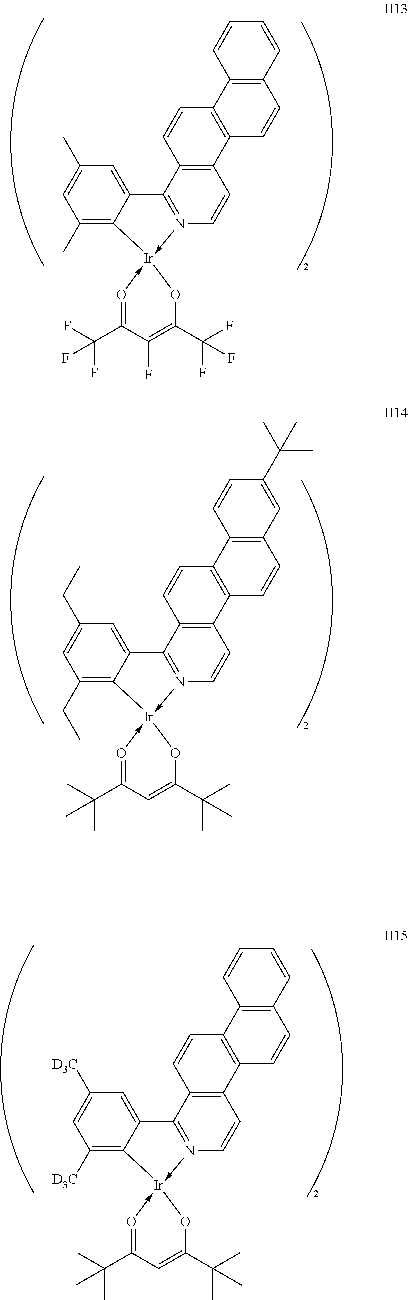

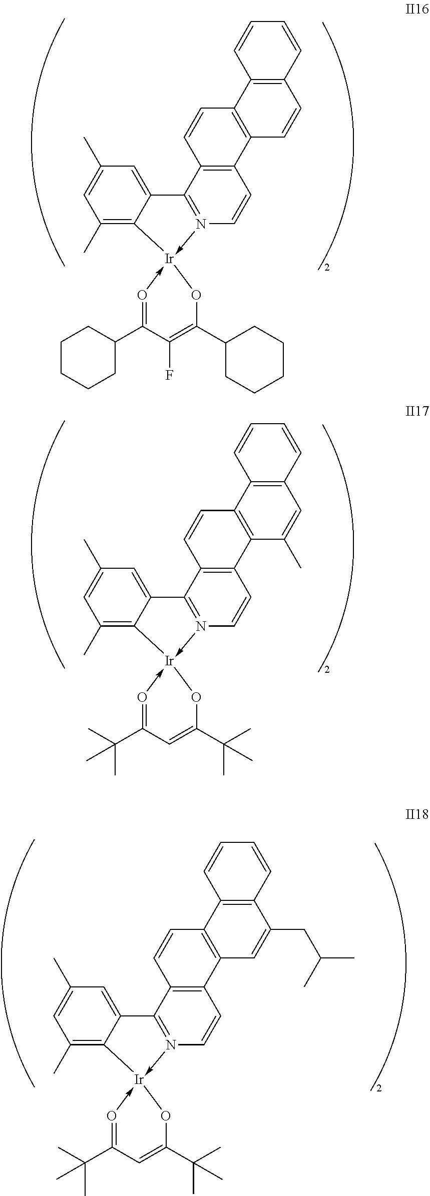

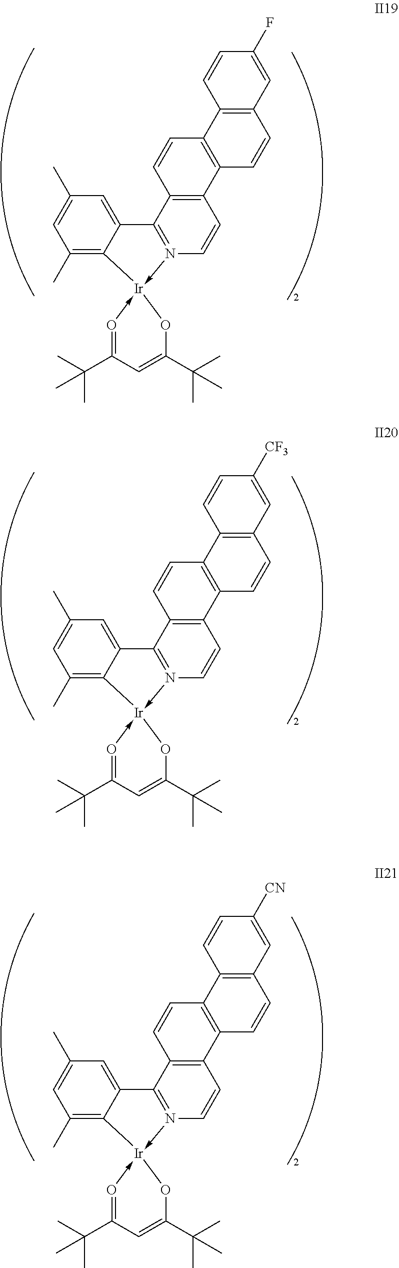

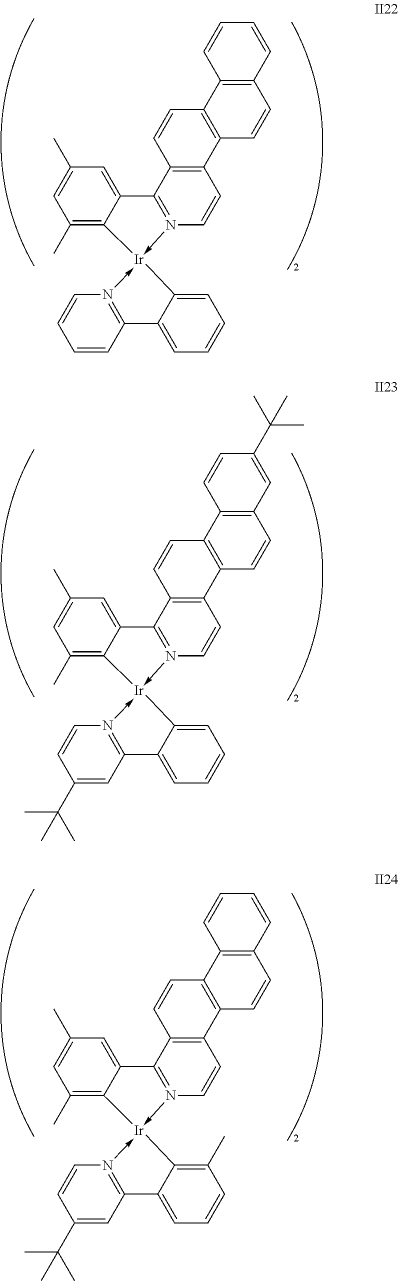

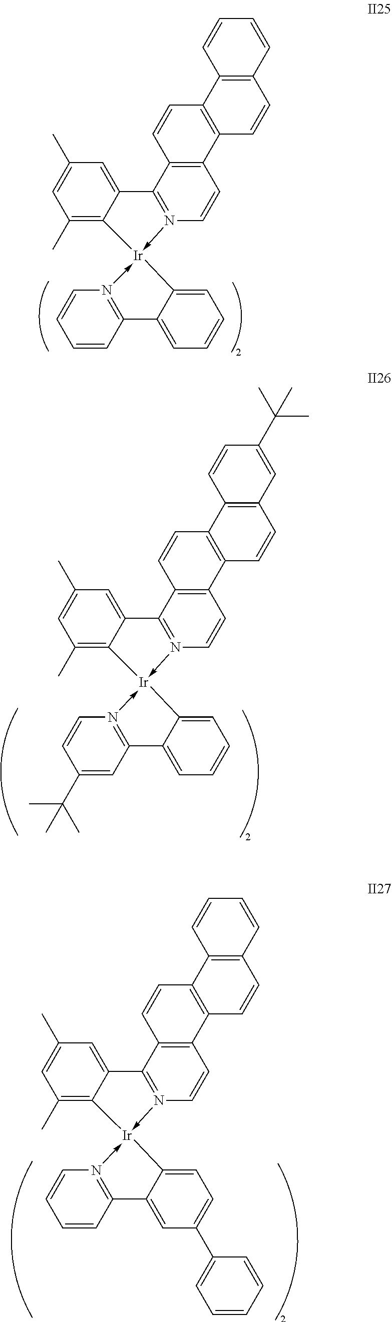

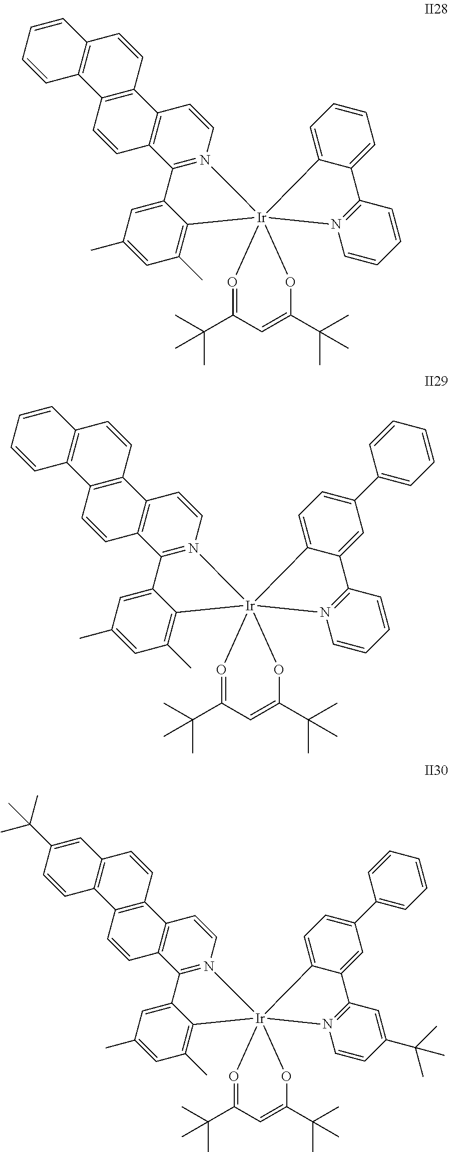

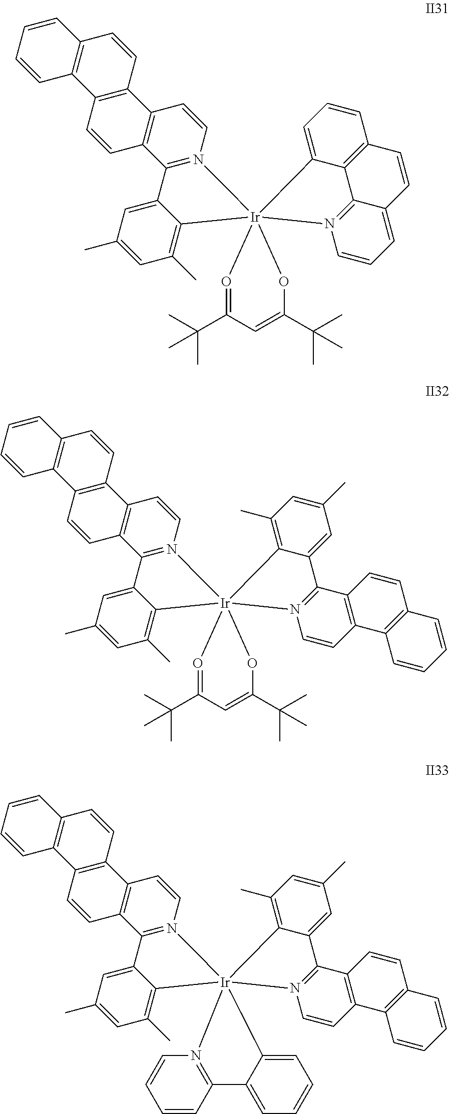

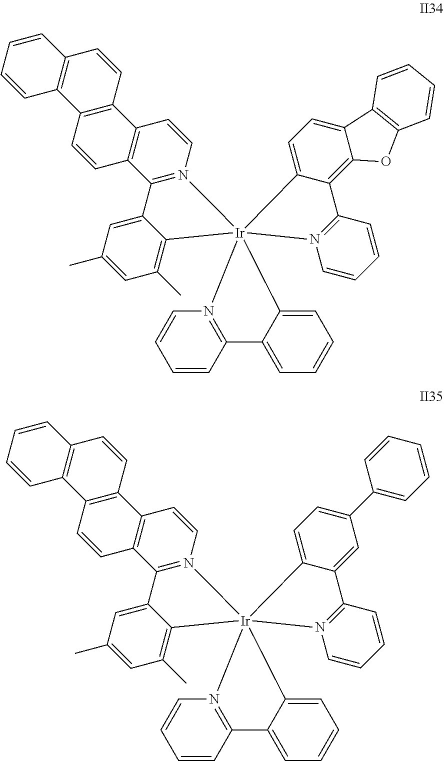

Of the above organometallic complexes, the exemplified compounds belonging to groups AA and BB are compounds having at least a phenanthrene skeleton in the ligand of the Ir complex, and are compounds that are particularly excellent in stability.

Of the above organometallic complexes, the exemplary compounds belonging to group CC are compounds each having at least a triphenylene skeleton in the ligand of the Ir complex, and are compounds that are particularly excellent in stability.

Of the above organometallic complexes, the exemplary compounds belonging to group DD are compounds each having at least a dibenzofuran skeleton or a dibenzothiophene skeleton in the ligand of the Ir complex. These compounds contain oxygen atoms and sulfur atoms in the fused rings, and thus the charge transport properties can be enhanced by the abundant lone-pair electrons possessed by these atoms. Thus, in particular, these compounds are compounds that can easily adjust the carrier balance.

Of the above organometallic complexes, the exemplified compounds belonging to group EE, group FF, and group GG are compounds each having at least a benzofluorene skeleton in the ligand of the Ir complex. Each of the compounds further has a substituent at the 9-position of the fluorene. The fluorene ring has the substituent in a direction perpendicular to the in-plane direction of the fluorene ring; thus, it is possible to particularly inhibit the fused rings from overlapping each other. For this reason, these compounds are particularly excellent in sublimability.

Of the above organometallic complexes, the exemplified compounds belonging to group HH are compounds each having at least a benzoisoquinoline skeleton in the ligand of the Ir complex. These compounds contain nitrogen atoms in the fused rings; hence, the charge transport properties can be enhanced due to lone-pair electrons and high electronegativity of these atoms. Thus, these compounds are compounds that can easily adjust the carrier balance.

Of the above organometallic complexes, the exemplified compounds belonging to group II are compounds each having at least a naphthoisoquinoline skeleton in the ligand of the Ir complex. These compounds contain nitrogen atoms in the fused rings; hence, the charge transport properties can be enhanced due to the lone-pair electrons and high electronegativity of these atoms. Thus, these compounds are compounds that can easily adjust the carrier balance.

In the present embodiment, examples of the light-emitting material mainly related to the light-emitting function include, in addition to the organometallic complexes represented by general formulae [Ir-1] to [Ir-16], fused-ring compounds, such as fluorene derivatives, naphthalene derivatives, pyrene derivatives, perylene derivatives, tetracene derivatives, anthracene derivatives, and rubrene; quinacridone derivatives; coumarin derivatives; stilbene derivatives; organoaluminum complexes such as tris (8-quinolinolato)aluminum; iridium complexes; platinum complexes; rhenium complexes; copper complexes; europium complexes; ruthenium complexes; and polymer derivatives, such as poly(phenylene vinylene) derivatives, polyfluorene derivatives, and polyphenylene derivatives.

While specific examples of a compound that can be used as a light-emitting material are illustrated below, the present invention is not limited thereto. In the following specific examples, BD9, GD10 to GD19, and RD3 to RD11 are metal complexes, and can also be used as the first and second metal complexes according to the present embodiment. Compounds other than metal complexes can be used as light-emitting materials in combination with the first and third metal complexes.

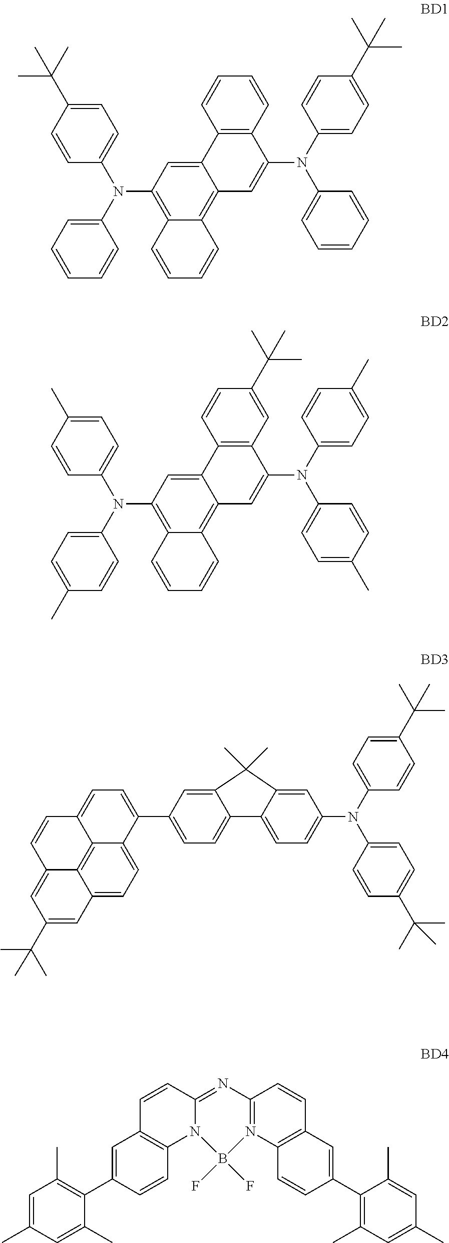

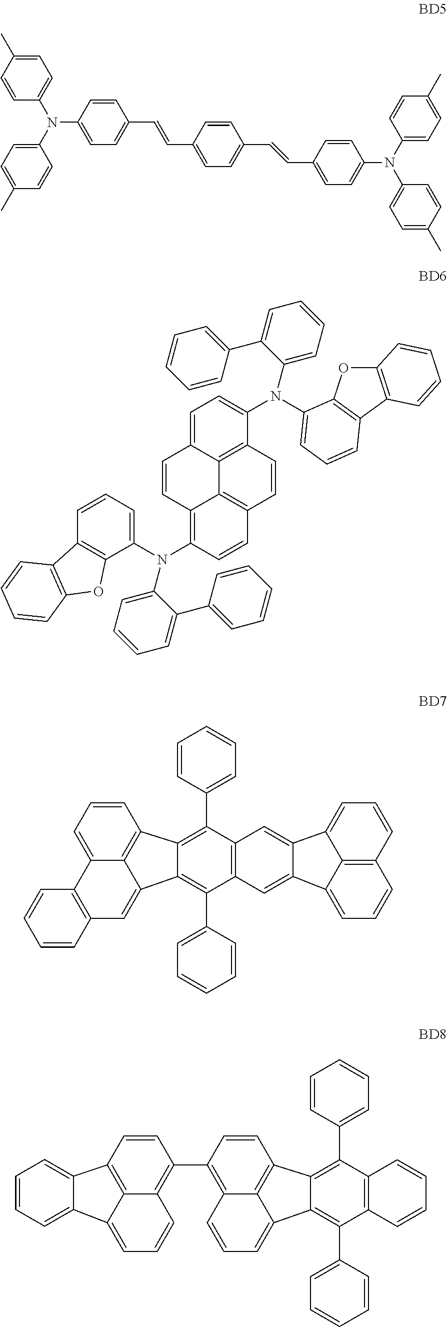

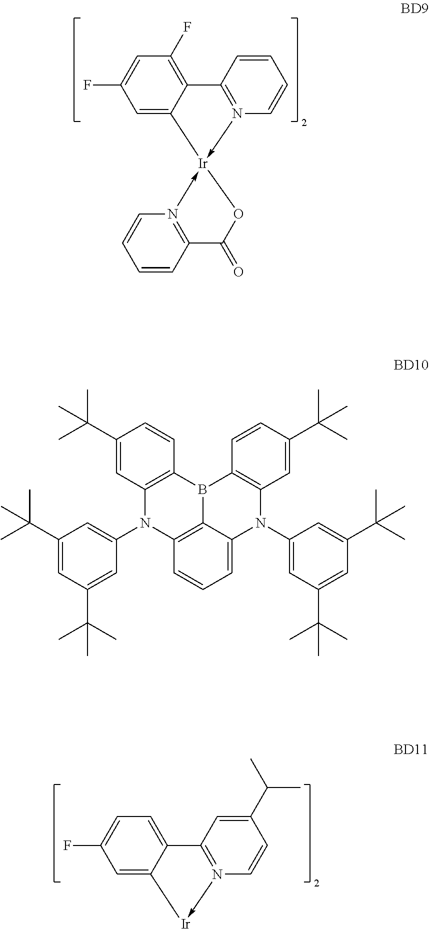

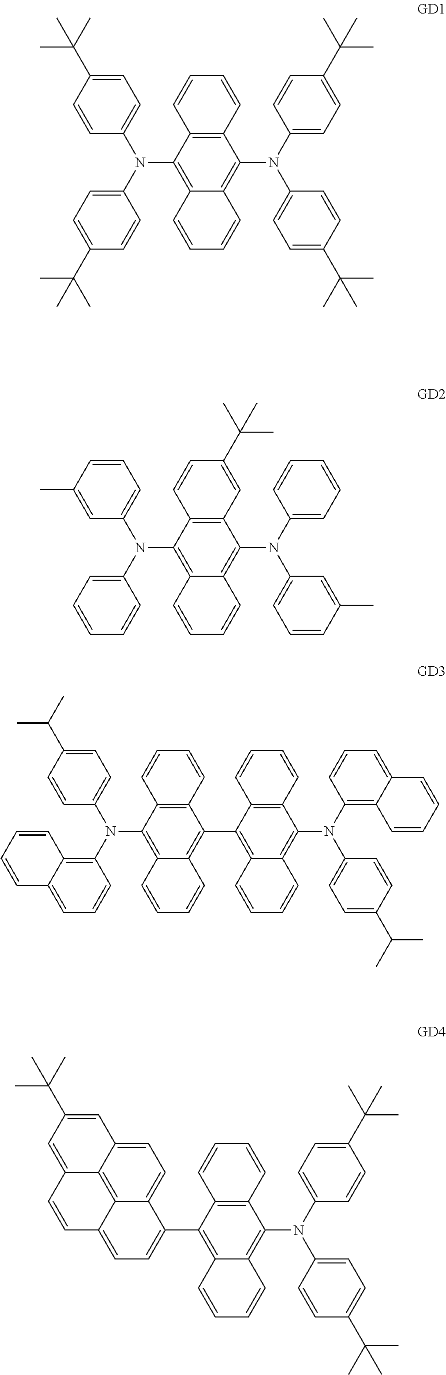

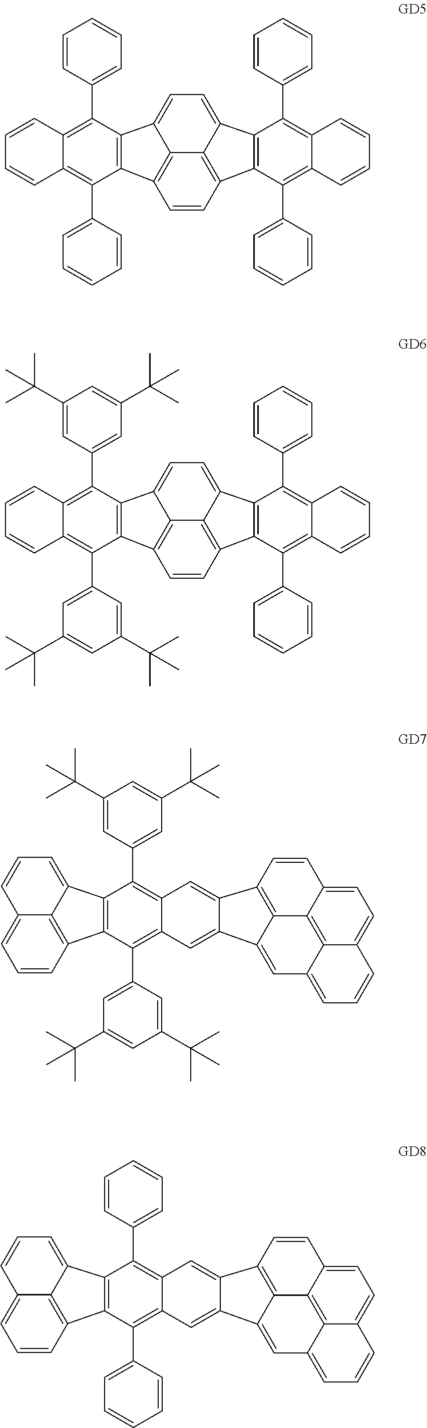

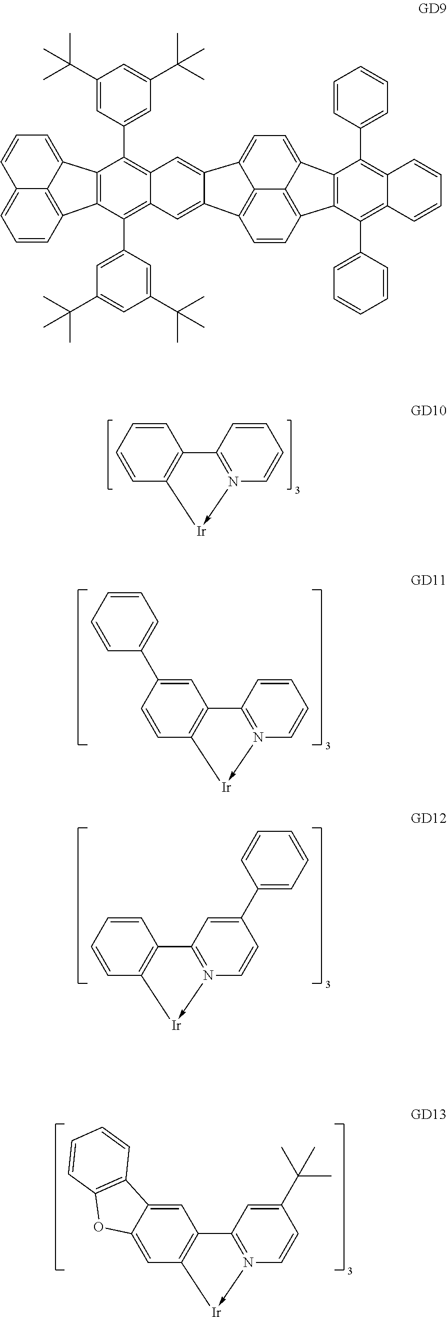

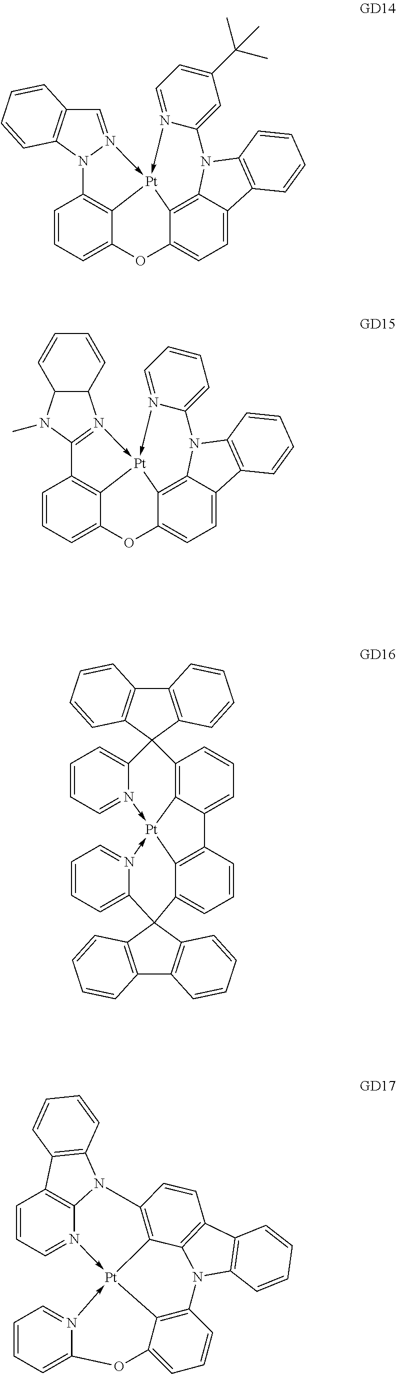

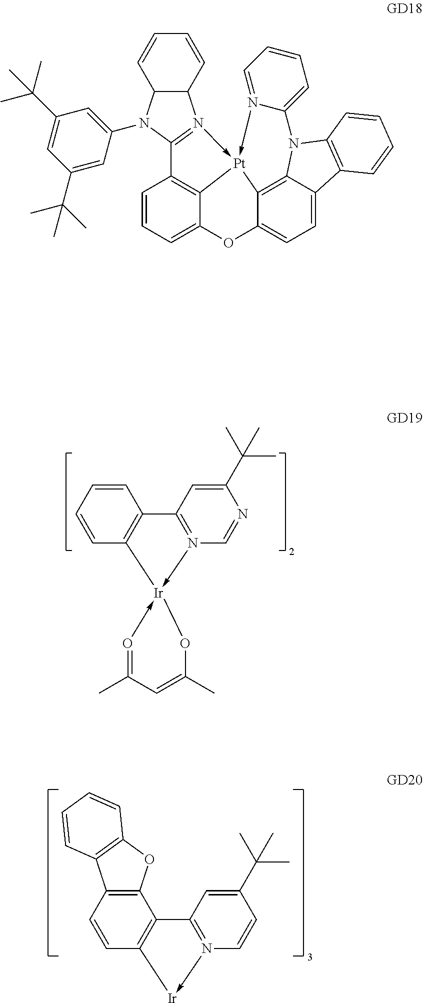

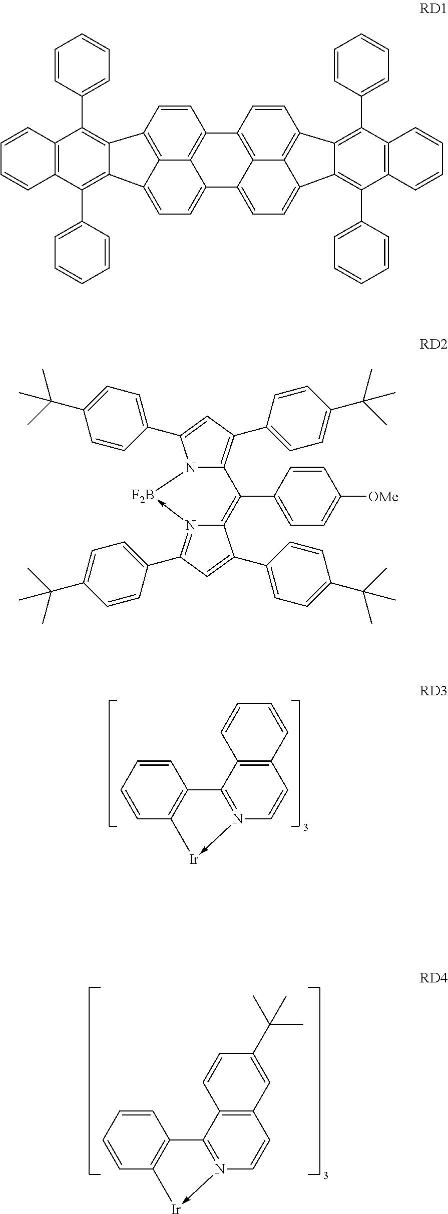

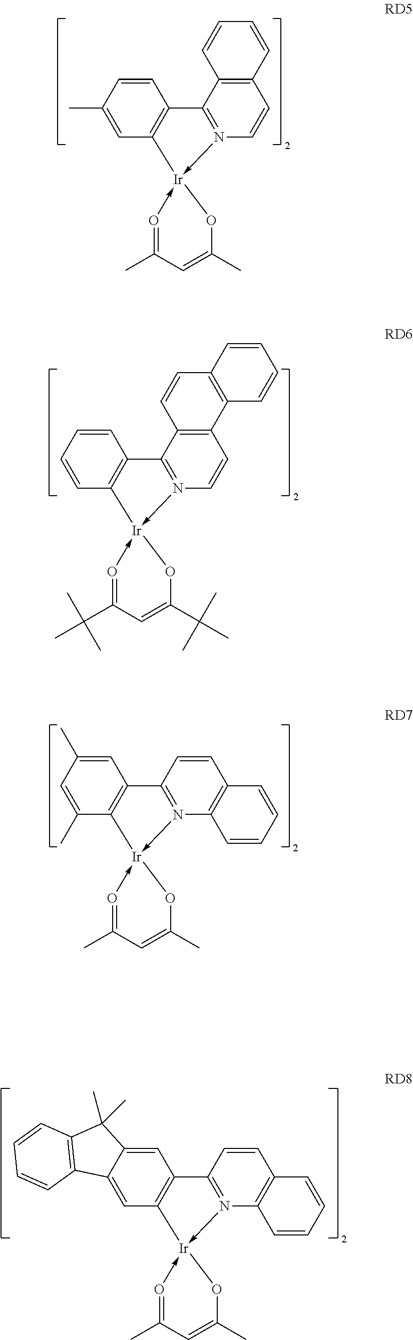

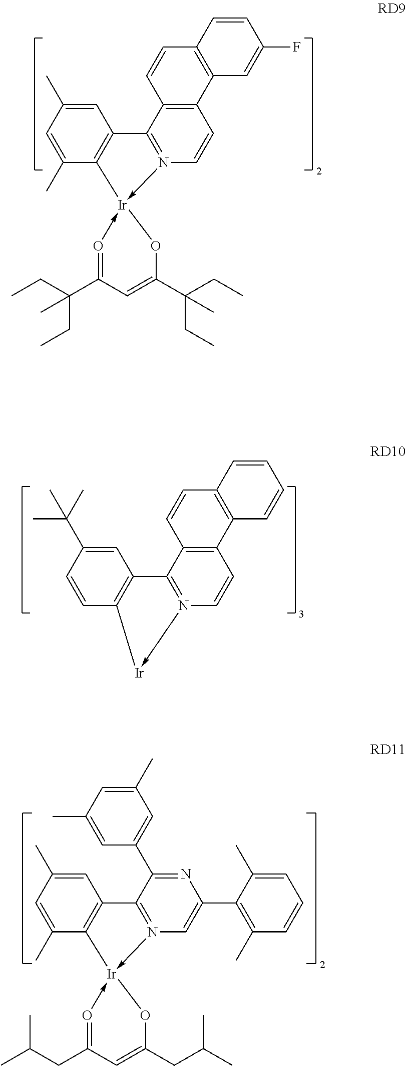

### First and Second Organic Compounds

The configuration according to an embodiment of the present invention has good carrier transfer and energy transfer between the light-emitting layers stacked. For this reason, the first and second organic compounds used as the first and second hosts according to an embodiment of the present invention are preferably compounds having excellent carrier transport properties.

As each of the first and second hosts, a material having any of a dibenzothiophene skeleton, a dibenzofuran skeleton, a triphenylene skeleton, or a phenanthrene skeleton are preferred. These materials have highly planar skeletons and can promote carrier transfer between light-emitting layers. Thus, the use of these materials can provide organic light-emitting devices with excellent luminous efficiency.

When these host materials are combined with the device configuration according to an embodiment of the present invention, it is possible to achieve a good carrier balance and provide organic light-emitting devices having better device durability.

### Third Organic Compound

The configuration according to an embodiment of the present invention has good carrier transfer and energy transfer between the light-emitting layers stacked. Thus, the second light-emitting layer according to an embodiment of the present invention preferably contains a third organic compound as an assist material. The assist material is preferably a compound that can easily adjust the carrier balance.

Specifically, a material having any of a triarylamine skeleton, a carbazole skeleton, an azine skeleton, and a xanthone skeleton is preferred. These materials have excellent electron-donating and electron-withdrawing properties; thus, the HOMO level and LUMO level can be easily adjusted, and the injection of carriers from the surrounding layers can be promoted. Thus, the use of these materials provides organic light-emitting devices having excellent luminous efficiency.

When these assist materials are combined with the device configuration according to an embodiment of the present invention, it is possible to achieve a good carrier balance and provide organic light-emitting devices having better device durability.

Examples of the host material or assist material contained in the light-emitting layer include, in addition to the materials described above in First and Second Organic Compounds and Third Organic Compound, aromatic hydrocarbon compounds and derivatives thereof, carbazole derivatives, dibenzofuran derivatives, dibenzothiophene derivatives, organoaluminum complexes such as tris(8-quinolinolato)aluminum, and organoberyllium complexes.

In particular, as the assist material, a material having a carbazole skeleton, a material having an azine ring, or a material having a xanthone skeleton is preferred. These materials have high electron-donating and electron-withdrawing properties, and thus the HOMO level and LUMO level can be easily adjusted. When these assist materials are combined with the metal complexes according to an embodiment of the present invention, a good carrier balance can be achieved.

While specific examples of a compound that can be used as the host or assist material in the light-emitting layer are illustrated below, the present invention is not limited thereto.

Among the specific examples below, materials each having a carbazole skeleton are EM32 to EM38. Materials each having an azine ring are EM35 to EM40. Materials each having a xanthone skeleton are EM28 and EM30.

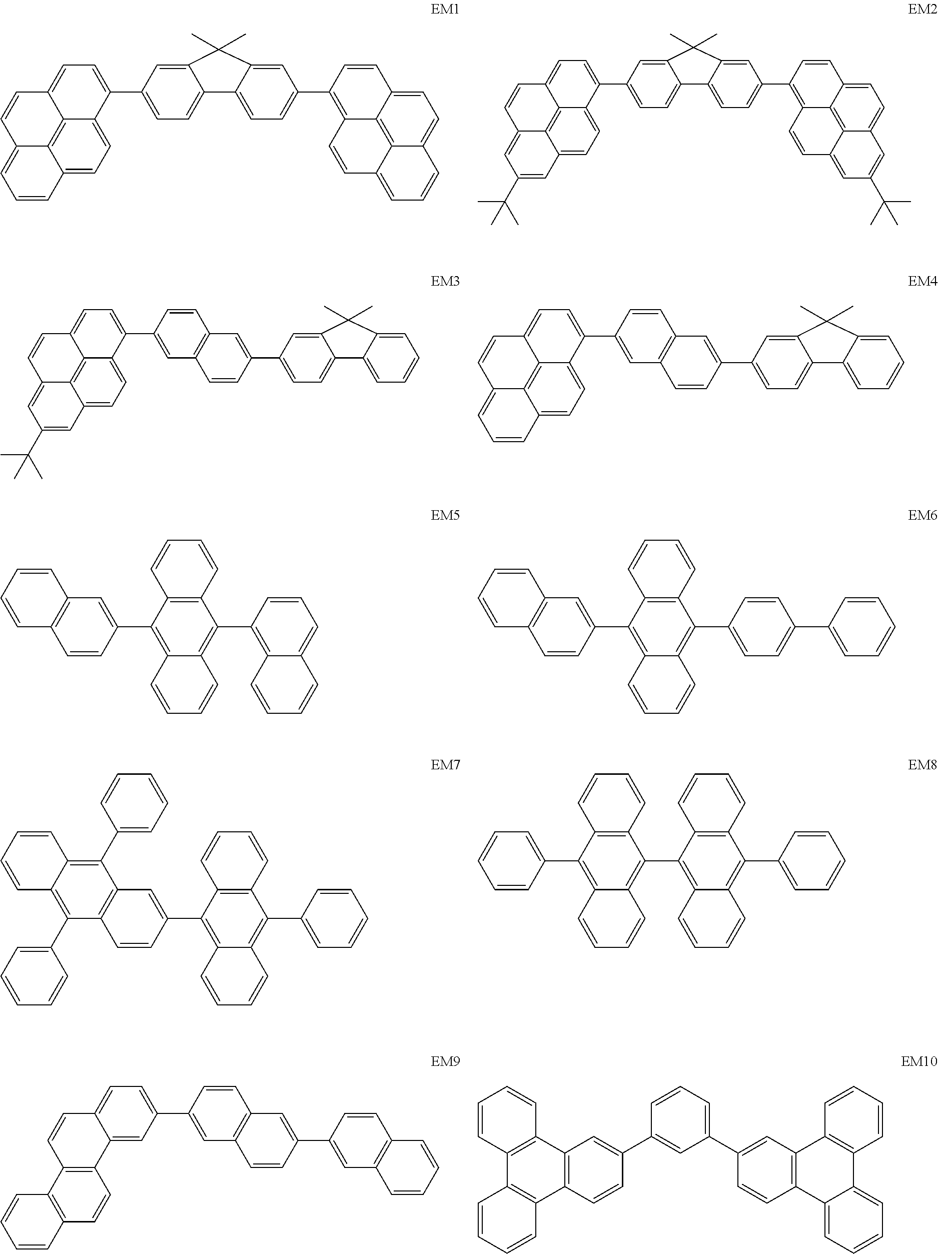

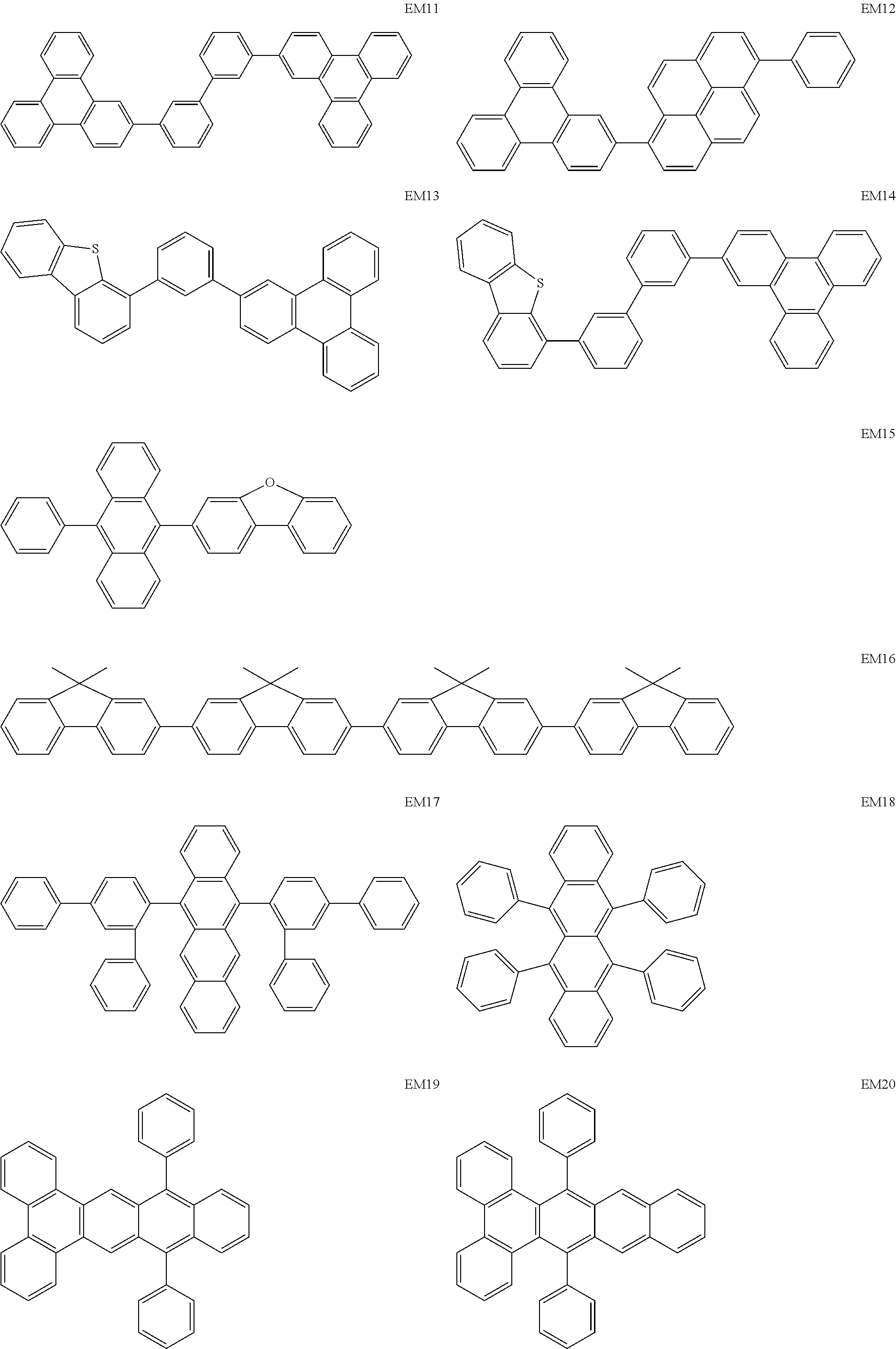

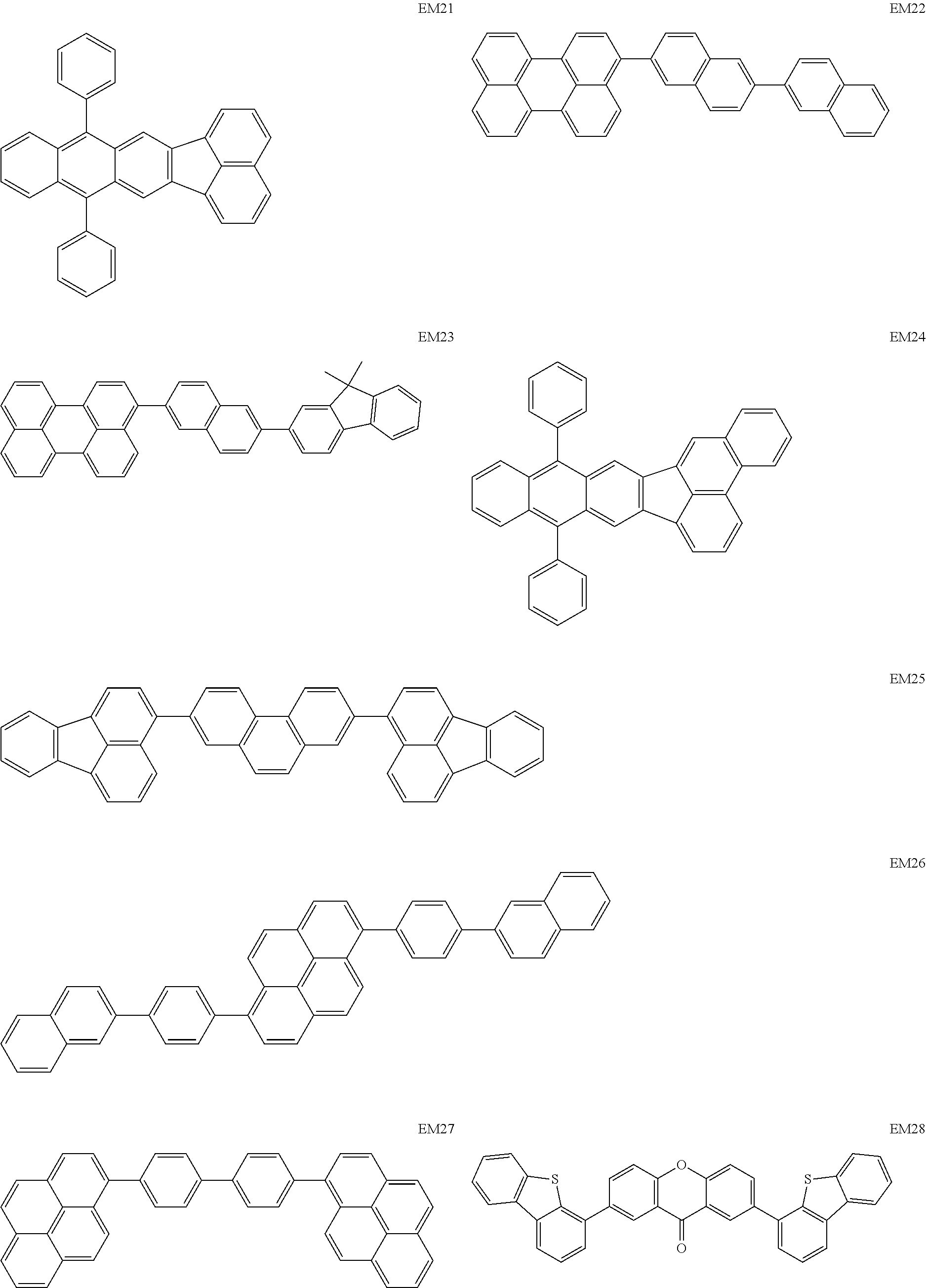

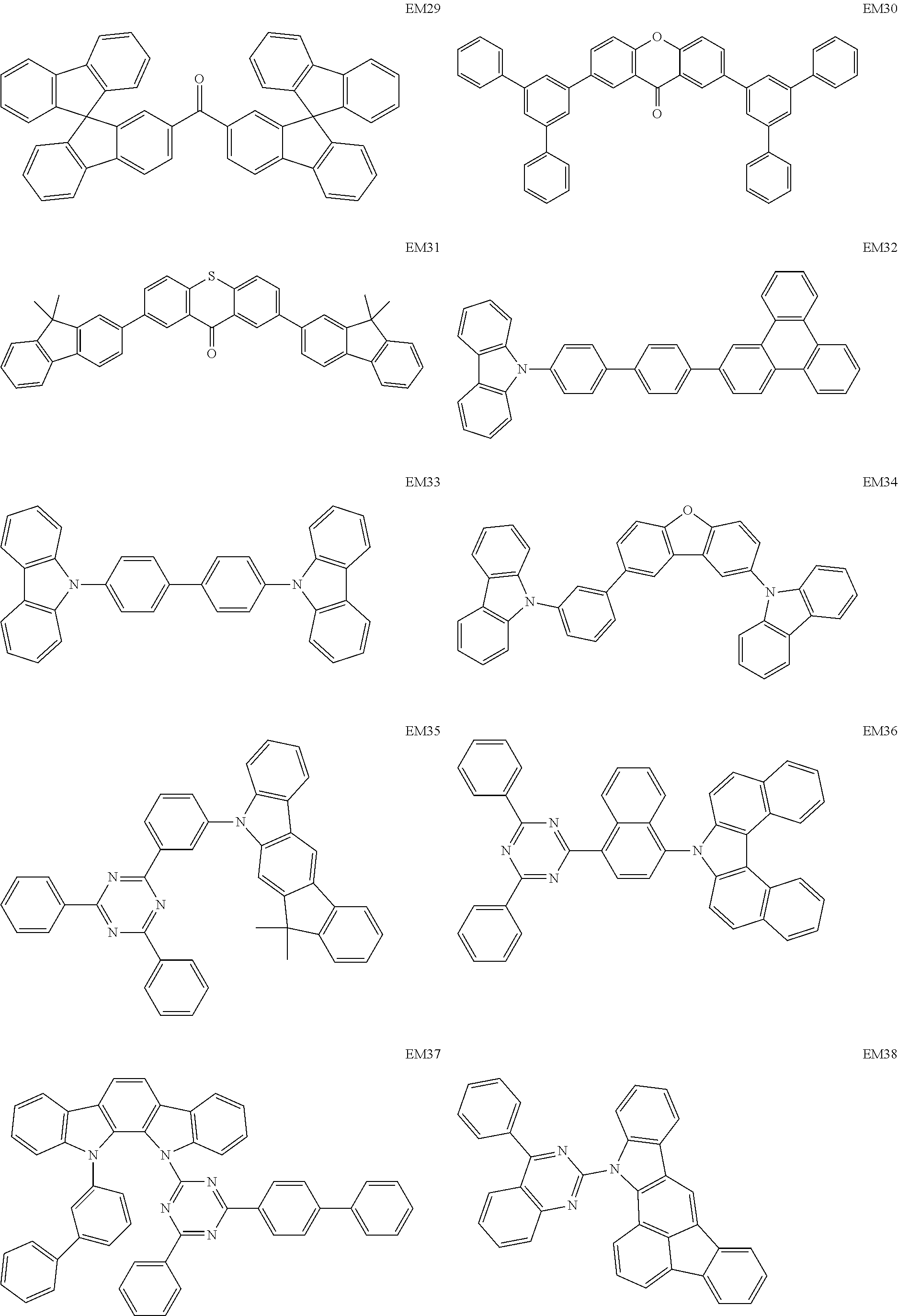

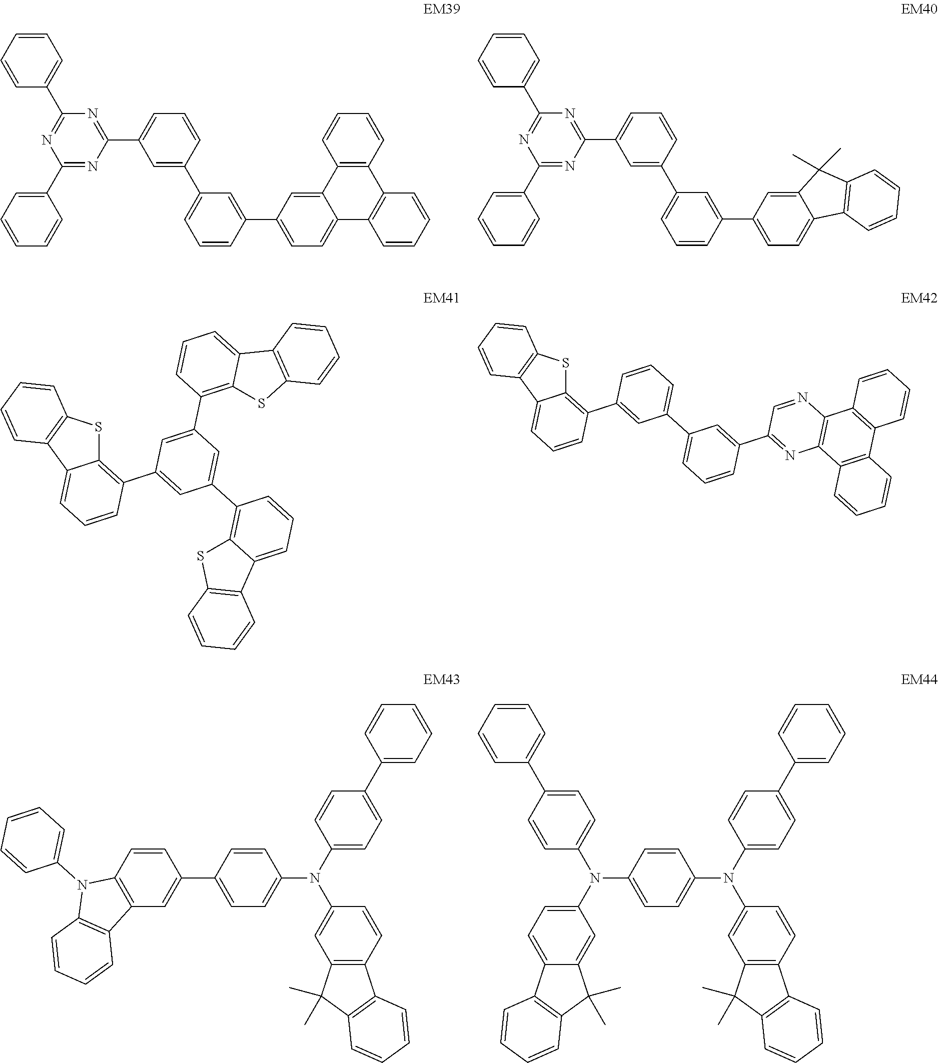

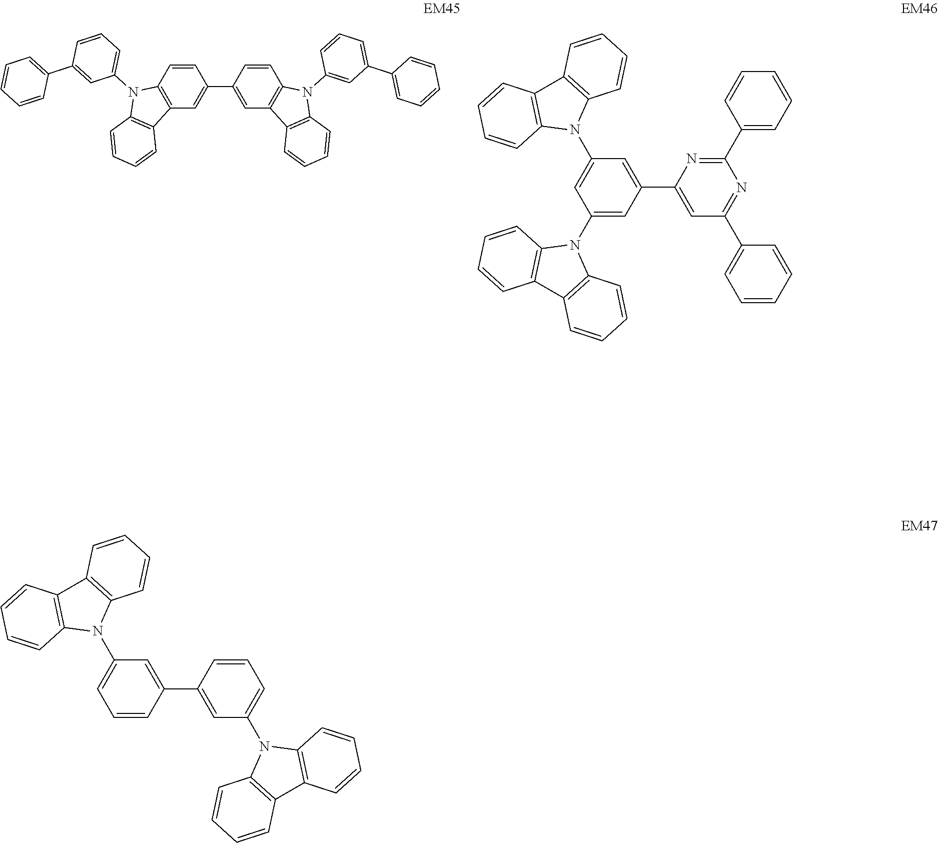

### Other Compounds

In an organic light-emitting device according to the present embodiment, a hole injection layer, a hole transport layer, an electron-blocking layer, an electron injection layer, an electron transport layer, and a hole-blocking layer may be disposed between the light-emitting layer and the electrodes, as necessary.

As a hole injection-transport material that can be used for the hole injection layer or the hole transport layer, a material having high hole mobility can be used so as to facilitate the injection of holes from the anode and to transport the injected holes to the light-emitting layers. To inhibit a deterioration in film quality, such as crystallization, in the organic light-emitting device, a material having a high glass transition temperature is preferred. Examples of low-or high-molecular-weight materials having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material can also be used for an electron-blocking layer.

Non-limiting specific examples of a compound used as the hole injection-transport material will be illustrated below.

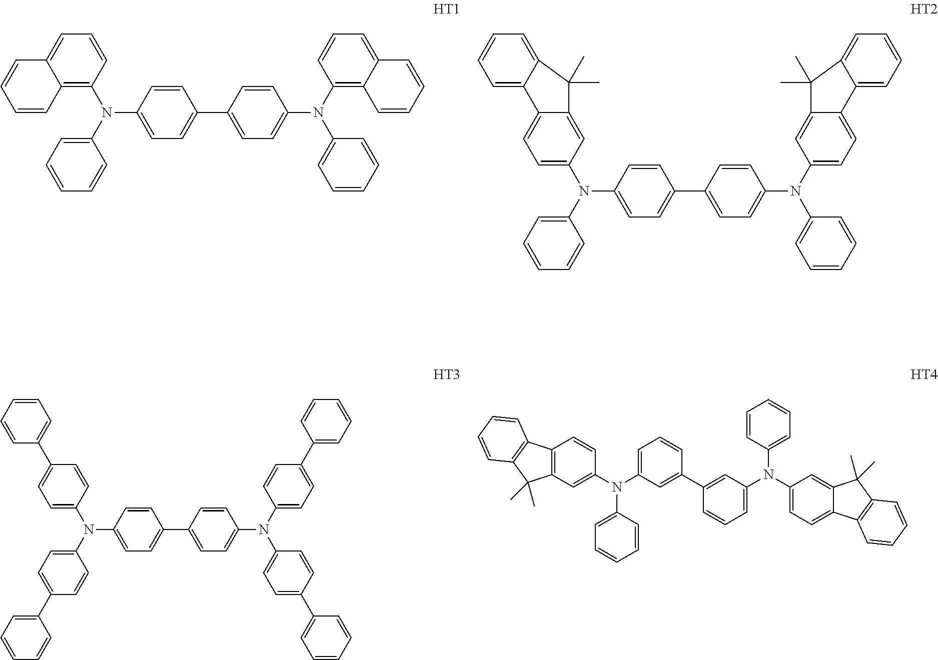 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccccc3)c3cccc(-c4cccc(N(c5ccccc5)c5ccc6c(c5)C(C)(C)c5ccccc5-6)c4)c3)cc21]

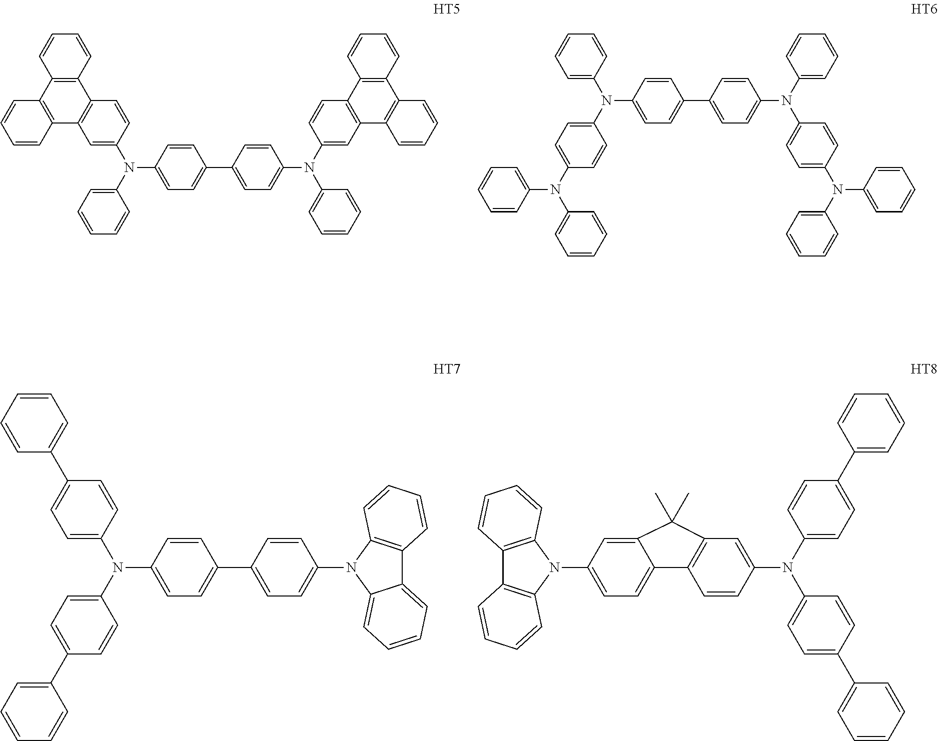 [SMILES: c1ccc(N(c2ccc(-c3ccc(N(c4ccccc4)c4ccc5c6ccccc6c6ccccc6c5c4)cc3)cc2)c2ccc3c4ccccc4c4ccccc4c3c2)cc1 ; c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

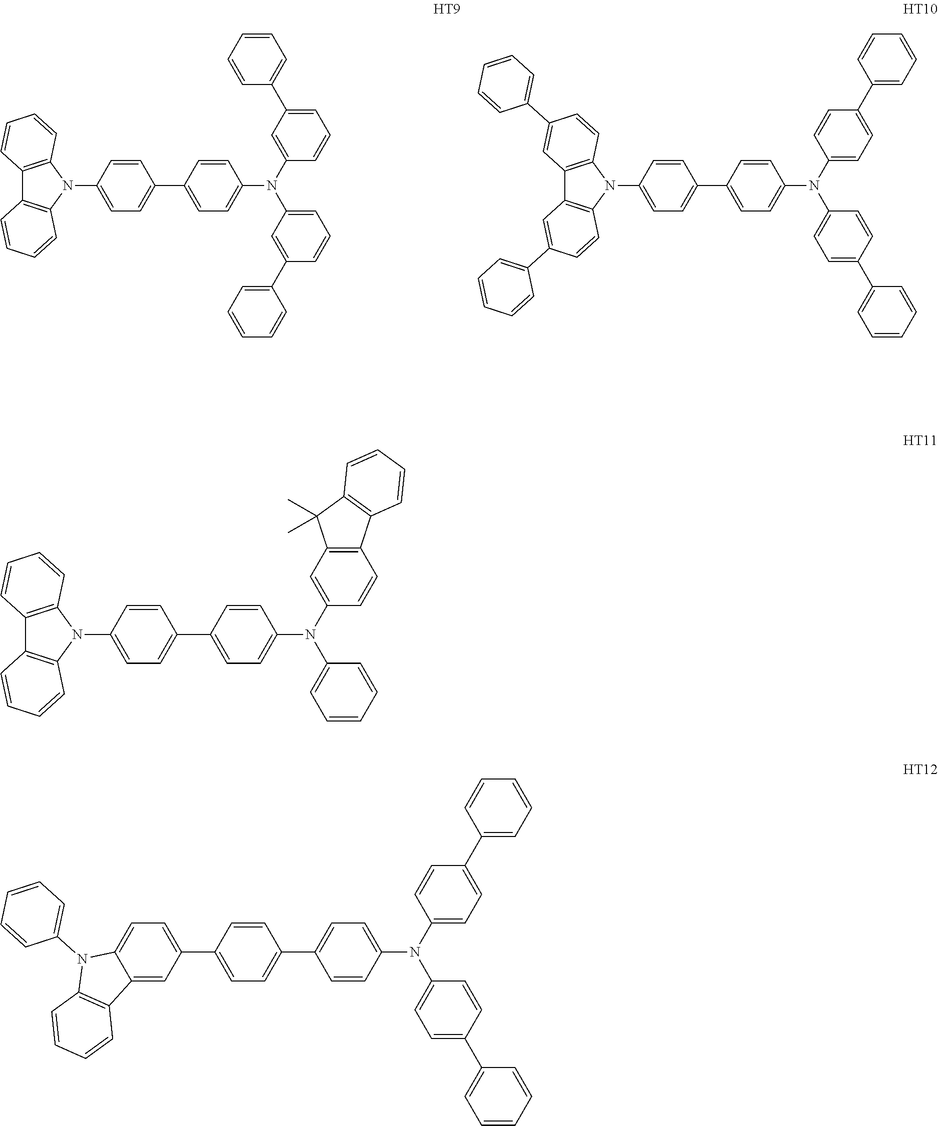 [SMILES: c1ccc(-c2cccc(N(c3ccc(-c4ccc(-n5c6ccccc6c6ccccc65)cc4)cc3)c3cccc(-c4ccccc4)c3)c2)cc1 ; c1ccc(-c2ccc(N(c3ccc(-c4ccccc4)cc3)c3ccc(-c4ccc(-n5c6ccc(-c7ccccc7)cc6c6cc(-c7ccccc7)ccc65)cc4)cc3)cc2)cc1 ; CC1(C)c2ccccc2-c2ccc(N(c3ccccc3)c3ccc(-c4ccc(-n5c6ccccc6c6ccccc65)cc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

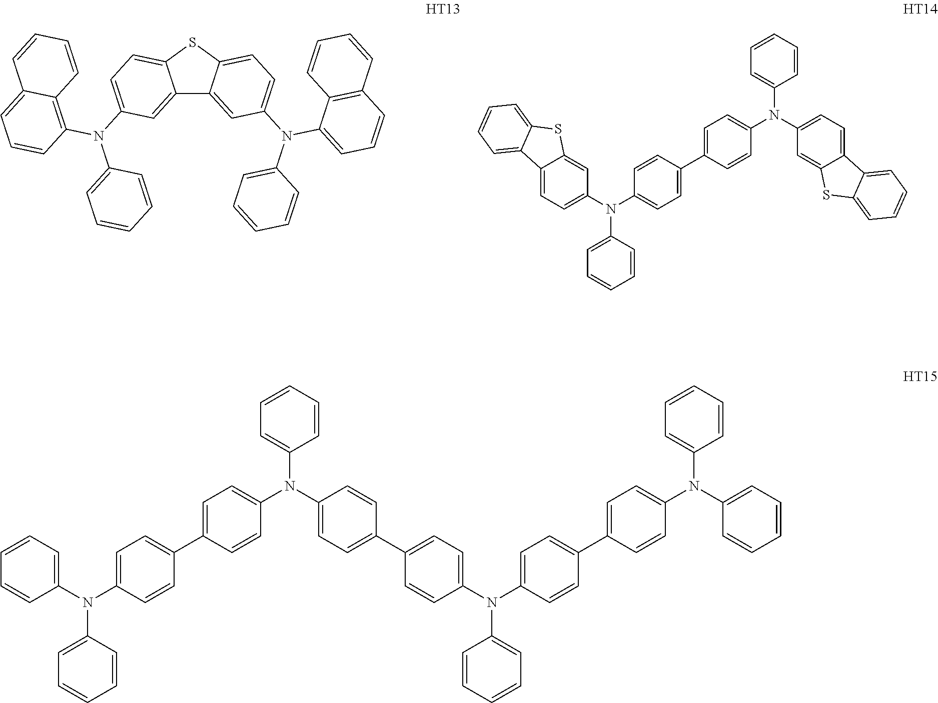 [SMILES: c1ccc(N(c2ccc3sc4ccc(N(c5ccccc5)c5cccc6ccccc56)cc4c3c2)c2cccc3ccccc23)cc1 ; c1ccc(N(c2ccc(-c3ccc(N(c4ccccc4)c4ccc5c(c4)sc4ccccc45)cc3)cc2)c2ccc3c(c2)sc2ccccc23)cc1 ; c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

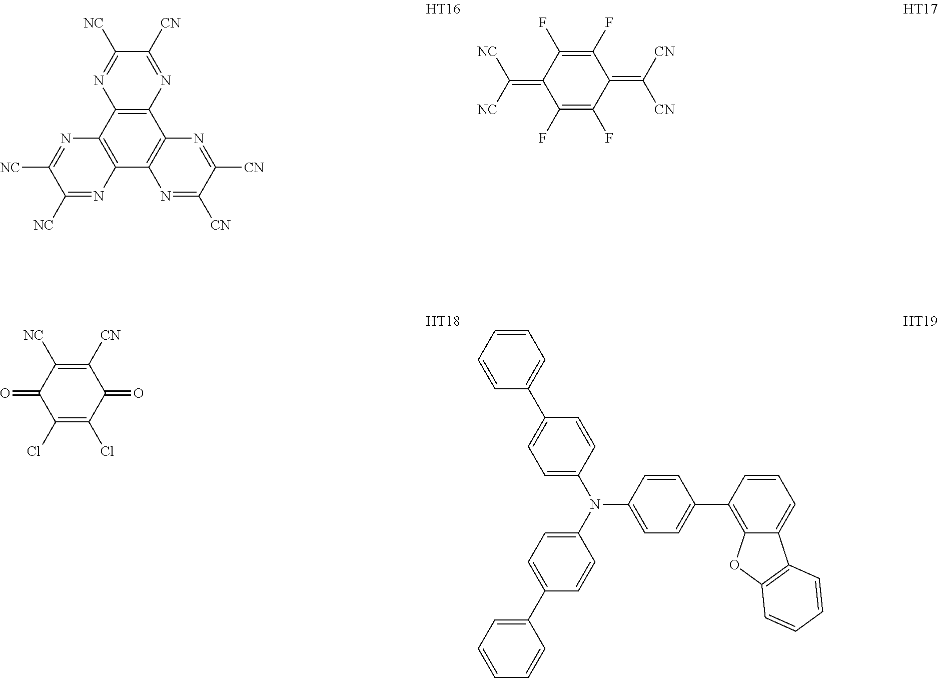 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

An electron transport material suitably used for the electron injection layer and the electron transport layer can be freely-selected from materials capable of transporting electrons injected from the cathode to the light-emitting layer, and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The above-described electron transport materials are preferably used for the hole-blocking layer.

Non-limiting examples of a compound used as the electron transport material will be specifically described below.

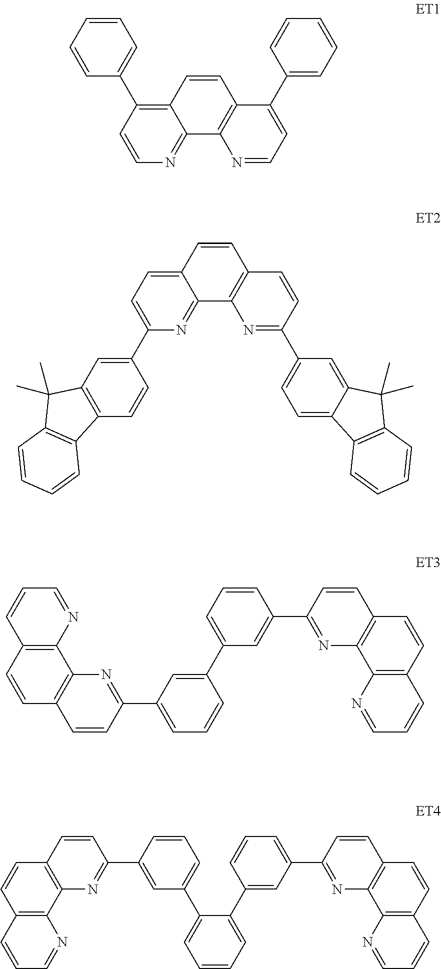

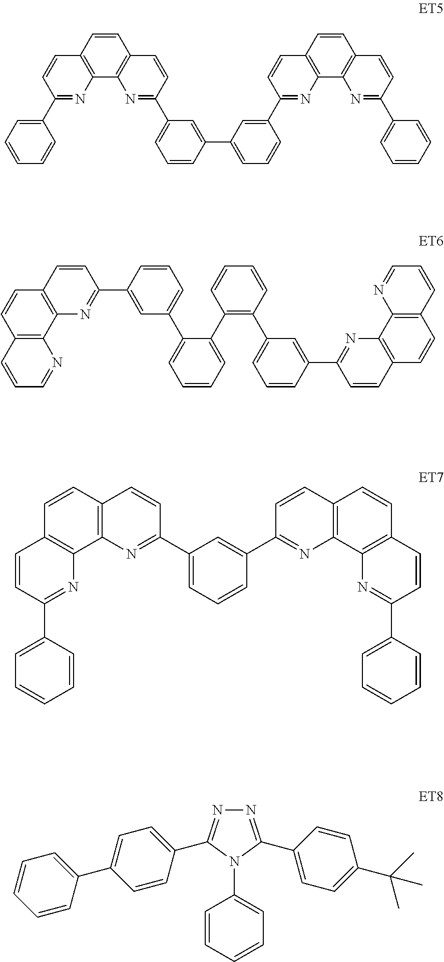 [SMILES: c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1ccc(-c2nnc(-c3ccc(-c4ccccc4)cc3)n2-c2ccccc2)cc1]

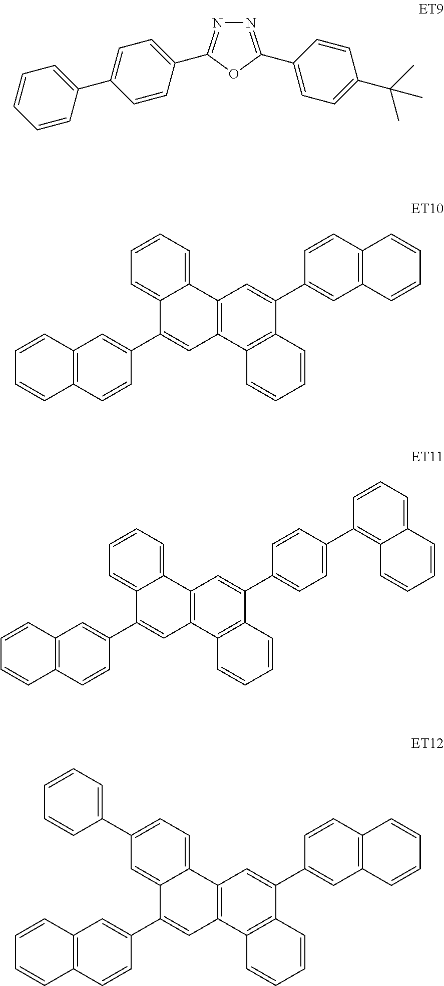

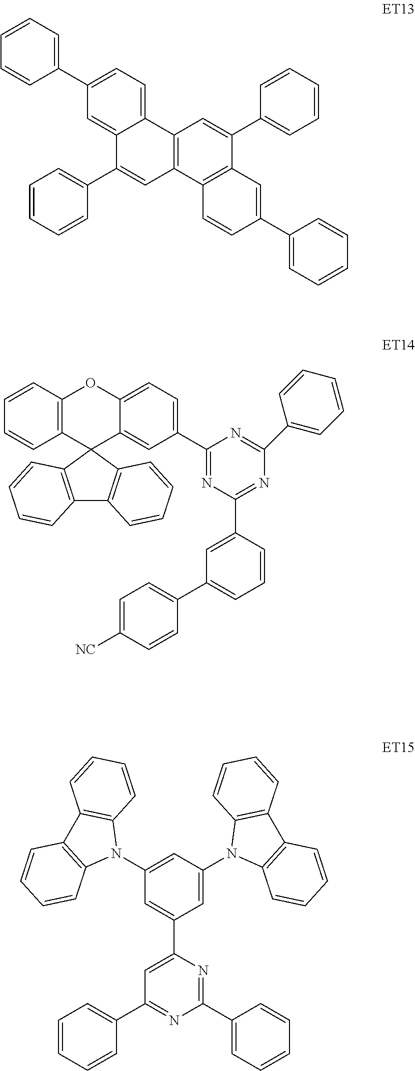

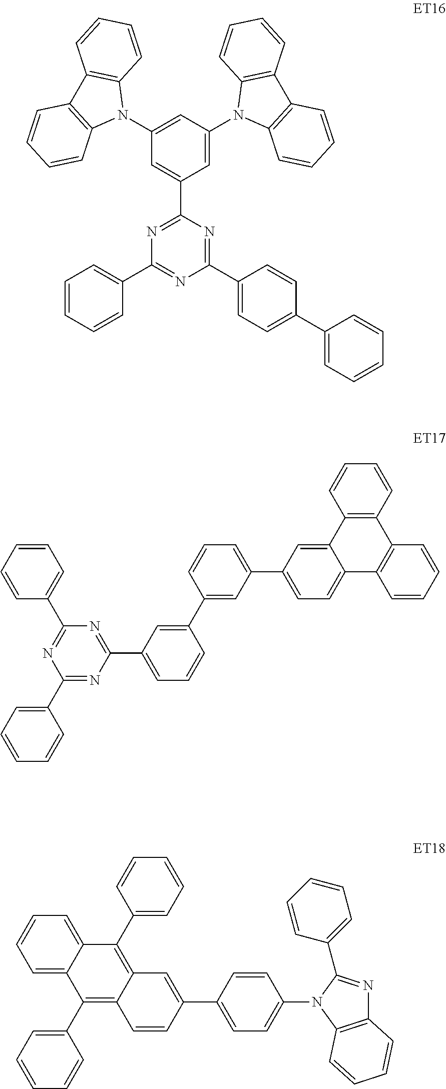 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2c3ccccc3c(-c3ccccc3)c3cc(-c4ccc(-n5c(-c6ccccc6)nc6ccccc65)cc4)ccc23)cc1]

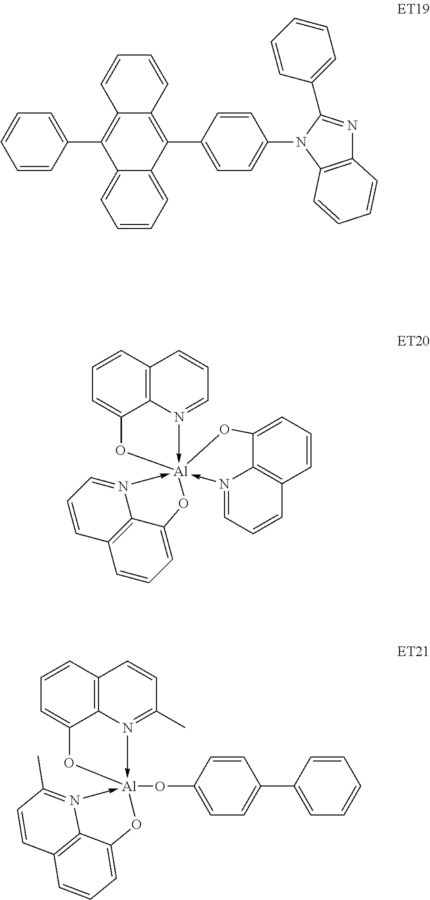

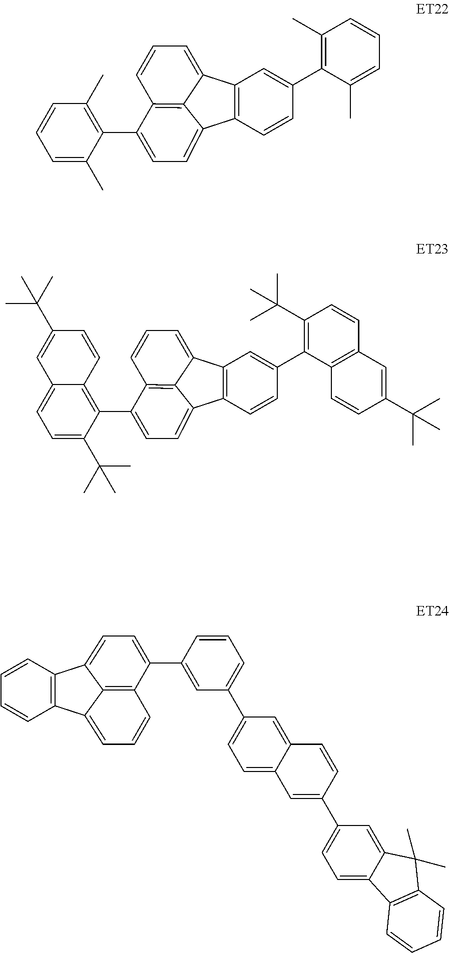

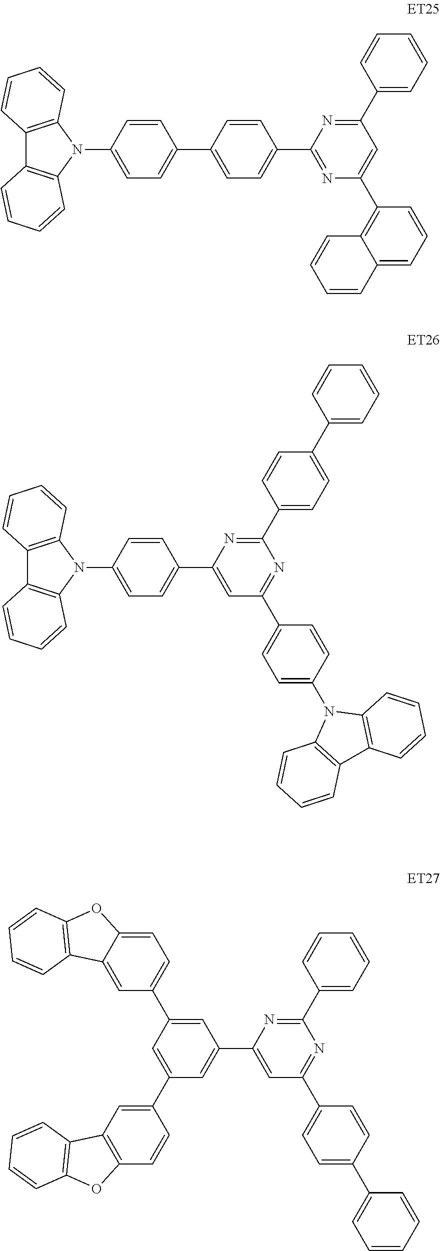 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### Configuration of Organic Light-Emitting Device

Constituent members, other than the organic compound layers, constituting the organic light-emitting device according to the present embodiment will be described below.

The organic light-emitting device includes an insulating layer, a first electrode, an organic compound layer, and a second electrode over a substrate. A protective layer, a color filter, a microlens, and so forth may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include quartz, glass, silicon wafers, resins, and metals. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used for the electrodes. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto. The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. Among them, it is preferable to use silver. To reduce the aggregation of silver, it is more preferable to use a silver alloy. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique is more preferably employed because good film coverage is obtained and thus the resistance is easily reduced.

### Organic Compound Layer

The organic compound layers according to the present embodiment are disposed between the first electrode and the second electrode, and include the stacked light-emitting layer including the first light-emitting layer and the second light-emitting layer as described above, and, as necessary, a hole injection layer, a hole transport layer, an electron-blocking layer, an electron injection layer, an electron transport layer, and a hole-blocking layer. Each of the organic compound layers is mainly composed of an organic compound, and may contain inorganic atoms and an inorganic compound. For example, each organic compound layer may contain, for example, copper, lithium, magnesium, aluminum, iridium, platinum, molybdenum, or zinc.

The organic compound layers, such as the hole injection layer, the hole transport layer, the electron-blocking layer, the light-emitting layer, the hole-blocking layer, the electron transport layer, and the electron injection layer, can be formed by a dry process, such as a vacuum deposition method, an ionized evaporation method, sputtering, or plasma. Alternatively, instead of the dry process, it is also possible to employ a wet process in which a material is dissolved in an appropriate solvent and then a film is formed by a known coating method, such as spin coating, dipping, a casting method, a Langmuir-Blodgett (LB) technique, or an ink jet method.

When the layer is formed by a vacuum deposition method or a solution coating method, crystallization is unlikely to occur and the layer has excellent stability over time. In the case of forming a film by the coating method, the film may be formed in combination with an appropriate binder resin.

Examples of the binder resin include, but are not limited to, polyvinyl carbazole resins, polycarbonate resins, polyester resins, acrylonitrile butadiene styrene (ABS) resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on the cathode. For example, a glass member provided with a moisture absorbent can be bonded to the cathode to reduce the entry of, for example, water into the organic compound layer, thereby reducing the occurrence of display defects. In another embodiment, a passivation film composed of, for example, silicon nitride may be disposed on the cathode to reduce the entry of, for example, water into the organic compound layer. For example, after the formation of the cathode, the substrate may be transported to another chamber without breaking the vacuum, and a silicon nitride film having a thickness of 2 μm may be formed by a CVD method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound, may have a low-molecular-weight or high-molecular-weight compound, and is preferably a high-molecular-weight compound.

The planarization layers may be disposed above and below (or on) the color filter and may be composed of the same or different component materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

The organic light-emitting device may include an optical member, such as a microlens, on the outgoing light side. The microlens can be composed of, for example, an acrylic resin or an epoxy resin. The microlens may be used to increase the amount of light emitted from the organic light-emitting device and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Light-Emitting Apparatus

Pixel circuits may be connected to the organic light-emitting devices according to an embodiment of the present invention to provide a light-emitting apparatus. Each of the pixel circuits may be of an active matrix type, which independently controls the emission of multiple organic light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit.

The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to an organic light-emitting device.

### Pixel

A display apparatus including multiple pixels may be provided by using multiple organic light-emitting devices according to an embodiment of the present invention. Each pixel includes subpixels configured to emit colors different from each other. The subpixels may have respective red, green, and blue (RGB) emission colors.

Light emerges from a region of the pixel, also called a pixel aperture. This region is also referred to as a first region. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to an embodiment of the present invention can be used as a component member of a display apparatus or lighting apparatus. Other applications include exposure light sources for electrophotographic image-forming apparatuses, backlights for liquid crystal displays, and light-emitting apparatuses including white-light sources and color filters.

The display apparatus may be an image information-processing unit having an image input unit that receives image information from an area CCD, a linear CCD, a memory card, or the like, an information-processing unit that processes the input information, and a display unit that displays the input image.

The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

The following describes a display apparatus according to the present embodiment with reference to the attached drawings.

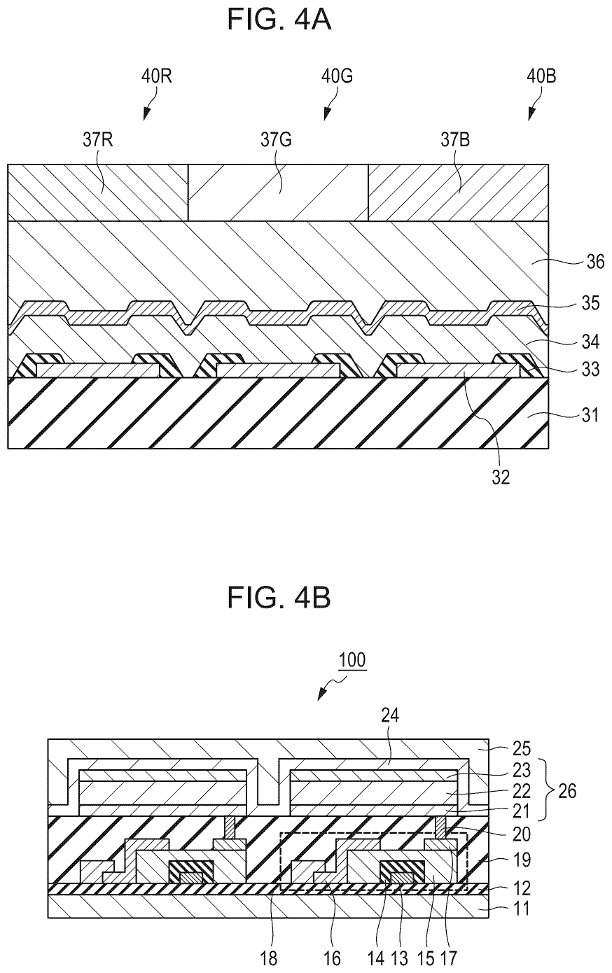

FIG. 4A is an example of pixels that are components of the display apparatus according to the present embodiment. Each of the pixels includes subpixels 40. The subpixels are divided into 40R, 40G, and 40B according to their light emission. The emission color is determined by selectively transmitting or converting the color of light emitted from the subpixels through a color filter. Each subpixel includes a reflective electrode 32 serving as a first electrode, an insulating layer 33 covering the edge of the reflective electrode 32, an organic compound layer 34 covering the first electrode and the insulating layer, a transparent electrode 35, a protective layer 36, and a color filter 37, over an interlayer insulating layer 31.

The transistors and capacitive elements may be disposed under or in the interlayer insulating layer 31. Each transistor may be electrically coupled to a corresponding one of the first electrodes through, for example, a contact hole (not illustrated).

The insulating layer 33 is also called a bank or pixel separation film. The insulating layer covers the edge of each first electrode and surrounds the first electrode. Portions that are not covered with the insulating layer are in contact with the organic compound layer 34 and serve as light-emitting regions.

The protective layer 36 reduces the penetration of moisture into the organic compound layer. Although the protective layer is illustrated as a single layer, the protective layer may be formed of multiple layers. Each layer may be an inorganic compound layer or an organic compound layer.

The color filter 37 is separated into 37R, 37G, and 37B according to its color. The color filter 37 may be disposed on a planarization film, which is not illustrated. A resin protective layer (not illustrated) may be disposed on the color filter 37. The color filter 37 may be disposed on the protective layer 36. Alternatively, the color filter 37 may be disposed on an opposite substrate, such as a glass substrate, and then bonded.

FIGS. 4A and 4B are schematic cross-sectional views illustrating an example of a display apparatus including organic light-emitting devices according to an embodiment of the present invention and transistors coupled to the respective organic light-emitting devices. Each of the transistors is an example of an active element.

A display apparatus 100 illustrated in FIG. 4B includes organic light-emitting devices 26 and TFTs 18 as an example of transistors. Each organic light-emitting device 26 includes an anode 21, a cathode 23, and an organic compound layer 22 disposed therebetween. A substrate 11 composed of a material, such as glass or silicon, is provided, and an insulating layer 12 is disposed thereon. On the insulating layer 12, a gate electrode 13, a gate insulating film 14, and a semiconductor layer 15 of each TFT 18 are disposed. Each TFT 18 includes the semiconductor layer 15, a drain electrode 16, and a source electrode 17. The TFTs 18 are overlaid with an insulating film 19. Anodes 21 included in the organic light-emitting devices 26 are coupled to the source electrodes 17 through contact holes 20 provided in the insulating film 19.

The mode of electrical connection between the electrodes (anode and cathode) included in each organic light-emitting device 26 and the electrodes (source electrode and drain electrode) included in a corresponding one of the TFTs is not limited to the mode illustrated in FIG. 4B. That is, it is sufficient that any one of the anode and the cathode is electrically coupled to any one of the source electrode and the drain electrode of each TFT 18. The term “TFT” refers to a thin-film transistor. In the organic light-emitting device according to the present embodiment, the luminance is controlled by the TFT elements, which are an example of switching elements; thus, an image can be displayed at respective luminance levels by arranging multiple organic light-emitting devices in the plane.

To reduce the deterioration of the organic light-emitting devices, a first protective layer 24 and a second protective layer 25 are disposed on the cathodes 23.

In the display apparatus 100 illustrated in FIG. 4B, although the transistors are used as switching elements, other switching elements may be used instead.

The transistors used in the display apparatus 100 of FIG. 4B may be transistors using a single-crystal silicon wafer, thin-film transistors having active layers on the insulating surface of a substrate, low-temperature polysilicon transistors, or active-matrix drivers formed on a substrate such as a Si substrate. Examples of the active layer include single-crystal silicon, non-single-crystal silicon materials, such as amorphous silicon and microcrystalline silicon, and non-single-crystal oxide semiconductors, such as indium-zinc oxide and indium-gallium-zinc oxide.

The transistors in the display apparatus 100 illustrated in FIG. 4B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed. Whether transistors are formed in the substrate or TFT elements are used is selected in accordance with the size of a display unit. For example, when the display unit has a size of about 0.5 inches, organic light-emitting devices are preferably disposed on a Si substrate.

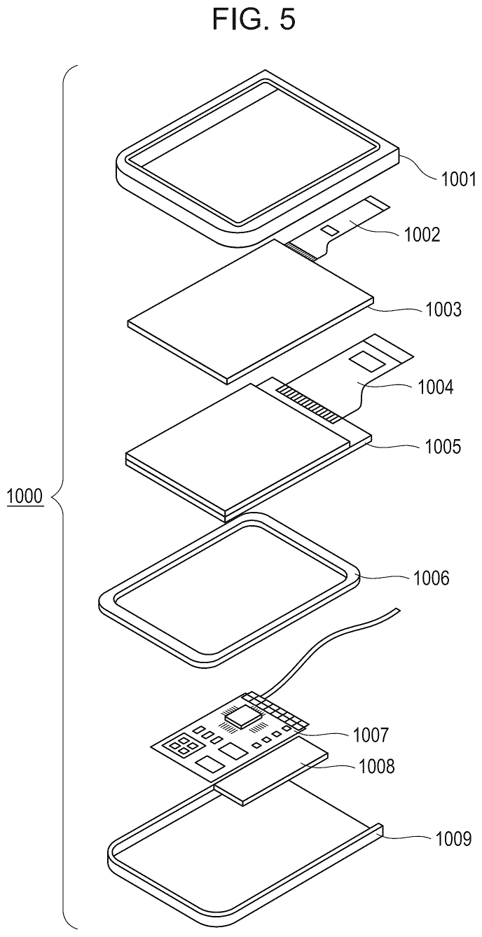

FIG. 5 is a schematic view illustrating an example of a display apparatus according to the present embodiment. A display apparatus 1000 includes, between an upper cover 1001 and a lower cover 1009, a touch panel 1003, a display panel 1005, a frame 1006, a circuit substrate 1007, and a battery 1008. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment is used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

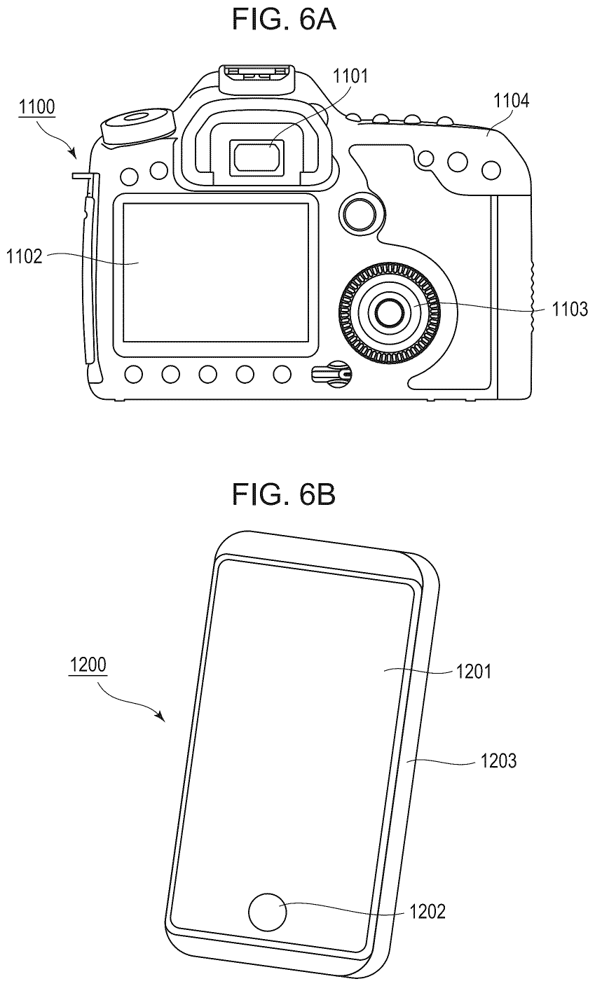

FIG. 6A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 includes the display apparatus according to the present embodiment. The display apparatus may display environmental information, imaging instructions, and so forth in addition to an image to be captured. The environmental information includes, for example, the intensity of external light, the direction of external light, the moving speed of a subject, and the possibility that a subject is shielded by a shielding material.

The timing suitable for imaging is only for a short time; thus, it is better to display the information as soon as possible. Thus, a display apparatus including an organic light-emitting device with a fast response time can be suitably used in an image pickup apparatus or the like where a high display speed is required.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus is also referred to as a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 6B is a schematic view illustrating an example of an electronic apparatus according to the present embodiment. An electronic apparatus 1200 includes a display unit 1201, an operation unit 1202, and a housing 1203. The display unit 1201 has the organic light-emitting device according to the present embodiment. The housing 1203 may accommodate a circuit, a printed circuit board including the circuit, a battery, and a communication unit. The operation unit 1202 may be a button or a touch-panel-type reactive unit. The operation unit may be a biometric recognition unit that recognizes a fingerprint to release the lock or the like. An electronic apparatus having a communication unit can also be referred to as a communication apparatus. The electronic apparatus may further have a camera function by being equipped with a lens and an image pickup device. An image captured by the camera function is displayed on the display unit. Examples of the electronic apparatus include smartphones and notebook computers.

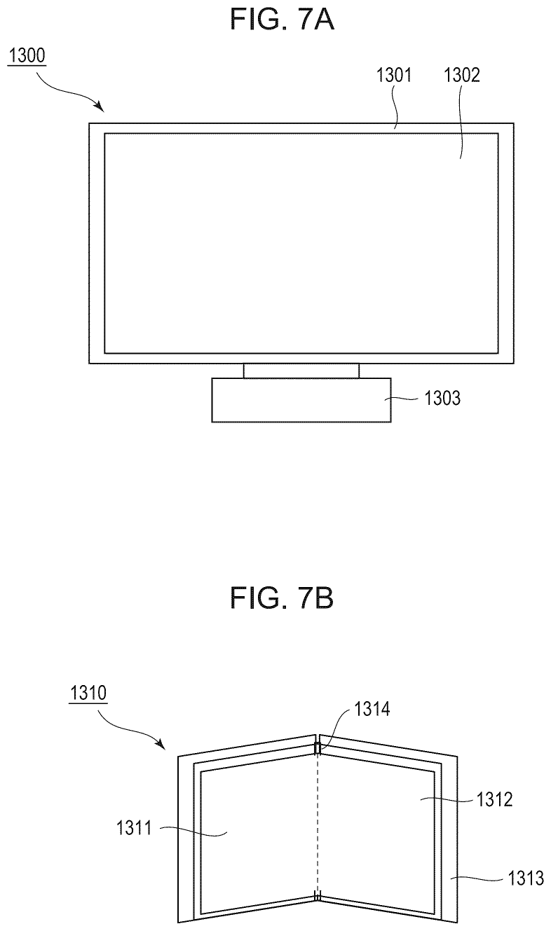

FIGS. 7A and 7B are each a schematic view illustrating an example of a display apparatus according to the present embodiment. FIG. 7A illustrates a display apparatus, such as a television monitor or a personal computer monitor. A display apparatus 1300 includes a frame 1301 and a display unit 1302. The display unit 1302 has the organic light-emitting device according to the present embodiment.

The frame 1301 and the display unit 1302 are supported by a base 1303. The base 1303 is not limited to a form illustrated in FIG. 7A. The lower side of the frame 1301 may also serve as a base.

The frame 1301 and the display unit 1302 may be curved. The radius of curvature may be 5,000 mm or more and 6,000 mm or less.

FIG. 7B is a schematic view illustrating another example of a display apparatus according to the present embodiment. A display apparatus 1310 illustrated in FIG. 7B can be folded and is what is called a foldable display apparatus. The display apparatus 1310 includes a first display unit 1311, a second display unit 1312, a housing 1313, and an inflection point 1314. The first display unit 1311 and the second display unit 1312 include the organic light-emitting device according to the present embodiment. The first display unit 1311 and the second display unit 1312 may be a single, seamless display apparatus or may be divided from each other at the inflection point. The first display unit 1311 and the second display unit 1312 may display different images. Alternatively, a single image may be displayed in the first and second display units.

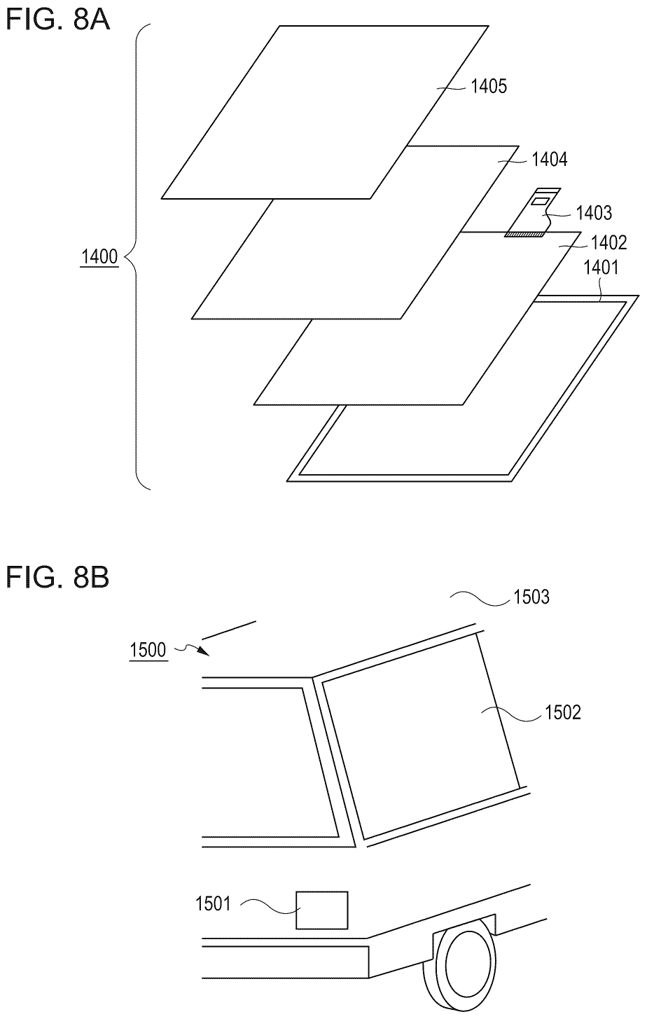

FIG. 8A is a schematic view illustrating an example of a lighting apparatus according to the present embodiment. A lighting apparatus 1400 includes a housing 1401, a light source 1402, a circuit board 1403, an optical filter 1404, and a light diffusion unit 1405. The light source may include an organic light-emitting device according to the present embodiment. The optical filter is a filter that improves the color rendering properties of the light source. The light diffusion unit can effectively diffuse light from the light source to deliver the light to a wide range when used for illumination and so forth. The optical filter and the light diffusion unit are disposed on the light emission side of the lighting apparatus. A cover may be disposed at the outermost portion, as needed.

The lighting apparatus is, for example, an apparatus that lights a room. The lighting apparatus may emit light of white, neutral white, or any color from blue to red, and may include a light control circuit that controls the light. The lighting apparatus includes the organic light-emitting device according to an embodiment of the present invention and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the device to the outside of the device and is composed of, for example, a metal having a high specific heat or liquid silicone.

FIG. 8B is a schematic view illustrating an automobile as an example of a moving object according to the present embodiment. The automobile includes a tail lamp, which is an example of lighting units. An automobile 1500 includes a tail lamp 1501 and may be configured to light the tail lamp when a brake operation or the like is performed.

The tail lamp 1501 includes the organic light-emitting device according to the present embodiment, and may have a protective member that protects the organic light-emitting device. The protective member may be composed of any material as long as it has a certain degree of strength and is transparent. The protective member is preferably composed of polycarbonate or the like. The polycarbonate may be mixed with a furandicarboxylic acid derivative, an acrylonitrile derivative, or the like.

The automobile 1500 includes an automobile body 1503 and windows 1502 attached thereto. The windows may be transparent displays, except when the windows are used to check areas in front of and behind of the automobile. Each of the transparent displays includes an organic light-emitting device according to the present embodiment. In this case, the components, such as the electrodes, of the organic light-emitting device are formed of transparent members.

The moving object according to the embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

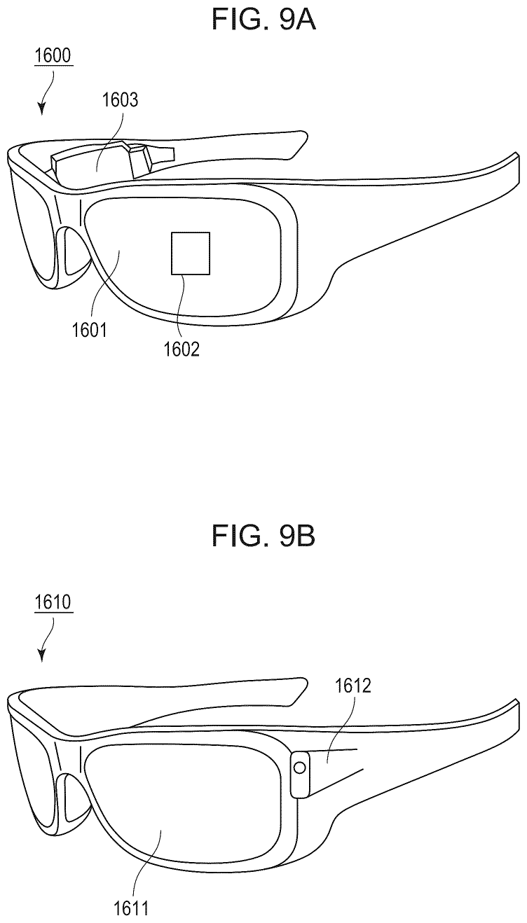

Examples of applications of the display apparatuses of the above embodiments will be described with reference to FIGS. 9A and 9B. The display apparatus according to the present embodiment can be used for systems that can be worn as wearable devices, such as smart glasses, HMDs, and smart contact lenses. A display apparatus used in such an application is an image pickup and display apparatus including an image pickup apparatus that can photoelectrically convert visible light and a display apparatus that can emit visible light.

FIG. 9A illustrates a pair of glasses 1600 (smart glasses) according to an example of applications. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus. The control unit 1603 controls the operation of the image pickup apparatus 1602 and the display apparatus. The lens 1601 has an optical system for focusing light on the image pickup apparatus 1602.

FIG. 9B illustrates a pair of glasses 1610 (smart glasses) according to an example of applications. The glasses 1610 include a control unit 1612. The control unit 1612 includes an image pickup apparatus corresponding to the image pickup apparatus 1602 illustrated in FIG. 9A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. The gaze detection unit using infrared light includes an infrared light-emitting unit that emits infrared light toward the eyeball of a user gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light.

Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present invention includes an image pickup apparatus including light-receiving elements, and may control an image displayed on the display apparatus based on the gaze information of the user from the image pickup apparatus.

Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

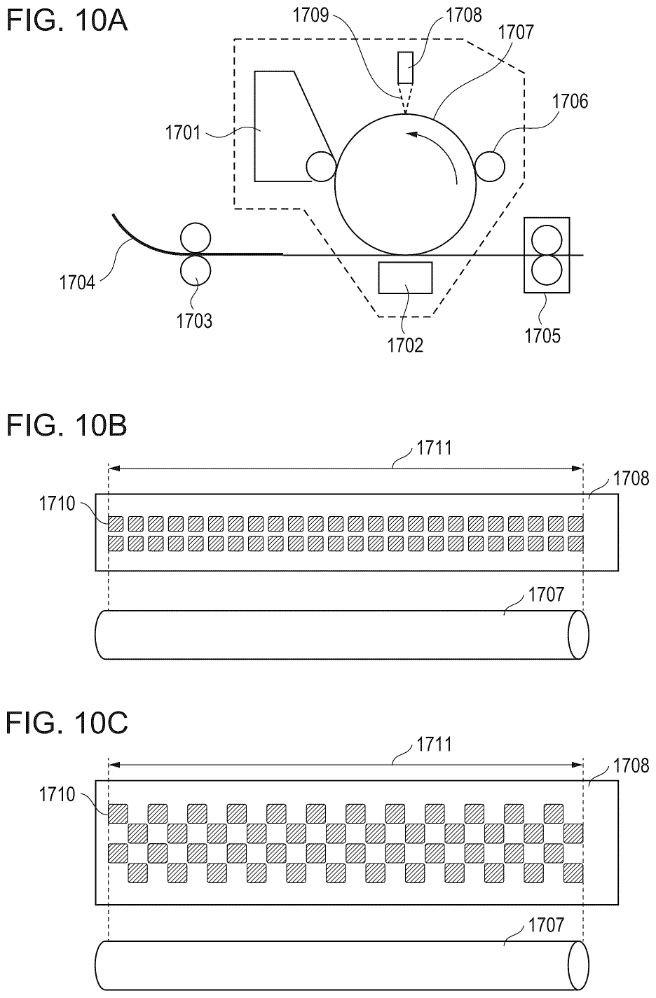

FIG. 10A is a schematic view of an example of an image-forming apparatus according to an embodiment of the present invention. An image-forming apparatus is an electrophotographic image-forming apparatus and includes a photoconductor 1707, an exposure light source 1708, a charging unit 1706, a developing unit 1701, a transfer unit 1702, a conveying roller 1703, and a fixing unit 1705. The irradiation of light 1709 is performed from the exposure light source 1708 to form an electrostatic latent image on the surface of the photoconductor 1707. This exposure light source 1708 includes the organic light-emitting device according to the present embodiment. The developing unit 1701 contains, for example, a toner. The charging unit 1706 charges the photoconductor 1707. The transfer unit 1702 transfers the developed image to a recording medium 1704. The conveying roller 1703 transports the recording medium 1704. The recording medium 1704 is paper, for example. The fixing unit 1705 fixes the image formed on the recording medium 1704.

FIGS. 10B and 10C each illustrate an exposure light source 1708 and are each a schematic view illustrating a state in which multiple light-emitting portions 1710 having organic light-emitting devices according to the present embodiment are arranged on a long substrate. Arrows 1711 each represent the row direction in which the organic light-emitting devices are arranged. The row direction is the same as the direction of the axis on which the photoconductor 1707 rotates. This direction can also be referred to as the long-axis direction of the photoconductor 1707. FIG. 10B illustrates a configuration in which the light-emitting portions 1710 are arranged in the long-axis direction of the photoconductor 1707. FIG. 10C is different from FIG. 10B in that the light-emitting portions 1710 are arranged alternately in the row direction in a first row and a second row. The first row and the second row are located at different positions in the column direction. In the first row, the multiple light-emitting portions 1710 are spaced apart. The second row has the light-emitting portions 1710 at positions corresponding to the positions between the light-emitting portions 1710 in the first row. In other words, the multiple light-emitting portions 1710 are also spaced apart in the column direction. The arrangement in FIG. 10C can be rephrased as, for example, a lattice arrangement, a staggered arrangement, or a checkered pattern.

As described above, the use of an apparatus including the organic light-emitting device according to the present embodiment enables a stable display with good image quality even for a long time.

### Included Configuration

The disclosure of the present embodiment includes the following configurations.

### Configuration 1

An organic light-emitting device includes:
a first electrode;
a light-emitting layer including:
   a first light-emitting layer, and
   a second light-emitting layer; and
a second electrode,
in which the first light-emitting layer is in contact with the second light-emitting layer,
the first light-emitting layer contains:
   a first organic compound,
   a first metal complex, and
   a second metal complex,
the second light-emitting layer contains:
   a second organic compound, and
   a third metal complex, the second light-emitting layer being free of the first metal complex, and
relationships represented by the following formulae [a] to [c] hold:

T1D2>T1D1 [a]

T1D3≥T1D2 [b]

$$T 1 D 2 - T 1 D 1 > T 1 D 3 - T 1 D 2 \qquad [ c ]$$

where T1D1 is the triplet energy of the first metal complex, T1D2 is the triplet energy of the second metal complex, and T1D3 is the triplet energy of the third metal complex.

### Configuration 2

In the organic light-emitting device described in configuration 1, a relationship represented by the following formula [d] holds:

C1D2≥C1D3 [d]

where C1D2 is a concentration of the second metal complex in the light-emitting layer, and C1D3 is a concentration of the third metal complex in the light-emitting layer.

### Configuration 3

In the organic light-emitting device described in configuration 1 or 2, a relationship represented by the following formula [e] holds:

C1D2≥C1D1 [e]

where C1D1 is a concentration of the first metal complex in the light-emitting layer, and C1D2 is a concentration of the second metal complex in the light-emitting layer.

### Configuration 4

In the organic light-emitting device described in any one of configurations 1 to 3, the second metal complex and the third metal complex have at least one identical ligand.

### Configuration 5

In the organic light-emitting device described in any one of configurations 1 to 4, relationships represented by the following formulae [f] and [g] hold:

$$\vert LUMOD 3 - LUMOD 2 \vert \leq 0.2 eV \qquad [ f ]$$

$$\vert HOMOD 3 - HOMOD 2 \vert \leq 0.2 eV \qquad [ g ]$$

where HOMOD2 is the HOMO energy level of the second metal complex, LUMOD2 is the LUMO energy level of the second metal complex, HOMOD3 is the HOMO energy level of the third metal complex, and LUMOD3 is the LUMO energy level of the third metal complex.

### Configuration 6

In the organic light-emitting device described in any one of configurations 1 to 5, the first metal complex is a red-phosphorescent material, and the third metal complex is a green-phosphorescent material.

### Configuration 7

In the organic light-emitting device described in any one of configurations 1 to 6, the second light-emitting layer contains a third organic compound that is not a metal complex.

### Configuration 8

In the organic light-emitting device described in any one of configurations 1 to 7, the first electrode is an anode, the second electrode is a cathode, the first light-emitting layer is adjacent to the anode, and the second light-emitting layer is adjacent to the cathode.

### Configuration 9

In the organic light-emitting device described in any one of configurations 1 to 8, a relationship represented by the following formula [h] holds:

C1D3>C1D1 [h]

where C1D3 is the concentration of the third metal complex in the light-emitting layer, and C1D1 is the concentration of the first metal complex in the light-emitting layer.

### Configuration 10

In the organic light-emitting device described in any one of configurations 1 to 9, the second metal complex and the third metal complex are the same compound.

### Configuration 11

In the organic light-emitting device described in any one of configurations 1 to 10, the first organic compound and the second organic compound are the same compound.

### Configuration 12

In the organic light-emitting device described in any one of configurations 1 to 11, the color of light emitted from the light-emitting layer is yellow.

### Configuration 13

A display apparatus includes:
multiple pixels, at least one of the multiple pixels including the organic light-emitting device described in any one of configurations 1 to 12; and
a transistor coupled to the organic light-emitting device.

### Configuration 14

An image pickup apparatus includes:
an optical unit including multiple lenses;
an image pickup device configured to receive light passing through the optical unit; and
a display unit configured to display an image captured by the image pickup device,
wherein the display unit includes the organic light-emitting device described in any one of configurations 1 to 12.

### Configuration 15

An electronic apparatus includes:
a display unit including the organic light-emitting device described in any one of configurations 1 to 12;
a housing provided with the display unit; and
a communication unit disposed in the housing and configured to communicate with an outside.

### Configuration 16

A lighting apparatus includes:
a light source including the organic light-emitting device described in any one of configurations 1 to 12; and
a light diffusion unit or an optical filter configured to transmit light emitted from the light source.

### Configuration 17

A moving object includes:
a lighting unit including the organic light-emitting device described in any one of configurations 1 to 12; and
a body provided with the lighting unit.

### Configuration 18

An exposure light source for an electrophotographic image-forming apparatus includes:
the organic light-emitting device described in any one of configurations 1 to 12.

### EXAMPLES

### Example 1

### Evaluation of Triplet Energy

The T1 energy of the dopant was evaluated by the following method. The results are presented in Table 1. The evaluation was performed by photoluminescence (PL) measurement of a dilute toluene solution at an excitation wavelength of 300 nm at 77 K using F-4500, manufactured by Hitachi, Ltd., and a preset phosphorescence mode measurement. The triplet energy was calculated from the maximum emission wavelength of the resulting emission spectrum.

### Evaluation of HOMO and LUMO

The HOMO levels and LUMO levels of the host and dopant were evaluated by the following methods. The results are presented in Table 1.

### A) Method for Evaluating HOMO Level

Under a vacuum of 5×10⁻⁴ Pa or less, a vapor-deposited film having a thickness of 30 nm was formed on an aluminum substrate, and this thin film was used for the measurement using AC-3 (manufactured by Riken Keiki Co., Ltd.).

### B) Method for Evaluating LUMO Level

Under a vacuum of 5×10⁻⁴ Pa or less, a vapor-deposited film having a thickness of 30 nm was formed on a silica substrate, and the optical band gap (absorption edge) of the target material was determined using this thin film with a spectrophotometer (V-560, manufactured by JASCO Corporation). A value obtained by adding the value of the HOMO level to the optical band gap value was used as the LUMO level. The results are presented in Table 1.

TABLE 1

| Com- | T1 | HOMO | LUMO | Com- | T1 | HOMO | LUMO |
|---|---|---|---|---|---|---|---|
| pound | (eV) | (eV) | (eV) | pound | (eV) | (eV) | (eV) |
| AA1 | 2.3 | −5.7 | −3.4 | FF11 | 2.3 | −5.3 | −3.2 |
| AA2 | 2.4 | −5.6 | −3.3 | HH1 | 2.0 | −5.4 | −3.4 |
| AA21 | 2.3 | −5.7 | −3.4 | HH19 | 2.0 | −5.4 | −3.5 |
| AA22 | 2.4 | −5.4 | −3.1 | II1 | 2.0 | −5.4 | −3.5 |
| BB2 | 2.3 | −5.4 | −3.1 | II8 | 2.0 | −5.4 | −3.5 |
| BB3 | 2.3 | −5.4 | −3.1 | II9 | 2.0 | −5.4 | −3.5 |
| BB21 | 2.3 | −5.5 | −3.2 | JJ1 | 2.3 | −5.6 | −3.4 |
| CC1 | 2.3 | −5.6 | −3.3 | JJ2 | 2.4 | −5.5 | −3.1 |
| CC2 | 2.4 | −5.5 | −3.2 | JJ4 | 2.3 | −5.4 | −3.1 |
| CC21 | 2.3 | −5.6 | −3.3 | JJ14 | 2.4 | −5.2 | −2.8 |
| CC22 | 2.4 | −5.5 | −3.2 | JJ16 | 2.3 | −5.6 | −3.4 |
| DD1 | 2.4 | −5.6 | −3.4 | JJ17 | 2.4 | −5.5 | −3.2 |
| DD2 | 2.4 | −5.4 | −3.1 | JJ19 | 2.3 | −5.6 | −3.2 |
| DD7 | 2.4 | −5.3 | −3.0 | JJ20 | 2.4 | −5.3 | −2.9 |
| DD8 | 2.4 | −5.5 | −3.3 | GD10 | 2.4 | −5.5 | −3.1 |
| DD29 | 2.4 | −5.6 | −3.4 | GD11 | 2.4 | −5.5 | −3.1 |
| BD9 | 2.7 | −6.2 | −3.5 | GD20 | 2.4 | −5.2 | −2.8 |
| DD30 | 2.4 | −5.4 | −2.8 | RD3 | 2.0 | −5.5 | −3.6 |
| DD31 | 2.4 | −5.4 | −2.8 | RD7 | 2.0 | −5.4 | −3.5 |
| EE1 | 2.4 | −5.5 | −3.2 | RD10 | 2.0 | −5.5 | −3.5 |

### Example 2

An organic light-emitting device having a bottom-emission structure was produced in which an anode, a hole injection layer, a hole transport layer, an electron-blocking layer, a light-emitting layer, a hole-blocking layer, an electron transport layer, an electron injection layer, and a cathode were sequentially formed over a substrate.

An ITO film was formed on a glass substrate and subjected to desired patterning to form an ITO electrode (anode). At this time, the thickness of the ITO electrode was 100 nm. The substrate on which the ITO electrode had been formed in this way was used as an ITO substrate in the following steps. Next, vacuum deposition was performed by resistance heating in a vacuum chamber at 1.33×10⁻⁴ Pa to successively form organic compound layers and an electrode layer presented in Table 2 on the ITO substrate. Here, the opposite electrode (metal electrode layer, cathode) had an electrode area of 3 mm². Thereafter, the substrate was transferred to a glove box and sealed with a glass cap containing a drying agent in a nitrogen atmosphere to provide an organic light-emitting device.

TABLE 2

| | Material | | | Thickness (nm) |
|---|---|---|---|---|
| Cathode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Second light-emitting layer | Second host | EM14 | Ratio by mass | 15 |
| (EML) | Third metal complex | AA2 | EM14:AA2 = | |
| | (T1 [eV]) | (2.4 eV) | 85:15 | |
| First light-emitting layer | First host | EM10 | Ratio by mass | 5 |
| (EML) | Second metal complex | AA1 | EM10:AA1:HH1 = | |
| | (T1 [eV]) | (2.3 eV) | 78:20:2 | |
| | First metal complex | HH1 | | |
| | (T1 [eV]) | (2.0 eV) | | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

The characteristics of the resulting organic light-emitting device were measured and evaluated. The emission color of the organic light-emitting device was yellow, and the maximum external quantum efficiency (E.Q.E.) was 18%.

The device was subjected to a continuous operation test at a current density of 100 mA/cm². The time when the percentage of luminance degradation reached 5% was measured. When the time when the percentage of luminance degradation of Comparative Example 1 reached 5% was defined as 1.0, the luminance degradation ratio in this example was 2.3.

With regard to measurement instruments, in this example, the current-voltage characteristics were measured with a Hewlett-Packard 4140B microammeter, and the luminance was measured with a Topcon BM7.

### Examples 3 to 20 and Comparative Example 1 to 5

Organic light-emitting devices of Examples 3 to 20 and Comparative Examples 1 to 5 were produced in the same manner as in Example 2, except that the compounds constituting the organic compound layers were appropriately changed to those given in Table 3. The characteristics of the resulting organic light-emitting devices were measured and evaluated as in Example 2. The measurement results are presented in Table 3.

When the second light-emitting layer contained an assist material, the ratio by mass of the second host to assist material to third metal complex was adjusted to be 55:30:15.

TABLE 3

| | | First light-emitting layer | | | | | | | | |
|---|---|---|---|---|---|---|---|---|---|---|
| | | | Second metal | | Second light-emitting layer | | | | | |
| | | | complex | First metal | | | Third metal | | | Luminance |
| | | First | (T1 [eV]) | complex | Second | | complex | | E.Q.E | degradation |
| | EBL | host | or assist | (T1 [eV]) | host | Assist | (T1 [eV]) | HBL | [%] | ratio |
| Example 3 | HT19 | EM10 | JJ19(2.3 eV) | HH1(2.0 eV) | EM14 | None | AA2(2.4 eV) | ET12 | 19 | 1.8 |
| Example 4 | HT15 | EM10 | JJ19(2.3 eV) | HH19(2.0 eV) | EM14 | EM29 | AA2(2.4 eV) | ET12 | 20 | 2.4 |
| Example 5 | HT15 | EM13 | JJ4(2.3 eV) | HH1(2.0 eV) | EM14 | EM30 | CC2(2.4 eV) | ET11 | 22 | 2.4 |
| Example 6 | HT19 | EM11 | JJ4(2.3 eV) | HH1(2.0 eV) | EM14 | None | CC22(2.4 eV) | ET11 | 19 | 1.8 |
| Example 7 | HT19 | EM14 | AA1(2.3 eV) | HH19(2.0 eV) | EM11 | None | DD2(2.4 eV) | ET11 | 19 | 1.8 |
| Example 8 | HT19 | EM13 | AA21(2.3 eV) | HH19(2.0 eV) | EM11 | None | DD2(2.4 eV) | ET11 | 18 | 1.8 |
| Example 9 | HT19 | EM14 | CC1(2.3 eV) | II9(2.0 eV) | EM10 | None | DD7(2.4 eV) | ET12 | 19 | 1.8 |
| Example 10 | HT15 | EM14 | AA21(2.3 eV) | II8(2.0 eV) | EM14 | EM30 | DD30(2.4 eV) | ET12 | 23 | 2.4 |
| Example 11 | HT19 | EM10 | JJ4(2.3 eV) | II9(2.0 eV) | EM14 | None | JJ2(2.4 eV) | ET12 | 19 | 1.8 |
| Example 12 | HT15 | EM11 | JJ4(2.3 eV) | II9(2.0 eV) | EM14 | None | JJ14(2.4 eV) | ET11 | 18 | 1.8 |
| Example 13 | HT19 | EM13 | FF11(2.3 eV) | II8(2.0 eV) | EM14 | None | JJ17(2.4 eV) | ET12 | 18 | 1.8 |
| Example 14 | HT15 | EM39 | AA21(2.3 eV) | RD3(2.0 eV) | EM41 | None | JJ20(2.4 eV) | ET12 | 17 | 1.7 |
| Example 15 | HT15 | EM34 | CC1(2.3 eV) | RD7(2.0 eV) | EM14 | None | GD20(2.4 eV) | ET11 | 19 | 1.7 |
| Example 16 | HT19 | EM35 | BB21(2.3 eV) | RD7(2.0 eV) | EM39 | None | GD11(2.4 eV) | ET12 | 19 | 1.7 |
| Example 17 | HT19 | EM34 | CC21(2.3 eV) | RD10(2.0 eV) | EM37 | EM30 | JJ19(2.3 eV) | ET12 | 21 | 2.1 |
| Example 18 | HT19 | EM13 | JJ19(2.3 eV) | II9(2.0 eV) | EM39 | EM30 | JJ19(2.3 eV) | ET11 | 20 | 2.3 |
| Example 19 | HT19 | EM14 | JJ19(2.3 eV) | II8(2.0 eV) | EM14 | EM31 | JJ4(2.3 eV) | ET12 | 22 | 2.8 |
| Example 20 | HT19 | EM43 | JJ4(2.3 eV) | II9(2.0 eV) | EM39 | EM31 | GD11(2.3 eV) | ET11 | 20 | 1.8 |
| Comparative | HT19 | EM42 | EM43 | GD10 | EM42 | EM47 | RD7(2.0 eV) | ET11 | 18 | 1.0 |
| Example 1 | | | | (2.4 eV) | | | | | | |
| Comparative | HT19 | EM45 | None | BD9 | EM46 | None | BD9 | ET11 | 7 | 0.3 |
| Example 2 | | | | (2.7 eV) | | | (2.7 eV) | | | |
| Comparative | HT19 | EM47 | None | GD10 | EM47 | BD9 | GD10 | ET11 | 12 | 0.8 |
| Example 3 | | | | (2.4 eV) | | (2.6 eV) | (2.4 eV) | | | |
| Comparative | HT19 | EM14 | None | HH1 | EM14 | None | AA2 | ET12 | 15 | 1.3 |
| Example 4 | | | | (2.0 eV) | | | (2.4 eV) | | | |
| Comparative | HT19 | EM10 | JJ1(2.3 eV) | II9 | EM14 | EM30 | BD9 | ET11 | 15 | 1.1 |
| Example 5 | | | | (2.0 eV) | | | (2.7 eV) | | | |
| Comparative | HT19 | EM10 | EM29 | GD10 | EM11 | None | RD7 | ET11 | 13 | 1.4 |
| Example 6 | | | | (2.4 eV) | | | (2.0 eV) | | | |
| Comparative | HT19 | EM45 | GD10 | RD7 | EM45 | RD7 | GD10 | ET11 | 8 | 1.3 |
| Example 7 | | | (2.4 eV) | (2.0 eV) | | (2.0 eV) | (2.4 eV) | | | |

From Table 3, the values of E.Q.E. in Comparative Examples 1 to 7 were 18%, 7%, 12%, 15%, 15%, 13%, and 8%. The luminance degradation ratios in Comparative Examples 1 to 7 were 1.0, 0.3, 0.8, 1.3, 1.1, 1.4, and 1.3. These devices are considered to have poor light emission characteristics and durability characteristics because carrier transfer and triplet energy transfer between the stacked light-emitting layers are less likely to occur.

In contrast, each of the organic light-emitting devices according to an embodiment of the present invention exhibited excellent luminous efficiency and an excellent device lifetime. This is because the stacked light-emitting layers according to an embodiment of the present invention have a relationship in which carrier transfer and energy transfer occur easily.

Furthermore, it was possible to provide the organic light-emitting device having particularly excellent device lifetime by selecting the host material and the light-emitting material suitable for combination with the stacked light-emitting layer according to an embodiment of the present invention.

As described above, the organic compounds of the present invention can provide the organic light-emitting device having excellent luminous efficiency and device lifetime.

### Example 21

An organic light-emitting device was produced in the same manner as in Example 2, except that the thickness of the first light-emitting layer was changed to 10 nm. The characteristics of the resulting organic light-emitting device were measured and evaluated as in Example 2. The maximum external quantum efficiency (E.Q.E.) was 16%, and the luminance degradation ratio was 2.0.

### Example 22

An organic light-emitting device was produced in the same manner as in Example 2, except that the thickness of the first light-emitting layer was changed to 10 nm and the thickness of the second light-emitting layer was changed to 10 nm. The characteristics of the resulting organic light-emitting device were measured and evaluated as in Example 2. The maximum external quantum efficiency (E. Q. E.) was 18%, and the luminance degradation ratio was 1.8.

### Example 23

An organic light-emitting device was produced in the same manner as in Example 2, except that the ratio by mass in the first light-emitting layer was changed to EM13:AA1:HH1=81:15:4, and the ratio by mass in the second light-emitting layer was changed to EM14:AA2=85:15. The characteristics of the resulting organic light-emitting device were measured and evaluated as in Example 2. The maximum external quantum efficiency (E.Q.E.) was 16%, and the luminance degradation ratio was 2.0.

### Example 24

An organic light-emitting device was produced in the same manner as in Example 2, except that the ratio by mass in the first light-emitting layer was changed to EM13:AA1:HH1=75:20:5, and the ratio by mass in the second light-emitting layer was changed to EM14:AA2=95:5. The characteristics of the resulting organic light-emitting device were measured and evaluated as in Example 2. The maximum external quantum efficiency (E.Q.E.) was 148, and the luminance degradation ratio was 2.2.

According to an embodiment of the present invention, it is possible to provide the organic light-emitting device having improved durability characteristics.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic light-emitting device, comprising:
a first electrode;
a light-emitting layer including:
a first light-emitting layer, and
a second light-emitting layer; and
a second electrode,
wherein the first light-emitting layer is in contact with the second light-emitting layer,
the first light-emitting layer contains:
a first organic compound,
a first metal complex, and
a second metal complex,
the second light-emitting layer contains:
a second organic compound, and
a third metal complex, the second light-emitting layer being free of the first metal complex, and
relationships represented by the following formulae [a] to [c] hold:
T1D2>T1D1 [a]
T1D3≥T1D2 [b]
$$T 1 D 2 - T 1 D 1 > T 1 D 3 - T 1 D 2 \qquad [ c ]$$
where T1D1 is triplet energy of the first metal complex, T1D2 is triplet energy of the second metal complex, and T1D3 is triplet energy of the third metal complex.

2. The organic light-emitting device according to claim 1, wherein a relationship represented by the following formula [d] holds:
C1D2≥C1D3 [d]
where C1D2 is a concentration of the second metal complex in the light-emitting layer, and C1D3 is a concentration of the third metal complex in the light-emitting layer.

3. The organic light-emitting device according to claim 1, wherein a relationship represented by the following formula [e] holds:
C1D2>C1D1 [e]
where C1D1 is a concentration of the first metal complex in the light-emitting layer, and C1D2 is a concentration of the second metal complex in the light-emitting layer.

4. The organic light-emitting device according to claim 1, wherein the second metal complex and the third metal complex have at least one identical ligand.

5. The organic light-emitting device according to claim 1, wherein relationships represented by the following formulae [f] and [g] hold:
$$\vert LUMOD 3 - LUMOD 2 \vert \leq 0.2 eV \qquad [ f ]$$
$$\vert HOMOD 3 - HOMOD 2 \vert \leq 0.2 eV \qquad [ g ]$$
where HOMOD2 is an energy level of a highest occupied molecular orbital of the second metal complex, LUMOD2 is an energy level of a lowest unoccupied molecular orbital of the second metal complex, HOMOD3 is an energy level of a highest occupied molecular orbital of the third metal complex, and LUMOD3 is an energy level of a lowest unoccupied molecular orbital of the third metal complex.

6. The organic light-emitting device according to claim 1, wherein the first metal complex is a red-phosphorescent material, and the third metal complex is a green-phosphorescent material.

7. The organic light-emitting device according to claim 1, wherein the second light-emitting layer contains a third organic compound that is not a metal complex.

8. The organic light-emitting device according to claim 1, wherein the first electrode is an anode, the second electrode is a cathode, the first light-emitting layer is adjacent to the anode, and the second light-emitting layer is adjacent to the cathode.

9. The organic light-emitting device according to claim 1, wherein a relationship represented by the following formula [h] holds:
C1D3>C1D1 [h]
where C1D3 is a concentration of the third metal complex in the light-emitting layer, and C1D1 is a concentration of the first metal complex in the light-emitting layer.

10. The organic light-emitting device according to claim 1, wherein the second metal complex and the third metal complex are the same compound.

11. The organic light-emitting device according to claim 1, wherein the first organic compound and the second organic compound are the same compound.

12. The organic light-emitting device according to claim 1, wherein a color of light emitted from the light-emitting layer is yellow.

13. A display apparatus, comprising:
multiple pixels, at least one of the multiple pixels including the organic light-emitting device according to claim 1; and
a transistor coupled to the organic light-emitting device.

14. An image pickup apparatus, comprising:
an optical unit including multiple lenses;
an image pickup device configured to receive light passing through the optical unit; and
a display unit configured to display an image captured by the image pickup device,
wherein the display unit includes the organic light-emitting device according to claim 1.

15. An electronic apparatus, comprising:
a display unit including the organic light-emitting device according to claim 1;
a housing provided with the display unit; and
a communication unit disposed in the housing and configured to communicate with an outside.

16. A lighting apparatus, comprising:
a light source including the organic light-emitting device according to claim 1; and
a light diffusion unit or an optical filter configured to transmit light emitted from the light source.

17. A moving object, comprising:
a lighting unit including the organic light-emitting device according to claim 1; and
a body provided with the lighting unit.

18. An exposure light source for an electrophotographic image-forming apparatus, comprising:
the organic light-emitting device according claim 1.
